(19) United States
(12) Patent Application Publication
(10) Pub. No.: US 2016/0155803 A1
(43) Pub. Date: Jun. 2, 2016

(54) Semiconductor Device, Method for Manufacturing the Semiconductor Device, and Display Device Including the Semiconductor Device

(71) Applicant: Semiconductor Energy Laboratory Co., Ltd., Kanagawa-ken (JP)

(72) Inventors: Shunpei YAMAZAKI, Tokyo (JP); Junichi KOEZUKA, Tochigi (JP); Kenichi OKAZAKI, Tochigi (JP); Masami JINTYOU, Tochigi (JP); Yasutaka NAKAZAWA, Tochigi (JP); Toshimitsu OBONAI, Shimotsuke (JP); Yukinori SHIMA, Tatebayashi (JP); Daisuke KUROSAKI, Tochigi (JP)

(73) Assignee: Semiconductor Energy Laboratory Co., Ltd., Kanagawa-ken (JP)

(21) Appl. No.: 14/952,459

(22) Filed: Nov. 25, 2015

(30) Foreign Application Priority Data
Nov. 28, 2014 (JP) 2014-241466
Dec. 26, 2014 (JP) 2014-264766

(51) Int. Cl. H01L 29/10; H01L 27/12; H01L 29/66; H01L 29/786

(52) U.S. Cl. CPC H01L 29/1033; H01L 29/7869; H01L 27/1225; H01L 29/66969; H01L 27/127

(57) ABSTRACT

A change in electrical characteristics is inhibited and reliability is improved in a semiconductor device including an oxide semiconductor film. The semiconductor device includes a gate electrode, a gate insulating film over the gate electrode, an oxide semiconductor film over the gate insulating film, and a pair of electrodes over the oxide semiconductor film. The oxide semiconductor film includes a channel region and n-type regions in contact with the pair of electrodes. The channel region has fewer oxygen vacancies than the n-type regions.

### BACKGROUND OF THE INVENTION

1. Field of the Invention

One embodiment of the present invention relates to a semiconductor device including an oxide semiconductor film, a method for manufacturing the semiconductor device, and a display device including the semiconductor device.

Note that one embodiment of the present invention is not limited to the above technical field. The technical field of one embodiment of the invention disclosed in this specification and the like relates to an object, a method; or a manufacturing method. In addition, one embodiment of the present invention relates to a process, a machine, manufacture, or a composition of matter. In particular, one embodiment of the present invention relates to a semiconductor device, a display device, a liquid crystal display device, a light-emitting device, a power storage device, a memory device, an imaging device, a method for driving them, or a method for manufacturing them.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. An imaging device, a display device, a liquid crystal display device, a light-emitting device, an electro-optical device, a power generation device (including a thin film solar cell, an organic thin film solar cell, and the like), and an electronic device may each include a semiconductor device.

2. Description of the Related Art

Attention has been focused on a technique for forming a transistor using a semiconductor thin film formed over a substrate having an insulating surface (also referred to as a field-effect transistor (FET) or a thin film transistor (TFT)). Such transistors are applied to a wide range of electronic devices such as an integrated circuit (IC) and an image display device (display device). A semiconductor material typified by silicon is widely known as a material for a semiconductor thin film that can be used for a transistor. As another material, an oxide semiconductor has been attracting attention (e.g., Patent Document 1).

In addition, a method for manufacturing a semiconductor device in which an oxide semiconductor layer is highly purified in the following manner is disclosed: an oxide insulating layer is formed over the oxide semiconductor layer; oxygen is introduced (added) through the oxide insulating layer; heat treatment is performed; and impurities such as hydrogen, moisture, a hydroxyl group, or hydride are removed from the oxide semiconductor layer by the introduction of oxygen and the heat treatment (e.g., Patent Document 2).

### REFERENCE

### Patent Document

[Patent Document 1] Japanese Published Patent Application No. 2006-165529
[Patent Document 2] Japanese Published Patent Application No. 2011-199272

### SUMMARY OF THE INVENTION

In the case where a transistor including an oxide semiconductor film in a channel region is manufactured, impurities such as hydrogen or moisture entering the channel region of the oxide semiconductor film adversely affect the transistor characteristics and therefore cause a problem. Oxygen vacancies formed in the channel region of the oxide semiconductor film also adversely affect the transistor characteristics and therefore cause a problem. For example, oxygen vacancies formed in the channel region in the oxide semiconductor film are bonded to hydrogen to serve as a carrier supply source. The carrier supply source generated in the channel region in the oxide semiconductor film causes a change in the electrical characteristics, typically, shift in the threshold voltage, of the transistor including the oxide semiconductor film. Furthermore, there is a problem in that electrical characteristics fluctuate among the transistors. Therefore, it is preferable that the amount of oxygen vacancies in the channel region of the oxide semiconductor film be as small as possible. Moreover, it is preferable that the amount of impurities such as hydrogen or moisture as well as oxygen vacancies in the channel region of the oxide semiconductor film be as small as possible.

A region of the oxide semiconductor film, which is in contact with an electrode or a wiring, preferably has low resistance in order to obtain good contact resistance.

In view of the above problem, an object of one embodiment of the present invention is to inhibit a change in electrical characteristics and to improve reliability in a semiconductor device including an oxide semiconductor film. Another object of one embodiment of the present invention is to provide a novel semiconductor device and a novel method for manufacturing a semiconductor device. Another object of one embodiment of the present invention is to provide a novel display device.

Note that the description of the above object does not disturb the existence of other objects. In one embodiment of the present invention, there is no need to achieve all the objects. Objects other than the above objects will be apparent from and can be derived from the description of the specification and the like.

One embodiment of the present invention is a semiconductor device which includes a gate electrode, a gate insulating film over the gate electrode, an oxide semiconductor film over the gate insulating film, and a pair of electrodes over the oxide semiconductor film. The oxide semiconductor film includes a channel region and n-type regions in contact with the pair of electrodes. The channel region has fewer oxygen vacancies than the n-type regions.

Another embodiment of the present invention is a semiconductor device which includes a gate electrode, a gate insulating film over the gate electrode, an oxide semiconductor film over the gate insulating film, a pair of electrodes over the oxide semiconductor film, and an oxide insulating film over the oxide semiconductor film and the pair of electrodes. The oxide semiconductor film includes a channel region and n-type regions in contact with the pair of electrodes. The channel region has fewer oxygen vacancies than the n-type regions.

Another embodiment of the present invention is a semiconductor device which includes a first gate electrode, a gate insulating film over the first gate electrode, an oxide semiconductor film over the gate insulating film, a pair of electrodes over the oxide semiconductor film, an oxide insulating film over the oxide semiconductor film and the pair of electrodes, a nitride insulating film over the oxide insulating film, and a second gate electrode over the nitride insulating film. The oxide semiconductor film includes a channel region and n-type regions in contact with the pair of electrodes. The channel region has fewer oxygen vacancies than the n-type regions.

In any of the above embodiments, the channel region preferably has a thinner region than the oxide semiconductor film formed under the pair of electrodes.

In any of the above embodiments, the oxide semiconductor film preferably includes In, Zn, and M (M is Ti, Ga, Y, Zr, La, Ce, Nd, Sn, or Hf). In any of the above embodiments, the oxide semiconductor film preferably includes a crystal part, and the crystal part preferably has c-axis alignment and includes a portion whose c-axis is parallel to a normal vector of a surface over which the oxide semiconductor film is formed.

In any of the embodiments, oxygen molecules of more than or equal to 8.0×10¹⁴/cm² are preferably detected from the oxide insulating film by thermal desorption spectroscopy.

Another embodiment of the present invention is a display device including the semiconductor device according to any one of the above embodiments and a display element. Another embodiment of the present invention is a display module including the display device and a touch sensor. Another embodiment of the present invention is an electronic device including the semiconductor device according to any one of the above embodiments, the display device according to the above embodiment, or the display module according to the above embodiment; and an operation key or a battery.

Another embodiment of the present invention is a method for manufacturing a semiconductor device, which includes the steps of: forming a gate electrode over a substrate; forming a gate insulating film over the gate electrode; forming an oxide semiconductor film over the gate insulating film; forming a conductive film over the oxide semiconductor film to form a region having oxygen vacancies in the oxide semiconductor film; processing the conductive film to form a pair of electrodes; and removing the region of the oxide semiconductor film, which is between the pair of electrodes and has the oxygen vacancies, with a chemical solution or a gas supplied from above the oxide semiconductor film and the pair of electrodes.

Another embodiment of the present invention is a method for manufacturing a semiconductor device, which includes the steps of: forming a gate electrode over a substrate; forming a gate insulating film over the gate electrode; forming an oxide semiconductor film over the gate insulating film; forming a conductive film over the oxide semiconductor film to form a region having oxygen vacancies in the oxide semiconductor film; processing the conductive film to form a pair of electrodes; removing the region of the oxide semiconductor film, which is between the pair of electrodes and has the oxygen vacancies, with a chemical solution or a gas supplied from above the oxide semiconductor film and the pair of electrodes; forming an oxide insulating film over the oxide semiconductor film and the pair of electrodes; and adding oxygen to the oxide insulating film.

In any of the above embodiments, the conductive film is preferably formed with a sputtering apparatus. In any of the above embodiments, the conductive film is preferably formed with the power density of greater than or equal to 1 W/cm² and less than or equal to 4 W/cm².

With one embodiment of the present invention, a change in electrical characteristics can be inhibited and reliability can be improved in a semiconductor device including an oxide semiconductor film. With one embodiment of the present invention, a semiconductor device with lower power consumption can be provided. With one embodiment of the present invention, a novel semiconductor device or a novel method for manufacturing a semiconductor device can be provided. With one embodiment of the present invention, a novel display device can be provided.

Note that the description of these effects does not disturb the existence of other effects. One embodiment of the present invention does not necessarily have all the effects listed above. Other effects will be apparent from and can be derived from the description of the specification, the drawings, the claims, and the like.

### BRIEF DESCRIPTION OF THE DRAWINGS

FIGS. 1A to 1C are a top view and cross-sectional views illustrating one embodiment of a semiconductor device.

FIGS. 2A and 2B are cross-sectional views each illustrating one embodiment of a semiconductor device.

FIGS. 3A to 3C are a top view and cross-sectional views illustrating one embodiment of a semiconductor device.

FIGS. 4A and 4B are cross-sectional views illustrating one embodiment of a semiconductor device.

FIGS. 5A to 5D are cross-sectional views illustrating embodiments of a semiconductor device.

FIGS. 6A and 6B are cross-sectional views each illustrating one embodiment of a semiconductor device.

FIGS. 7A and 7B are band diagrams.

FIGS. 8A and 8B are schematic views each showing a concept when current flows in an oxide semiconductor film.

FIG. 9A is a schematic view of a band structure, and FIG. 9B is a band diagram.

FIGS. 10A and 10B show results of reliability tests performed on transistors.

FIG. 11 shows calculation results of the electron density distributions in the transistors.

FIGS. 12A to 12C are cross-sectional views of an example of a manufacturing process of a semiconductor device;

FIGS. 13A to 13C are cross-sectional views of an example of a manufacturing process of a semiconductor device.

FIGS. 14A to 14C are cross-sectional views of an example of a manufacturing process of a semiconductor device.

FIGS. 15A and 15B are cross-sectional views of an example of a manufacturing process of a semiconductor device;

FIGS. 16A and 16B each show a thermal profile of heat treatment in a gas baking furnace;

FIGS. 17A and 17B each show a thermal profile of heat treatment in a gas baking furnace;

FIGS. 18A to 18D are cross-sectional views illustrating an example of a manufacturing process of a semiconductor device.

FIGS. 19A to 19D are cross-sectional views illustrating an example of a manufacturing process of a semiconductor device.

FIGS. 20A to 20D are Cs-corrected high-resolution TEM images of a cross section of a CAAC-OS and a cross-sectional schematic view of the CAAC-OS;

FIGS. 21A to 21D are Cs-corrected high-resolution TEM images of a plane of a CAAC-OS.

FIGS. 22A to 22C show structural analysis of a CAAC-OS and a single crystal oxide semiconductor by XRD;

FIGS. 23A and 23B show electron diffraction patterns of a CAAC-OS;

FIG. 24 shows a change of crystal parts of an In—Ga—Zn oxide owing to electron irradiation.

FIGS. 25A to 25C illustrate a deposition method of a CAAC-OS.

FIG. 26 illustrates a crystal structure of InMZnO₄.

FIGS. 27A to 27E illustrate a deposition method of a CAAC-OS;

FIGS. 28A to 28C illustrate a deposition method of a CAAC-OS.

FIG. 29 illustrates a deposition method of an nc-OS.

FIGS. 30A to 30C are a block diagram and circuit diagrams illustrating a display device.

FIGS. 31A and 31B are perspective views illustrating an example of a touch panel.

FIGS. 32A and 32B are cross-sectional views illustrating examples of a display device.

FIG. 33 is a cross-sectional view illustrating an example of a touch sensor;

FIGS. 34A and 35B are cross-sectional views illustrating examples of a touch panel.

FIGS. 35A and 35B are a block diagram and a timing chart of a touch sensor.

FIG. 36 is a circuit diagram of a touch sensor;

FIG. 37 illustrates a circuit structure in a semiconductor device.

FIG. 38A is a diagram showing a configuration of a pixel circuit, and FIG. 38B is a timing chart illustrating the operation of the pixel circuit.

FIG. 39 illustrates a display module.

FIGS. 40A to 40G illustrate electronic devices.

FIG. 41 illustrates a structure of a deposition apparatus.

FIGS. 42A to 42D are a cross-sectional view illustrating samples in Example and cross-sectional views illustrating a fabrication process of the samples in Example.

FIGS. 43A and 43B show results of sheet resistance measurement and results of ESR measurement, respectively.

FIGS. 44A to 44C are a top view and cross-sectional views illustrating a transistor.

FIGS. 45A and 45B show results of reliability tests performed on transistors in Example.

FIGS. 46A and 46B are cross-sectional TEM images of a transistor in Example.

FIGS. 47A and 47B are cross-sectional TEM images of a transistor in Example.

FIG. 48 is a top view showing observation portions of cross sections in Example.

FIG. 49 shows cross-sectional TEM images of a transistor in Example.

FIG. 50 shows cross-sectional TEM images of a transistor in Example.

FIGS. 51A and 51B show probability distribution of the on-state current of transistors and probability distribution of the threshold voltage of the transistors, respectively.

FIG. 52 shows results of reliability tests performed on transistors in Example.

FIG. 53 shows the deterioration rate of the on-state current of transistors with respect to stress time.

### DETAILED DESCRIPTION OF THE INVENTION

Hereinafter, embodiments will be described with reference to drawings. However, the embodiments can be implemented with various modes. It will be readily appreciated by those skilled in the art that modes and details can be changed in various ways without departing from the spirit and scope of the present invention. Thus, the present invention should not be interpreted as being limited to the following description of the embodiments and the examples.

In the drawings, the size, the layer thickness, or the region is exaggerated for clarity in some cases. Therefore, embodiments of the present invention are not limited to such a scale. Note that the drawings are schematic views showing ideal examples, and embodiments of the present invention are not limited to shapes or values shown in the drawings.

Note that the ordinal numbers such as “first”, “second”, and the like in this specification and the like are used for convenience and do not denote the order of steps or the stacking order of layers. Therefore, for example, description can be made even when “first” is replaced with “second” or “third”, as appropriate. In addition, the ordinal numbers in this specification and the like are not necessarily the same as those which specify one embodiment of the present invention.

Note that in this specification, terms for describing arrangement, such as “over” “above”, “under”, and “below”, are used for convenience in describing a positional relation between components with reference to drawings. Further, the positional relation between components is changed as appropriate in accordance with a direction in which each component is described. Thus, there is no limitation on terms used in this specification, and description can be made appropriately depending on the situation.

The “semiconductor device” in this specification and the like means all devices which can operate by utilizing semiconductor characteristics. A semiconductor element such as a transistor, a semiconductor circuit, an arithmetic device, and a memory device are each an embodiment of a semiconductor device. An imaging device, a display device, a liquid crystal display device, a light-emitting device, an electro-optical device, a power generation device (including a thin film solar cell, an organic thin film solar cell, and the like), and an electronic appliance may each include a semiconductor device.

In this specification and the like, a transistor is an element having at least three terminals of a gate, a drain, and a source. In addition, the transistor has a channel region between a drain (a drain terminal, a drain region, or a drain electrode) and a source (a source terminal, a source region, or a source electrode), and current can flow through the drain region, the channel region, and the source region. Note that in this specification and the like, a channel region refers to a region through which current mainly flows.

Further, functions of a source and a drain might be switched when transistors having different polarities are employed or a direction of current flow is changed in circuit operation, for example. Therefore, the terms “source” and “drain” can be switched in this specification and the like.

Note that in this specification and the like, the expression “electrically connected” includes the case where components are connected through an “object having any electric function”. There is no particular limitation on an “object having any electric function” as long as electric signals can be transmitted and received between components that are connected through the object. Examples of an “object having any electric function” are a switching element such as a transistor, a resistor, an inductor, a capacitor, and elements with a variety of functions as well as an electrode and a wiring.

Note that in this specification and the like, a silicon oxynitride film refers to a film in which the proportion of oxygen is higher than that of nitrogen. The silicon oxynitride film preferably contains oxygen, nitrogen, silicon, and hydrogen in the ranges of 55 atomic % to 65 atomic %, 1 atomic % to 20 atomic %, 25 atomic % to 35 atomic %, and 0.1 atomic % to 10 atomic %, respectively. A silicon nitride oxide film refers to a film in which the proportion of nitrogen is higher than that of oxygen. The silicon nitride oxide film preferably contains nitrogen, oxygen, silicon, and hydrogen in the ranges of 55 atomic % to 65 atomic %, 1 atomic % to 20 atomic %, 25 atomic % to 35 atomic %, and 0.1 atomic % to 10 atomic %, respectively.

In this specification and the like, the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

In this specification, the tenn “parallel” indicates that the angle formed between two straight lines is greater than or equal to −10° and less than or equal to 10°, and accordingly also includes the case where the angle is greater than or equal to −5° and less than or equal to 5°. In addition, the term “substantially parallel” indicates that the angle formed between two straight lines is greater than or equal to −30° and less than or equal to 30°. In addition, the term “perpendicular” indicates that the angle formed between two straight lines is greater than or equal to 80° and less than or equal to 100°, and accordingly also includes the case where the angle is greater than or equal to 85° and less than or equal to 95°. A term “substantially perpendicular” indicates that the angle formed between two straight lines is greater than or equal to 60° and less than or equal to 120°.

### Embodiment 1

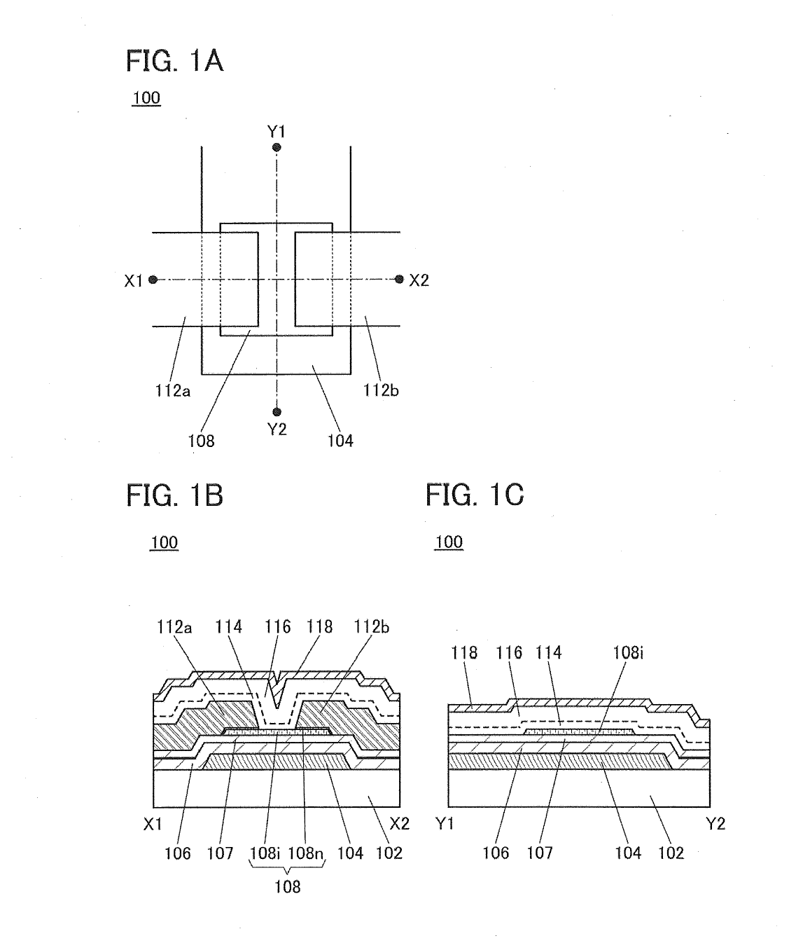

In this embodiment, a semiconductor device that is one embodiment of the present invention and a method for manufacturing the semiconductor device are described with reference to FIGS. 1A to 1C, FIGS. 2A and 2B, FIGS. 3A to 3C, FIGS. 4A and 4B, FIGS. 5A to 5D, FIGS. 6A and 6B, FIGS. 7A and 7B, FIGS. 8A and 8B, FIGS. 9A and 9B, FIGS. 10A and 10B, FIG. 11, FIGS. 12A to 12C, FIGS. 13A to 13C, FIGS. 14A to 14C, FIGS. 15A and 15B, and FIGS. 16A and 16B, FIGS. 17A and 17B,

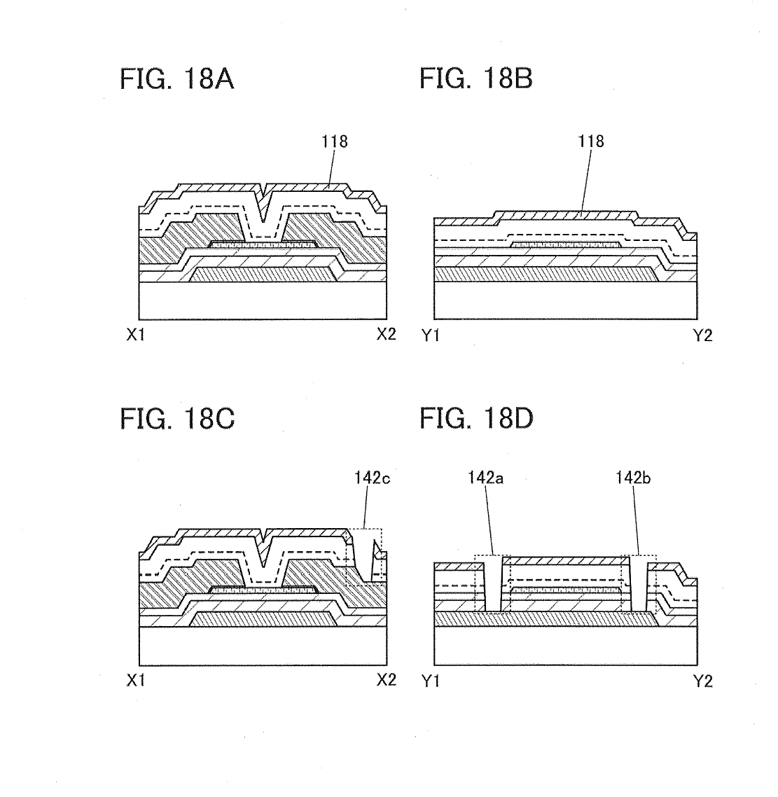

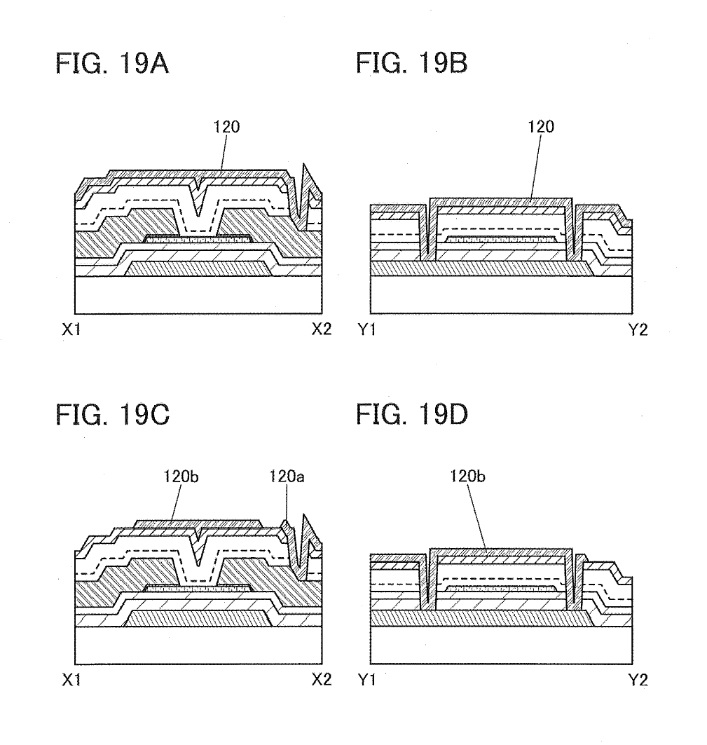

FIGS. 18A to 18D, and FIGS. 19A to 19D

### STRUCTURAL EXAMPLE 1 OF SEMICONDUCTOR DEVICE

FIG. 1A is a top view of a transistor 100 that is a semiconductor device of one embodiment of the present invention. FIG. 1B is a cross-sectional view taken along a dashed dotted line X1-X2 in FIG. 1A, and FIG. 1C is a cross-sectional view taken along a dashed dotted line Y1-Y2 in FIG. 1A. Note that in FIG. 1A, some components of the transistor 100 (e.g., an insulating film serving as a gate insulating film) are not illustrated to avoid complexity. Furthermore, the direction of the dashed dotted line X1-X1 may be called a channel length direction, and the direction of the dashed dotted line Y1-Y2 may be called a channel width direction. As in FIG. 1A, some components are not illustrated in some cases in top views of transistors described below.

The transistor 100 includes a conductive film 104 functioning as a gate electrode over a substrate 102, an insulating film 106 over the substrate 102 and the conductive film 104, an insulating film 107 over the insulating film 106, an oxide semiconductor film 108 over the insulating film 107, and conductive films 112a and 112b functioning as source and drain electrodes electrically connected to the oxide semiconductor film 108. Over the transistor 100, specifically, over the conductive films 112a and 112b and the oxide semiconductor film 108, insulating films 114, 116, and 118 are provided. The insulating films 114, 116, and 118 function as protective insulating films for the transistor 100.

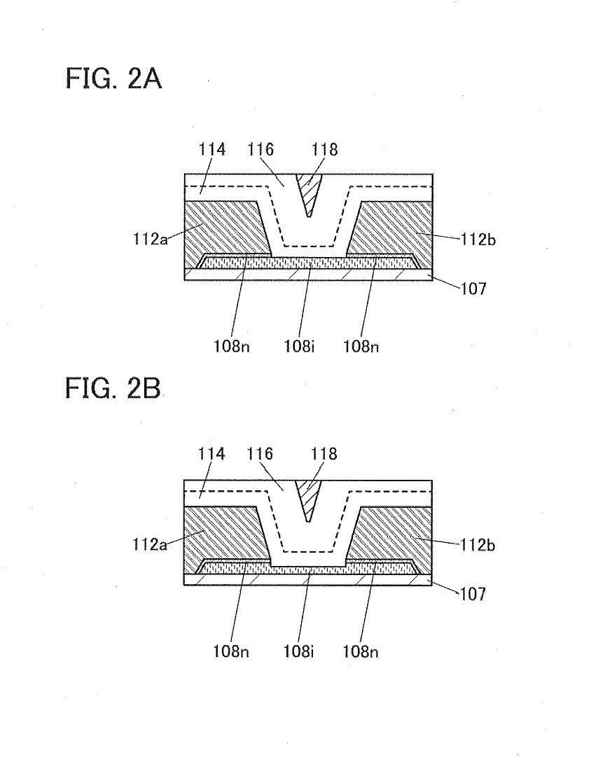

Here, the oxide semiconductor film 108 will be described with reference to FIGS. 2A and 2B. FIGS. 2A and 2B are each an enlarged view of the vicinity of the oxide semiconductor film 108 in FIG. 1B.

As illustrated in FIG. 1B and FIGS. 2A and 2B, the oxide semiconductor film 108 includes a channel region 108i and n-type regions 108n. The channel region 108i is a region between the conductive films 112a and 112b serving as a source electrode and a drain electrode. The n-type regions 108n are formed in regions in contact with the conductive films 112a and 112b serving as a source electrode and a drain electrode.

Note that FIG. 2A illustrates a structure in which an upper surface of the channel region 108i is substantially level with bottom surfaces of the n-type regions 108n, and FIG. 2B illustrates a structure in which the upper surface of the channel region 108i is lower than the bottom surfaces of the n-type regions 108n. The channel region 108i may have either the shape of FIG. 2A or the shape of FIG. 2B.

When impurities such as hydrogen or moisture enters the channel region 108i included in the oxide semiconductor film 108, the impurities are bonded to oxygen vacancies formed in the oxide semiconductor film 108, producing electrons serving as carriers. The carriers due to the impurities tend to make the transistor 100 be normally on. Therefore, for stable transistor characteristics, it is important to reduce impurities such as hydrogen or moisture in the channel region 108i included in the oxide semiconductor film 108 and to reduce oxygen vacancies in the channel region 108i included in the oxide semiconductor film 108. It is preferable that the resistances of the n-type regions 108n included in the oxide semiconductor film 108 be lower because the n-type regions 108n are in contact with and electrically connected to the conductive films 112a and 112b serving as a source electrode and a drain electrode. Therefore, in a structure of a transistor of one embodiment of the present invention, oxygen vacancies are formed in the n-type regions 108n included in the oxide semiconductor film 108, and hydrogen is bonded to the oxygen vacancies, whereby a low-resistance region is formed. The oxygen vacancies are formed in an upper portion of the oxide semiconductor film 108 in forming a conductive film which is to be the conductive films 112a and 112b serving as a source electrode and a drain electrode. After the conductive films 112a and 112b serving as a source electrode and a drain electrode are formed, a portion over a region which is to be the channel region 108i, in which oxygen vacancies are formed, is removed, and oxygen is moved from the insulating films 114 and 116 to the channel region 108i, whereby oxygen vacancies in the channel region 108i are filled.

With the above structure, the oxide semiconductor film in the channel region 108i can have a low impurity concentration and a low density of defect states (hereinafter, the state in which impurity concentration is low and density of defect states is low (the number of oxygen vacancies is small) is referred to as “highly purified intrinsic” or “substantially highly purified intrinsic”), and the oxide semiconductor film in the n-type regions 108n can have low contact resistance with the conductive films 112a and 112b serving as a source electrode and a drain electrode. Accordingly, a semiconductor device in which a change in electrical characteristics is inhibited can be provided.

The insulating films 114 and 116 each include a region that contains oxygen in excess of that in the stoichiometric composition (oxygen excess region). In other words, the insulating films 114 and 116 are insulating films capable of releasing oxygen. Note that the oxygen excess region is formed in each of the insulating films 114 and 116 in such a manner that oxygen is added to the insulating films 114 and 116 after the deposition, for example. An ion implantation method, an ion doping method, a plasma immersion ion implantation method, plasma treatment, or the like can be used as a method for adding oxygen. Note that for the above plasma treatment, an apparatus with which an oxygen gas is made to be plasma by high-frequency power (also referred to as a plasma etching apparatus or a plasma ashing apparatus) is preferably used.

The amount of released oxygen can be found by measuring an insulating film by thermal desorption spectroscopy (TDS). For example, the amount of released oxygen molecules from the insulating films 114 and 116 is more than or equal to 8.0×10¹⁴ atoms/cm², preferably more than or equal to 1.0×10¹⁵ atoms/cm², and further preferably more than or equal to 1.5×10¹⁵ atoms/cm² by TDS. Note that the surface temperature of the films in TDS is higher than or equal to 100° C. and lower than or equal to 700° C., preferably higher than or equal to 100° C. and lower than or equal to 500° C.

In one embodiment of the present invention, a protective film capable of inhibiting release of oxygen (also simply referred to as a protective film) is formed over the insulating film 116 and oxygen is introduced into the insulating films 114 and 116 through the protective film, so that the oxygen excess region is formed in the insulating films 114 and 116.

For the protective film capable of inhibiting release of oxygen, for example, indium (In) and a material including one of zinc (Zn), tin (Sn), tungsten (W), titanium (Ti), and silicon (Si) can be used. As the protective film, a conductive film including indium or a semiconductor film including indium is particularly preferable. The protective film may be removed after oxygen is introduced. As the conductive film including indium, a light-transmitting conductive material such as indium oxide including tungsten; indium zinc oxide including tungsten; indium oxide including titanium; indium tin oxide including titanium; indium tin oxide (In—Sn oxide, also referred to as ITO); indium zinc oxide (In—Zn oxide); or indium tin oxide including silicon (In—Sn—Si oxide, also referred to as ITSO) can be given. Among the above-described materials, ITSO is particularly preferably used in the protective film capable of inhibiting release of oxygen because it can be deposited over an insulating film having roughness or the like with favorable coverage.

Next, a structure of the transistor 100 illustrated in FIGS. 1A to 1C will be described in more detail.

### <Substrate>

There is no particular limitation on the property of a material and the like of the substrate 102 as long as the material has heat resistance enough to withstand at least heat treatment to be performed later. For example, a glass substrate, a ceramic substrate, a quartz substrate, a sapphire substrate, or the like may be used as the substrate 102. Alternatively, a single crystal semiconductor substrate or a polycrystalline semiconductor substrate made of silicon, silicon carbide, or the like, a compound semiconductor substrate made of silicon germanium or the like, an SOI (silicon on insulator) substrate, or the like may be used as the substrate 102. Still alternatively, any of these substrates provided with a semiconductor element may be used as the substrate 102. In the case where a glass substrate is used as the substrate 102, a glass substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm) Thus, a large-sized display device can be manufactured.

Alternatively, a flexible substrate may be used as the substrate 102, and the transistor 100 may be provided directly on the flexible substrate. Alternatively, a separation layer may be provided between the substrate 102 and the transistor 100. The separation layer can be used when part or the whole of a semiconductor device formed over the separation layer is separated from the substrate 102 and transferred onto another substrate. In such a case, the transistor 100 can be transferred to a substrate having low heat resistance or a flexible substrate as well.

### <Conductive Film>

The conductive film 104 functioning as a gate electrode and the conductive films 112a and 112b functioning as a source electrode and a drain electrode can each be formed using a metal element selected from chromium (Cr), copper (Cu), aluminum (Al), gold (Au), silver (Ag), zinc (Zn), molybdenum (Mo), tantalum (Ta), titanium (Ti), tungsten (W), manganese (Mn), nickel (Ni), iron (Fe), and cobalt (Co); an alloy including any of these metal elements as its component; an alloy including a combination of any of these elements; or the like.

Furthermore, the conductive films 104, 112a, and 112b may have a single-layer structure or a stacked-layer structure of two or more layers. For example, a single-layer structure of an aluminum film containing silicon, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, and the like can be given. Alternatively, an alloy film or a nitride film which contains aluminum and one or more elements selected from titanium, tantalum, tungsten, molybdenum, chromium, neodymium, and scandium may be used.

The conductive films 104, 112a, and 112b can be formed using a light-transmitting conductive material such as indium tin oxide, indium oxide including tungsten oxide, indium zinc oxide including tungsten oxide, indium oxide including titanium oxide, indium tin oxide including titanium oxide, indium zinc oxide, or indium tin oxide to which silicon oxide is added.

A Cu—X alloy film (X is Mn, Ni, Cr, Fe, Co, Mo, Ta, or Ti) may be used for the conductive films 104, 112a, and 112b. Use of a Cu—X alloy film enables the manufacturing cost to be reduced because wet etching process can be used in the processing.

### <Gate Insulating Film>

As each of the insulating films 106 and 107 functioning as a gate insulating film of the transistor 100, an insulating layer including at least one of the following films formed by a plasma enhanced chemical vapor deposition (PECVD) method, a sputtering method, or the like can be used: a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film Note that instead of a stacked structure of the insulating films 106 and 107, an insulating film of a single layer formed using a material selected from the above or an insulating film of three or more layers may be used.

Note that the insulating film 107 that is in contact with the oxide semiconductor film 108 in the transistor 100 is preferably an oxide insulating film and preferably includes a region including oxygen in excess of the stoichiometric composition (oxygen-excess region). In other words, the insulating film 107 is an insulating film which is capable of releasing oxygen. In order to provide the oxygen excess region in the insulating film 107, the insulating film 107 is formed in an oxygen atmosphere, for example. Alternatively, the oxygen excess region may be formed by introduction of oxygen into the insulating film 107 after the deposition. As a method for introducing oxygen, an ion implantation method, an ion doping method, a plasma immersion ion implantation method, plasma treatment, or the like may be employed.

In the case where hafnium oxide is used for the insulating film 107, the following effect is attained. Hafnium oxide has a higher dielectric constant than silicon oxide and silicon oxynitride. Therefore, by using hafnium oxide, the thickness of the insulating film 107 can be made large as compared with the case where silicon oxide is used; thus, leakage current due to tunnel current can be low. That is, it is possible to provide a transistor with a low off-state current. Moreover, hafnium oxide with a crystalline structure has higher dielectric constant than hafnium oxide with an amorphous structure. Therefore, it is preferable to use hafnium oxide with a crystalline structure in order to provide a transistor with a low off-state current. Examples of the crystalline structure include a monoclinic crystal structure and a cubic crystal structure. Note that one embodiment of the present invention is not limited to the above examples.

In this embodiment, a silicon nitride film is formed as the insulating film 106, and a silicon oxide film is formed as the insulating film 107. The silicon nitride film has a higher dielectric constant than a silicon oxide film and needs a larger thickness for capacitance equivalent to that of the silicon oxide film. Thus, when the silicon nitride film is included in the gate insulating film of the transistor, the thickness of the insulating film can be increased. This makes it possible to reduce a decrease in withstand voltage of the transistor 100 and furthermore to increase the withstand voltage, thereby reducing electrostatic discharge damage to the transistor 100.

### <Oxide Semiconductor Film>

The oxide semiconductor film 108 contains In, Zn, and M (M is Ti, Ga, Y, Zr, La, Ce, Nd, Sn, or Hf). Typically, In—Ga oxide, In—Zn oxide, or In-M-Zn oxide can be used for the oxide semiconductor film 108. It is particularly preferable to use In-M-Zn oxide for the semiconductor film 108.

In the case where the oxide semiconductor film 108 includes In-M-Zn oxide, it is preferable that the atomic ratio of metal elements of a sputtering target used for forming the In-M-Zn oxide satisfy In≧M and Zn≧M. As the atomic ratio of metal elements of such a sputtering target, In:M:Zn=1:1:1, In:M:Zn=1:1:1.2, In:M:Zn=2:1:3, In:M:Zn=3:1:2, and In:M:Zn=4:2:4.1 are preferable.

For example, it is preferable that the oxide semiconductor film 108 be formed using an In-M-Zn oxide containing In, Ga, and Zn at the atomic ratio of 4:2:4.1 as a sputtering target, because the field-effect mobility of the transistor can be increased. The transistor having high field-effect mobility can be favorably used in a pixel circuit or a driving circuit of a high-definition display device typified by 4 k×2 k pixels (3840 pixels in the horizontal direction and 2160 pixels in the perpendicular direction) or 8 k×4 k pixels (7680 pixels in the horizontal direction and 4320 pixels in the perpendicular direction).

Note that the atomic ratio of metal elements in the formed oxide semiconductor film 108 varies from the above atomic ratios of metal elements of the sputtering targets in a range of ±40% in some cases. For example, when a sputtering target with an atomic ratio of In to Ga and Zn of 4:2:4.1 is used, the atomic ratio of In to Ga and Zn in the oxide semiconductor film 108 may be 4:2:3 or in the vicinity of 4:2:3.

Alternatively, when a sputtering target with an atomic ratio of In to Ga and Zn of 1:1:1.2 is used, the atomic ratio of In to Ga and Zn in the oxide semiconductor film 108 may be 1:1:1 or in the vicinity of 1:1:1.

Note that in the case where the oxide semiconductor film 108 is formed of In-M-Zn oxide, the proportion of In and the proportion of M, not taking Zn and O into consideration, are preferably greater than 25 atomic % and less than 75 atomic %, respectively, and more preferably greater than 34 atomic % and less than 66 atomic %, respectively.

The energy gap of the oxide semiconductor film 108 is 2 eV or more, preferably 2.5 eV or more, further preferably 3 eV or more. In this manner, the amount of off-state current of a transistor can be reduced by using an oxide semiconductor having a wide energy gap.

The thickness of the oxide semiconductor film 108 is greater than or equal to 3 nm and less than or equal to 200 nm, preferably greater than or equal to 3 nm and less than or equal to 100 nm, further preferably greater than or equal to 3 nm and less than or equal to 50 nm.

Note that, without limitation to those described above, a material with an appropriate composition may be used depending on required semiconductor characteristics and electrical characteristics (e.g., field-effect mobility and threshold voltage) of a transistor. Furthermore, in order to obtain required semiconductor characteristics of a transistor, it is preferable that the carrier density, the impurity concentration, the defect density, the atomic ratio of a metal element to oxygen, the interatomic distance, the density, and the like of the oxide semiconductor film 108 be set to be appropriate.

A highly purified intrinsic or substantially highly purified intrinsic oxide semiconductor film has few carrier generation sources, and thus can have a low carrier density. Thus, a transistor in which a channel region is formed in the oxide semiconductor film rarely has a negative threshold voltage (is rarely normally on). A highly purified intrinsic or substantially highly purified intrinsic oxide semiconductor film has a low density of defect states and accordingly has a low density of trap states in some cases. Furthermore, the highly purified intrinsic or substantially highly purified intrinsic oxide semiconductor film has an extremely low off-state current; even when an element has a channel width of 1×10⁶ μm and a channel length (L) of 10 μm, the off-state current can be less than or equal to the measurement limit of a semiconductor parameter analyzer, i.e., less than or equal to 1×10⁻¹³ A, at a voltage (drain voltage) between a source electrode and a drain electrode of from 1 V to 10 V.

Accordingly, the transistor in which the channel region is formed in the highly purified intrinsic or substantially highly purified intrinsic oxide semiconductor film can have a small variation in electrical characteristics and high reliability. Charges trapped by the trap states in the oxide semiconductor film take a long time to be released and may behave like fixed charges. Thus, the transistor whose channel region is formed in the oxide semiconductor film having a high density of trap states has unstable electrical characteristics in some cases. As examples of the impurities, hydrogen, nitrogen, an alkali metal, an alkaline earth metal, and the like are given.

Hydrogen included in the oxide semiconductor film 108 reacts with oxygen bonded to a metal atom to be water, and also causes an oxygen vacancy in a lattice from which oxygen is released (or a portion from which oxygen is released). Due to entry of hydrogen into the oxygen vacancy, an electron serving as a carrier is sometimes generated. Furthermore, in some cases, bonding of part of hydrogen to oxygen bonded to a metal atom causes generation of an electron serving as a carrier. Thus, a transistor including an oxide semiconductor film which contains hydrogen is likely to be normally on. Accordingly, it is preferable that hydrogen be reduced as much as possible in the oxide semiconductor film 108. Specifically, the hydrogen concentration of the oxide semiconductor film 108, which is measured by secondary ion mass spectrometry (SIMS), is lower than or equal to 2×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, even further preferably lower than or equal to 5×10¹⁷ atoms/cm³, and further preferably lower than or equal to 1×10¹⁶ atoms/cm³.

When silicon or carbon that is one of elements belonging to Group 14 is contained in the oxide semiconductor film 108, oxygen vacancies are increased in the oxide semiconductor film 108, and the oxide semiconductor film 108 becomes an n-type film. Thus, the concentration of silicon or carbon (the concentration is measured by SIMS) in the oxide semiconductor film 108 or the concentration of silicon or carbon (the concentration is measured by SIMS) in the vicinity of an interface between the oxide semiconductor film 108 and an adjacent film is set to be lower than or equal to 2×10¹⁸ atoms/cm³, preferably lower than or equal to 2×10¹⁷ atoms/cm³.

In addition, the concentration of an alkali metal or an alkaline earth metal of the oxide semiconductor film 108, which is measured by SIMS, is lower than or equal to 1×10¹⁸ atoms/cm³, preferably lower than or equal to 2×10¹⁶ atoms/cm³. An alkali metal and an alkaline earth metal might generate carriers when bonded to an oxide semiconductor, in which case the off-state current of the transistor might be increased. Therefore, it is preferable to reduce the concentration of an alkali metal or an alkaline earth metal of the oxide semiconductor film 108.

Furthermore, when containing nitrogen, the oxide semiconductor film 108 easily becomes n-type by generation of electrons serving as carriers and an increase of carrier density. Thus, a transistor including an oxide semiconductor film which contains nitrogen is likely to have normally-on characteristics. For this reason, nitrogen in the oxide semiconductor film is preferably reduced as much as possible; the concentration of nitrogen which is measured by SIMS is preferably set, for example, lower than or equal to 5×10¹⁸ atoms/cm³.

An oxide semiconductor which can be used for the oxide semiconductor film 108 will be described in detail in Embodiment 2.

### <Protective Insulating Film>

The insulating films 114, 116, and 118 function as a protective insulating film. The insulating films 114 and 116 include oxygen, and the insulating film 118 includes nitrogen. Furthermore, the insulating film 114 is an insulating film that allows oxygen to pass through. Note that the insulating film 114 also functions as a film which relieves damage to the oxide semiconductor film 108 at the time of forming the insulating film 116 in a later step.

A silicon oxide film or a silicon oxynitride film with a thickness greater than or equal to 5 nm and less than or equal to 150 nm, preferably greater than or equal to 5 nm and less than or equal to 50 nm can be used as the oxide insulating film 114.

Further, it is preferable that the amount of defects in the oxide insulating film 114 be small; as a typical example, the spin density of a signal that appears at g=2.001 due to a dangling bond of silicon is preferably lower than or equal to 3×10¹⁷ spins/cm³ by electron spin resonance (ESR) measurement. This is because if the density of defects in the insulating film 114 is high, oxygen is bonded to the defects and the amount of oxygen that transmits the insulating film 114 is decreased.

Note that all oxygen entering the insulating film 114 from the outside does not move to the outside of the insulating film 114 and some oxygen remains in the insulating film 114. Furthermore, movement of oxygen occurs in the insulating film 114 in some cases in such a manner that oxygen enters the insulating film 114 and oxygen contained in the insulating film 114 moves to the outside of the insulating film 114. When an oxide insulating film which can transmit oxygen is formed as the insulating film 114, oxygen released from the insulating film 116 provided over the insulating film 114 can be moved to the oxide semiconductor film 108 through the insulating film 114.

Note that the insulating film 114 can be formed using an oxide insulating film having a low density of states due to nitrogen oxide. Note that the density of states due to nitrogen oxide can be formed between the energy of the valence band maximum (Eᵥ_{_}ₒₛ) and the energy of the conduction band minimum (E_{c}_{_}ₒₛ) of the oxide semiconductor film. A silicon oxynitride film that releases less nitrogen oxide, an aluminum oxynitride film that releases less nitrogen oxide, and the like can be used as the above oxide insulating film.

Note that a silicon oxynitride film that releases a small amount of nitrogen oxide is a film of which the amount of released ammonia is larger than the amount of released nitrogen oxide in thermal desorption spectroscopy analysis; the amount of released ammonia is typically greater than or equal to 1×10¹⁸/cm³ and less than or equal to 5×10¹⁹/cm³. Note that the amount of released ammonia is the amount of ammonia released by heat treatment with which the surface temperature of the film becomes a temperature higher than or equal to 50° C. and lower than or equal to 650° C., preferably higher than or equal to 50° C. and lower than or equal to 550° C.

Nitrogen oxide (NOₓ; x is greater than or equal to 0 and less than or equal to 2, preferably greater than or equal to 1 and less than or equal to 2), typically NO₂ or NO, forms levels in the insulating film 114, for example. The level is positioned in the energy gap of the oxide semiconductor film 108. Therefore, when nitrogen oxide is diffused to the vicinity of the interface between the insulating film 114 and the oxide semiconductor film 108, an electron is in some cases trapped by the level on the insulating film 114 side. As a result, the trapped electron remains in the vicinity of the interface between the insulating film 114 and the oxide semiconductor film 108; thus, the threshold voltage of the transistor is shifted in the positive direction.

Nitrogen oxide reacts with ammonia and oxygen in heat treatment. Since nitrogen oxide included in the insulating film 114 reacts with ammonia included in the insulating film 116 in heat treatment, nitrogen oxide included in the insulating film 114 is reduced. Therefore, an electron is hardly trapped at the vicinity of the interface between the insulating film 114 and the oxide semiconductor film 108.

By using such an oxide insulating film, the insulating film 114 can reduce the shift in the threshold voltage of the transistor, which leads to a smaller change in the electrical characteristics of the transistor.

Note that in an ESR spectrum at 100 K or lower of the insulating film 114, by heat treatment of a manufacturing process of the transistor, typically heat treatment at a temperature higher than or equal to 300° C. and lower than the strain point of the substrate, a first signal that appears at a g-factor of greater than or equal to 2.037 and less than or equal to 2.039, a second signal that appears at a g-factor of greater than or equal to 2.001 and less than or equal to 2.003, and a third signal that appears at a g-factor of greater than or equal to 1.964 and less than or equal to 1.966 are observed. The split width of the first and second signals and the split width of the second and third signals that are obtained by ESR measurement using an X-band are each approximately 5 mT. The sum of the spin densities of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 is lower than 1×10¹⁸ spins/cm³, typically higher than or equal to 1×10¹⁷ spins/cm³ and lower than 1×10¹⁸ spins/cm³.

In the ESR spectrum at 100 K or lower, the first signal that appears at a g-factor of greater than or equal to 2.037 and smaller than or equal to 2.039, the second signal that appears at a g-factor of greater than or equal to 2.001 and smaller than or equal to 2.003, and the third signal that appears at a g-factor of greater than or equal to 1.964 and smaller than or equal to 1.966 correspond to signals attributed to nitrogen oxide (NOₓ; x is greater than or equal to 0 and smaller than or equal to 2, preferably greater than or equal to 1 and smaller than or equal to 2). Typical examples of nitrogen oxide include nitrogen monoxide and nitrogen dioxide. In other words, the lower the total spin density of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 is, the smaller amount of nitrogen oxide the oxide insulating film contains.

The concentration of nitrogen of the oxide insulating film measured by SIMS is lower than or equal to 6×10²⁰ atoms/cm³.

The above oxide insulating film is formed by a PECVD method at a substrate temperature higher than or equal to 220° C., higher than or equal to 280° C., or higher than or equal to 350° C. using silane and dinitrogen monoxide, whereby a dense and hard film can be formed.

The insulating film 116 is formed using an oxide insulating film that contains oxygen at a higher proportion than oxygen in the stoichiometric composition. Part of oxygen is released by heating from the oxide insulating film that contains oxygen at a higher proportion than oxygen in the stoichiometric composition. The oxide insulating film that contains oxygen at a higher proportion than oxygen in the stoichiometric composition is an oxide insulating film of which the amount of released oxygen converted into oxygen atoms is greater than or equal to 8.0×10¹⁴ atoms/cm², preferably greater than or equal to 1.0×10¹⁵ atoms/cm² in TDS analysis. Note that the temperature of the film surface in the IDS analysis is preferably higher than or equal to 100° C. and lower than or equal to 700° C., or higher than or equal to 100° C. and lower than or equal to 500° C.

A silicon oxide film or a silicon oxynitride film with a thickness greater than or equal to 30 nm and less than or equal to 500 nm, preferably greater than or equal to 50 nm and less than or equal to 400 nm can be used as the insulating film 116.

It is preferable that the amount of defects in the insulating film 116 be small, and typically the spin density of a signal which appears at g=2.001 due to a dangling bond of silicon, be lower than 1.5×10¹⁸ spins/cm³, further preferably lower than or equal to 1×10¹⁸ spins/cm³ by ESR measurement. Note that the insulating film 116 is provided more apart from the oxide semiconductor film 108 than the insulating film 114 is; thus, the insulating film 116 may have higher defect density than the insulating film 114.

Further, the insulating films 114 and 116 can be formed using insulating films formed of the same kinds of materials; thus, a boundary between the insulating films 114 and 116 cannot be clearly observed in some cases. Thus, in this embodiment, the boundary between the insulating films 114 and 116 is shown by a dashed line. Although a two-layer structure of the insulating films 114 and 116 is described in this embodiment, the present invention is not limited to this structure. For example, a single-layer structure of either one of the insulating films 114 and 116 may be employed.

The insulating film 118 includes nitrogen. Alternatively, the insulating film 118 includes nitrogen and silicon. The insulating film 118 has a function of blocking oxygen, hydrogen, water, an alkali metal, an alkaline earth metal, or the like. It is possible to prevent outward diffusion of oxygen from the oxide semiconductor film 108, outward diffusion of oxygen included in the insulating films 114 and 116, and entry of hydrogen, water, or the like into the oxide semiconductor film 108 from the outside by providing the insulating film 118. A nitride insulating film, for example, can be used as the insulating film 118. The nitride insulating film is formed using silicon nitride, silicon nitride oxide, aluminum nitride, aluminum nitride oxide, or the like. Note that instead of the nitride insulating film having a blocking effect against oxygen, hydrogen, water, an alkali metal, an alkaline earth metal, and the like, an oxide insulating film having a blocking effect against oxygen, hydrogen, water, and the like, may be provided. As the oxide insulating film having a blocking effect against oxygen, hydrogen, water, and the like, an aluminum oxide film, an aluminum oxynitride film, a gallium oxide film, a gallium oxynitride film, an yttrium oxide film, an yttrium oxynitride film, a hafnium oxide film, and a hafnium oxynitride film can be given.

Note that the above-described various films such as the conductive films, the insulating films, and the oxide semiconductor film can be formed by a sputtering method, a chemical vapor deposition (CVD) method, a vacuum evaporation method, a pulsed laser deposition (PLD) method, or the like. Alternatively, the above-described various films can be formed by a plasma enhanced chemical vapor deposition (PECVD) method, a thermal CVD method, or an atomic layer deposition (ALD) method. As an example of the thermal CVD method, a metal organic chemical vapor deposition (MOCVD) method can be given. Further alternatively, the above-described various films can be formed by a coating method or a printing method.

A thermal CVD method has an advantage that no defect due to plasma damage is generated since it does not utilize plasma for forming a film.

Deposition over a substrate by a thermal CVD method may be performed in such a manner that a source gas and an oxidizer are supplied to a chamber at a time, the pressure inside the chamber is set to an atmospheric pressure or a reduced pressure, and the source gas and the oxidizer react with each other in the vicinity of the substrate or over the substrate.

Deposition by an ALD method may be performed in such a manner that the pressure inside a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves). For example, a first source gas is introduced, an inert gas (e.g., argon or nitrogen) or the like is introduced at the same time as or after the introduction of the first source gas so that the source gases are not mixed, and then a second source gas is introduced. Note that in the case where the first source gas and the inert gas are introduced at a time, the inert gas serves as a carrier gas, and the inert gas may also be introduced at the same time as the introduction of the second source gas. Alternatively, the first source gas may be exhausted by vacuum evacuation instead of the introduction of the inert gas, and then the second source gas may be introduced. The first source gas is adsorbed on the surface of the substrate to form a first layer; then the second source gas is introduced to react with the first layer; as a result, a second layer is stacked over the first layer, so that a thin film is formed. The sequence of the gas introduction is repeated a plurality of times until a desired thickness is obtained, whereby a thin film with excellent step coverage can be formed. The thickness of the thin film can be adjusted by the number of repetition times of the sequence of the gas introduction; therefore, an ALD method makes it possible to accurately adjust a thickness and thus is suitable for manufacturing a minute FET.

The variety of films such as the conductive films, the insulating films, the oxide semiconductor film, and the metal oxide film in this embodiment can be formed by an ALD method or a thermal CVD method such as an MOCVD method. For example, in the case where an In—Ga—Zn—O film is formed, trimethylindium, trimethylgallium, and dimethylzinc are used. Note that the chemical formula of trimethylindium is In(CH₃)₃. The chemical formula of trimethylgallium is Ga(CH₃)₃. The chemical formula of dimethylzinc is Zn(CH₃)₂. Without limitation to the above combination, triethylgallium (chemical formula: Ga(C₂H₅)₃) can be used instead of trimethylgallium and diethylzinc (chemical formula: Zn(C₂H₅)₂) can be used instead of dimethylzinc.

For example, in the case where a hafnium oxide film is formed by a deposition apparatus using an ALD method, two kinds of gases, that is, ozone (O₃) as an oxidizer and a source gas which is obtained by vaporizing a liquid containing a solvent and a hafnium precursor compound (e.g., a hafnium alkoxide or a hafnium amide such as tetrakis(dimethylamide)hafnium (TDMAH)) are used. Note that the chemical formula of tetrakis(dimethylamide)hafnium is Hf[N(CH₃)₂]₄. Examples of another material liquid include tetrakis(ethylmethylamide)hafnium.

For example, in the case where an aluminum oxide film is formed by a deposition apparatus using an ALD method, two kinds of gases, e.g., H₂O as an oxidizer and a source gas which is obtained by vaporizing a liquid containing a solvent and an aluminum precursor compound (e.g., trimethylaluminum (TMA)) are used. Note that the chemical formula of trimethylaluminum is Al(CH₃)₃. Examples of another material liquid include tris(dimethylamide)aluminum, triisobutylaluminum, and aluminum tris(2,2,6,6-tetramethyl-3,5-heptanedionate).

For example, in the case where a silicon oxide film is formed with a deposition apparatus using an ALD method, hexachlorodisilane is adsorbed on a surface where a film is to be formed, chlorine included in the adsorbate is removed, and radicals of an oxidizing gas (e.g., O₂ or dinitrogen monoxide) are supplied to react with the adsorbate.

For example, in the case where a tungsten film is formed with a deposition apparatus that uses an ALD method, a WF₆ gas and a B₂H₆ gas are used to form an initial tungsten film, and then a WF₆ gas and an H₂ gas are used to form a tungsten film

For example, in the case where an oxide semiconductor film, e.g., an In—Ga—Zn—O film is formed with a deposition apparatus that uses an ALD method, an In(CH₃)₃ gas and an O₃ gas are used to form an InO layer, then a Ga(CH₃)₃ gas and an O₃ gas are used to form a GaO layer, and then a Zn(CH₃)₂ gas and an O₃ gas are used to form a ZnO layer. Note that the order of these layers is not limited to this example.

A mixed compound layer such as an In—Ga—O layer, an In—Zn—O layer, or a Ga—Zn—O layer may be formed by mixing these gases. Note that although an H₂O gas which is obtained by bubbling with an inert gas such as Ar may be used instead of an O₃ gas, it is preferable to use an O₃ gas, which does not contain H. Furthermore, instead of an In(CH₃)₃ gas, an In(C₂H₅)₃ gas may be used. Instead of a Ga(CH₃)₃ gas, a Ga(C₂H₅)₃ gas may be used. Furthermore, a Zn(CH₃)₂ gas may be used.

### STRUCTURAL EXAMPLE 2 OF SEMICONDUCTOR DEVICE

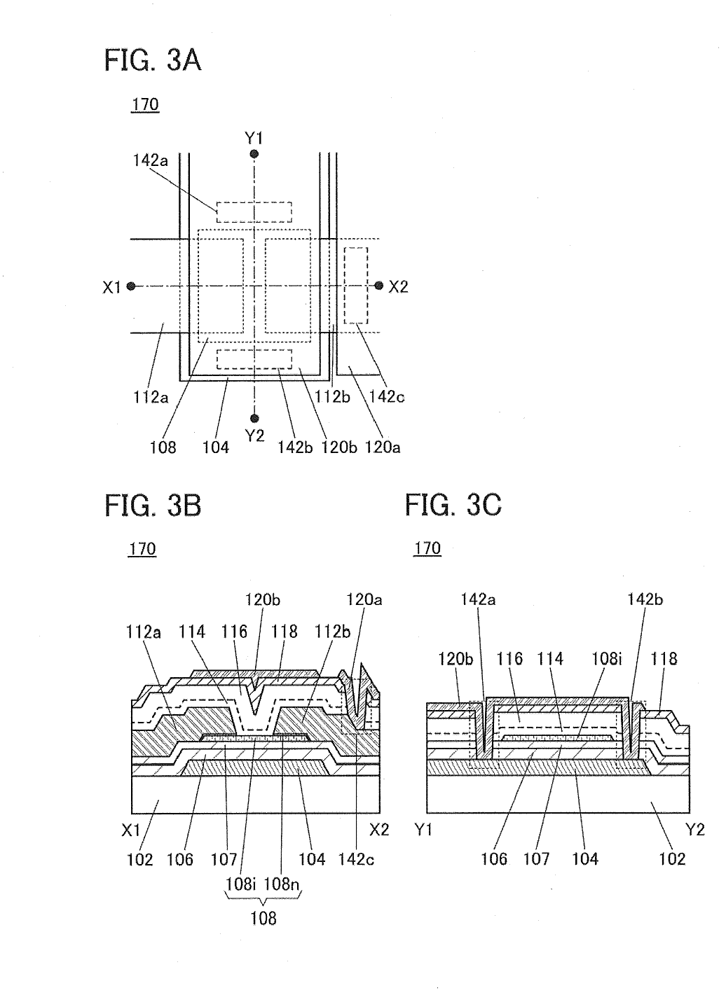

A structure example different from that of the transistor 100 in FIGS. 1A to 1C is described with reference to FIGS. 3A to 3C. Note that in the case where a portion has a function similar to that described above, the same hatch pattern is applied to the portion, and the portion is not especially denoted by a reference numeral in some cases.

FIG. 3A is a plan view of a transistor 170 that is a semiconductor device of one embodiment of the present invention. FIG. 3B is a cross-sectional view taken along dashed-dotted line X1-X2 illustrated in FIG. 3A, and FIG. 3C is a cross-sectional view taken along dashed-dotted line Y1-Y2 in FIG. 3A.

The transistor 170 includes the conductive film 104 functioning as a first gate electrode over the substrate 102, the insulating film 106 over the substrate 102 and the conductive film 104, the insulating film 107 over the insulating film 106, the oxide semiconductor film 108 over the insulating film 107, the conductive film 112a functioning as a source electrode electrically connected to the oxide semiconductor film 108, the conductive film 112b functioning as a drain electrode electrically connected to the oxide semiconductor film 108, the insulating film 114 over the oxide semiconductor film 108 and the conductive films 112a and 112b, the insulating film 116 over the insulating film 114, the insulating film 118 over the insulating film 116, and conductive films 120a and 120b over the insulating film 118.

In the transistor 170, the oxide semiconductor film 108 includes the channel region 108i and the n-type regions 108n as in the transistor 100 described above. In the oxide semiconductor film 108, the channel region 108i can be a highly purified intrinsic oxide semiconductor film in which oxygen vacancies are reduced, and the n-type regions can be an oxide semiconductor film having low contact resistance with the conductive films 112a and 112b serving as a source electrode and a drain electrode. Accordingly, a semiconductor device in which a change in electrical characteristics is inhibited can be provided.

Furthermore, the insulating films 106 and 107 function as a first gate insulating film of the transistor 170. The insulating films 114, 116, and 118 collectively function as a second gate insulating film of the transistor 170. The conductive film 120a functions as, for example, a pixel electrode used in a display device. The conductive film 120a is connected to the conductive film 112b through an opening 142c provided in the insulating films 114, 116, and 118. The conductive film 120b functions as a second gate electrode (also referred to as a back gate electrode).

As illustrated in FIG. 3C, the conductive film 120b is connected to the conductive film 104 functioning as a first gate electrode through openings 142a and 142b provided in the insulating films 106, 107, 114, 116, and 118. Accordingly, the conductive film 120b and the conductive film 104 are supplied with the same potential.

Note that although the structure in which the openings 142a and 142b are provided so that the conductive film 120b and the conductive film 104 are connected to each other is described in this embodiment, one embodiment of the present invention is not limited thereto. For example, a structure in which only one of the openings 142a and 142b is provided so that the conductive film 120b and the conductive film 104 are connected to each other, or a structure in which the openings 142a and 142b are not provided and the conductive film 120b and the conductive film 104 are not connected to each other may be employed. Note that in the case where the conductive film 120b and the conductive film 104 are not connected to each other, it is possible to apply different potentials to the conductive film 120b and the conductive film 104.

As illustrated in FIG. 3B, the oxide semiconductor film 108 is positioned to face the conductive film 104 that functions as a first gate electrode and the conductive film 120b that functions as the second gate electrode, and is sandwiched between the two conductive films each of which functions as a gate electrode. The lengths in the channel length direction and the channel width direction of the conductive film 120b functioning as a second gate electrode are longer than those in the channel length direction and the channel width direction of the oxide semiconductor film 108. The whole oxide semiconductor film 108 is covered with the conductive film 120b with the insulating films 114, 116, and 118 positioned therebetween. Since the conductive film 120b functioning as a second gate electrode is connected to the conductive film 104 functioning as a first gate electrode through the opening 142a and 142b provided in the insulating films 106, 107, 114, 116, and 118, a side surface of the oxide semiconductor film 108 in the channel width direction faces the conductive film 120b functioning as a second gate electrode with the insulating films 114, 116, and 118 positioned therebetween.

In other words, in the channel width direction of the transistor 170, the conductive film 104 functioning as a first gate electrode and the conductive film 120b functioning as a second gate electrode are connected to each other through the openings provided in the insulating films 106 and 107 functioning as first gate insulating films, and the insulating films 114, 116, and 118 functioning as second gate insulating films; and the conductive film 104 and the conductive film 120b surround the oxide semiconductor film 108 with the insulating films 106 and 107 functioning as first gate insulating films, and the insulating films 114, 116, and 118 functioning as second gate insulating films positioned therebetween.

Such a structure makes it possible that the oxide semiconductor film 108 included in the transistor 170 is electrically surrounded by electric fields of the conductive film 104 functioning as a first gate electrode and the conductive film 120b functioning as a second gate electrode. A device structure of a transistor, like that of the transistor 170, in which electric fields of a first gate electrode and a second gate electrode electrically surround an oxide semiconductor film where a channel region is formed can be referred to as a surrounded channel (s-channel) structure.

Since the transistor 170 has the s-channel structure, an electric field for inducing a channel can be effectively applied to the oxide semiconductor film 108 by the conductive film 104 functioning as a first gate electrode; therefore, the current drive capability of the transistor 170 can be improved and high on-state current characteristics can be obtained. Since the on-state current can be increased, it is possible to reduce the size of the transistor 170. In addition, since the transistor 170 is surrounded by the conductive film 104 functioning as a first gate electrode and the conductive film 120b functioning as a second gate electrode, the mechanical strength of the transistor 170 can be increased.

### STRUCTURAL EXAMPLE 3 OF SEMICONDUCTOR DEVICE

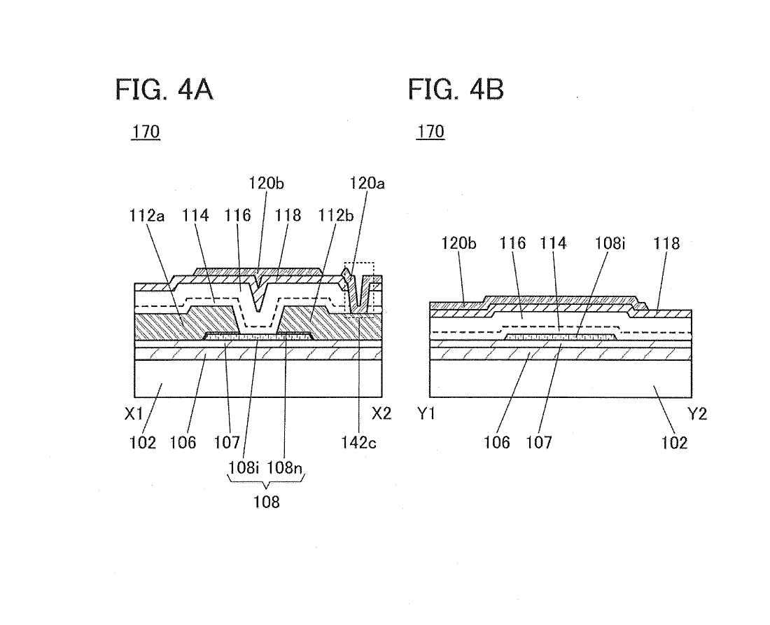

Structure examples different from that of the transistor 170 in FIGS. 3A to 3C are described with reference to FIGS. 4A and 4B. Note that in the case where a portion has a function similar to that described above, the same hatch pattern is applied to the portion, and the portion is not especially denoted by a reference numeral in some cases.

FIG. 4A is a cross-sectional view taken along dashed-dotted line X1-X2 of FIG. 3A, and FIG. 4B is a cross-sectional view taken along dashed-dotted line Y1-Y2 of FIG. 3A.

The transistor 170 illustrated in FIGS. 4A and 4B does not include the conductive film 104 functioning as a gate electrode of the transistor 170 illustrated in FIGS. 3B and 3C. That is, the transistor 170 illustrated in FIGS. 4A and 4B includes, above the oxide semiconductor film 108, the conductive film 120b functioning as a gate electrode. In other words, the transistor 170 in FIGS. 4A and 4B is a single-gate transistor having a top-gate structure.

### STRUCTURE EXAMPLE 4 OF SEMICONDUCTOR DEVICE

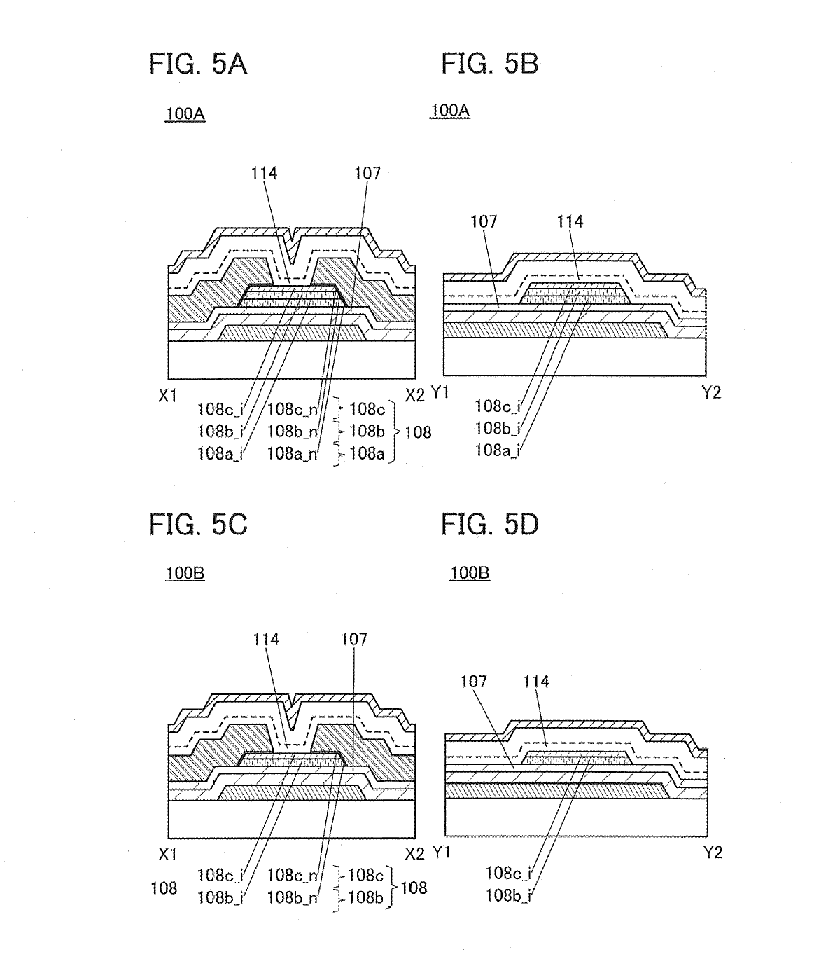

A structure example different from that of the transistor 100 in FIGS. 1A to 1C is described with reference to FIGS. 5A to 5D. Note that in the case where a portion has a function similar to that described above, the same hatch pattern is applied to the portion, and the portion is not especially denoted by a reference numeral in some cases.

FIGS. 5A, 5B, 5C, and 5D are cross-sectional views of modification examples of the transistor 100 in FIGS. 1B and 1C.

A transistor 100A in FIGS. 5A and 5B has the same structure as the transistor 100 in FIGS. 1B and 1C except that the oxide semiconductor film 108 has a three-layer structure. Specifically, the oxide semiconductor film 108 of the transistor 100A includes an oxide semiconductor film 108a, an oxide semiconductor film 108b, and an oxide semiconductor film 108c. The oxide semiconductor film 108a includes a high-purity region 108a_i and n-type regions 108a_n. The oxide semiconductor film 108b includes a channel region 108b_i and n-type regions 108b_n. The oxide semiconductor film 108c includes a high-purity region 108c_i and n-type regions 108c_n.

A transistor 100B in FIGS. 5C and SD has the same structure as the transistor 100 in FIGS. 1B and 1C except that the oxide semiconductor film 108 has a two-layer structure. Specifically, the oxide semiconductor film 108 of the transistor 100B includes the oxide semiconductor film 108b and the oxide semiconductor film 108c. The oxide semiconductor film 108b includes the channel region 108b_i and the n-type regions 108b_n. The oxide semiconductor film 108c includes the high-purity region 108c_i and the n-type regions 108c_n.

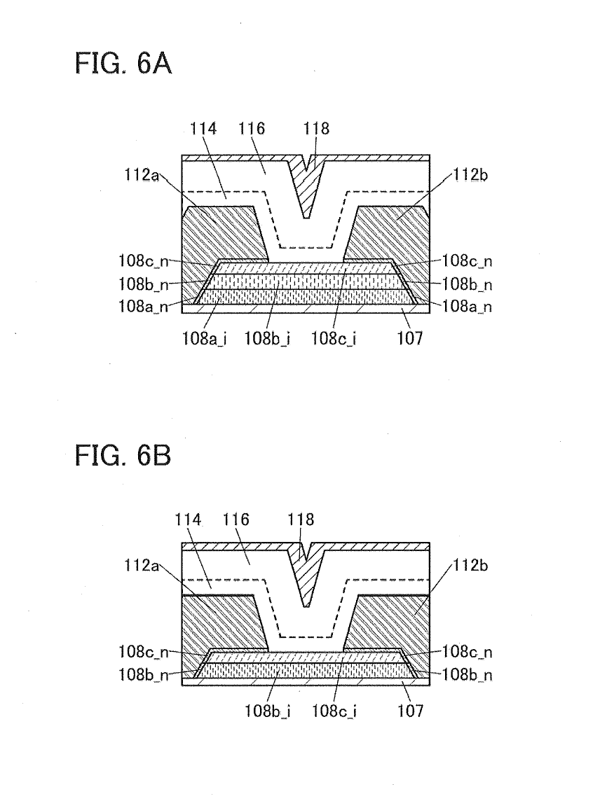

Note that FIG. 6A is an enlarged view of the vicinity of the oxide semiconductor film 108 in FIG. 5A, and FIG. 6B is an enlarged view of the vicinity of the oxide semiconductor film 108 in FIG. 5C.

As illustrated in FIGS. 6A and 6B, the oxide semiconductor film 108 includes the high-purity region 108a_i, the channel region 108b_i, and the high-purity region 108c_i. The channel region 108b_i is a region between the conductive films 112a and 112b serving as a source electrode and a drain electrode. The n-type regions 108a_n, 108b_n, and 108c_n are formed in regions in contact with the conductive films 112a and 112b serving as a source electrode and a drain electrode.

In the oxide semiconductor film 108 in the transistor 100A, the high-purity region 108a_i, the channel region 108b_i, and the high-purity region 108c_i can each be a highly purified intrinsic oxide semiconductor in which oxygen vacancies are reduced, and the n-type regions 108a_n, 108b_n, and 108c_n can be an oxide semiconductor film having low contact resistance with the conductive films 112a and 112b serving as a source electrode and a drain electrode. Accordingly, a semiconductor device in which a change in electrical characteristics is inhibited can be provided.

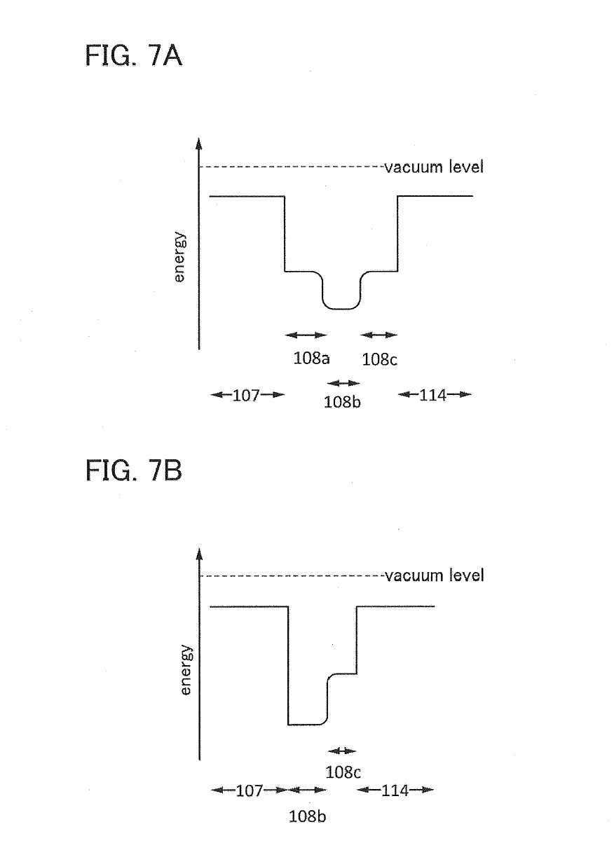

Here, a band structure including the oxide semiconductor films 108a, 108b, and 108c and the insulating films in contact with the oxide semiconductor films 108a, 108b, and 108c is described with reference to FIGS. 7A and 7B.

FIG. 7A shows an example of a band structure in the thickness direction of a stack including the insulating film 107, the oxide semiconductor films 108a, 108b, and 108c, and the insulating film 114. FIG. 7B shows an example of a band structure in the thickness direction of a stack including the insulating film 107, the oxide semiconductor films 108b and 108c, and the insulating film 114. For easy understanding, energy level of the conduction band minimum (Ec) of each of the insulating film 107, the oxide semiconductor films 108a, 108b, and 108c, and the insulating film 114 is shown in the band structures.

In the band structure of FIG. 7A, a silicon oxide film is used as each of the insulating films 107 and 114, an oxide semiconductor film formed using a metal oxide target having an atomic ratio of metal elements of In:Ga:Zn=1:3:2 is used as the oxide semiconductor film 108a, an oxide semiconductor film formed using a metal oxide target having an atomic ratio of metal elements of In:Ga:Zn=1:1:1 is used as the oxide semiconductor film 108b, and an oxide semiconductor film formed using a metal oxide target having an atomic ratio of metal elements of In:Ga:Zn=1:3:2 is used as the oxide semiconductor film 108c.

In the band structure of FIG. 7B, a silicon oxide film is used as each of the insulating films 107 and 114, an oxide semiconductor film formed using a metal oxide target having an atomic ratio of metal elements of In:Ga:Zn=1:1:1 is used as the oxide semiconductor film 108b, and a metal oxide film formed using a metal oxide target having an atomic ratio of metal elements of In:Ga:Zn=1:3:2 is used as the oxide semiconductor film 108c.

As illustrated in FIGS. 7A and 7B, the energy level of the conduction band minimum gradually varies between the oxide semiconductor film 108a and the oxide semiconductor film 108b and between the oxide semiconductor film 108b and the oxide semiconductor film 108c. In other words, the energy level at the bottom of the conduction band is continuously varied or continuously connected. To obtain such a band structure, there exists no impurity, which forms a defect state such as a trap center or a recombination center, at the interface between the oxide semiconductor film 108a and the oxide semiconductor film 108b or at the interface between the oxide semiconductor film 108b and the oxide semiconductor film 108c.

To form a continuous junction between the oxide semiconductor film 108a and the oxide semiconductor film 108b and between the oxide semiconductor film 108b and the oxide semiconductor film 108c, it is necessary to form the films successively without exposure to the air by using a multi-chamber deposition apparatus (sputtering apparatus) provided with a load lock chamber.

With the band structure of FIG. 7A or FIG. 7B, the oxide semiconductor film 108b serves as a well, and a channel region is formed in the oxide semiconductor film 108b in the transistor with the stacked-layer structure. The provision of the oxide semiconductor film 108a and/or the oxide semiconductor film 108c enables the oxide semiconductor film 108b to be distanced away from trap states.

In addition, the trap states might be more distant from the vacuum level than the energy level of the conduction band minimum (Ec) of the oxide semiconductor film 108b functioning as a channel region, so that electrons are likely to be accumulated in the trap states. When the electrons are accumulated in the trap states, the electrons become negative fixed electric charge, so that the threshold voltage of the transistor is shifted in the positive direction. Therefore, it is preferable that the energy level of the trap states be closer to the vacuum level than the energy level of the conduction band minimum (Ec) of the oxide semiconductor film 108b. Such a structure inhibits accumulation of electrons in the trap states. As a result, the on-state current and the field-effect mobility of the transistor can be increased.

In FIGS. 7A and 7B, the energy level of the conduction band minimum of each of the oxide semiconductor films 108a and 108c is closer to the vacuum level than that of the oxide semiconductor film 108b. Typically, a difference in energy level between the conduction band minimum of the oxide semiconductor film 108b and the conduction band minimum of each of the oxide semiconductor films 108a and 108c is 0.15 eV or more or 0.5 eV or more and 2 eV or less or 1 eV or less. That is, the difference between the electron affinity of each of the oxide semiconductor films 108a and 108c and the electron affinity of the oxide semiconductor film 108b is 0.15 eV or more or 0.5 eV or more and 2 eV or less or 1 eV or less.

In such a structure, the oxide semiconductor film 108b serves as a main path of current and functions as a channel region. In addition, since the oxide semiconductor films 108a and 108c each contain one or more metal elements that are the same as those contained in the oxide semiconductor film 108b in which a channel region is formed, interface scattering is less likely to occur at the interface between the oxide semiconductor film 108a and the oxide semiconductor film 108b or at the interface between the oxide semiconductor film 108b and the oxide semiconductor film 108c. Thus, the transistor can have high field-effect mobility because the movement of carriers is not hindered at the interface.

To prevent each of the oxide semiconductor films 108a and 108c from functioning as part of a channel region, a material having sufficiently low conductivity is used for the oxide semiconductor films 108a and 108c. Alternatively, a material which has a smaller electron affinity (a difference in energy level between the vacuum level and the conduction band minimum) than the oxide semiconductor film 108b and has a difference in energy level in the conduction band minimum from the oxide semiconductor film 108b (band offset) is used for the oxide semiconductor films 108a and 108c. Furthermore, to inhibit generation of a difference between threshold voltages due to the value of the drain voltage, it is preferable to form the oxide semiconductor films 108a and 108c using a material whose energy level of the conduction band minimum is closer to the vacuum level than that of the oxide semiconductor film 108b by 0.2 eV or more, preferably 0.5 eV or more.

It is preferable that the oxide semiconductor films 108a and 108c not have a spinel crystal structure. This is because if the oxide semiconductor films 108a and 108c have a spinel crystal structure, constituent elements of the conductive films 112a and 112b might be diffused to the oxide semiconductor film 108b at the interface between the spinel crystal structure and another region. Note that each of the oxide semiconductor films 108a and 108c is preferably a CAAC-OS, which will be described later, in which case a higher blocking property against constituent elements of the conductive films 112a and 112b, for example, copper elements, is obtained.

The thickness of each of the oxide semiconductor films 108a and 108c is greater than or equal to a thickness that is capable of inhibiting diffusion of the constituent elements of the conductive films 112a and 112b to the oxide semiconductor film 108b, and less than a thickness that inhibits supply of oxygen from the insulating film 114 to the oxide semiconductor film 108b. For example, when the thickness of each of the oxide semiconductor films 108a and 108c is greater than or equal to 10 nm, diffusion of the constituent elements of the conductive films 112a and 112b to the oxide semiconductor film 108b can be inhibited. When the thickness of each of the oxide semiconductor films 108a and 108c is less than or equal to 100 nm, oxygen can be effectively supplied from the insulating films 114 and 116 to the oxide semiconductor film 108b.

When the oxide semiconductor films 108a and 108c are each an In-M-Zn oxide in which the atomic ratio of the element M (M is Ti, Ga, Y, Zr, La, Ce, Nd, Sn, or Hf) is higher than that of In, the energy gap of each of the oxide semiconductor films 108a and 108c can be large and the electron affinity thereof can be small. Therefore, a difference in electron affinity between the oxide semiconductor film 108b and each of the oxide semiconductor films 108a and 108c may be controlled by the proportion of the element M Furthermore, an oxygen vacancy is less likely to be generated in the oxide semiconductor layer in which the atomic ratio of Ti, Ga, Y, Zr, La, Ce, Sn, Nd, or Hf is higher than that of In because Ti, Ga, Y, Zr, La, Ce, Sn, Nd, and Hf are each a metal element that is strongly bonded to oxygen.

When an In-M-Zn oxide is used for the oxide semiconductor films 108a and 108c, the proportions of In and M, not taking Zn and O into consideration, are as follows: the atomic percentage of In is preferably less than 50 atomic % and the atomic percentage of M is greater than 50 atomic % and further preferably the atomic percentage of In is less than 25 atomic % and the atomic percentage of M is greater than 75 atomic %. Alternatively, a gallium oxide film may be used as each of the oxide semiconductor films 108a and 108c.

Furthermore, in the case where each of the oxide semiconductor films 108a, 108b, and 108c is an In-M-Zn oxide, the proportion of M atoms in each of the oxide semiconductor films 108a and 108c is higher than that in the oxide semiconductor film 108b. Typically, the proportion of M atoms in each of the oxide semiconductor films 108a and 108c is 1.5 or more times, preferably twice or more times, and further preferably three or more times as high as that in the oxide semiconductor film 108b.

Furthermore, in the case where the oxide semiconductor films 108a, 108b, and 108c are each an In-M-Zn oxide, when the oxide semiconductor film 108b has an atomic ratio of In:M:Zn=x₁:y₁:z₁ and the oxide semiconductor films 108a and 108c each have an atomic ratio of In:M:Zn=x₂:y₂:z₂, y₂/x₂ is larger than y₁/x₁, preferably y₂/x₂ is 1.5 or more times as large as y₁/x₁, further preferably, y₂/x₂ is two or more times as large as y₁/x₁, or still further preferably y₂/x₂ is three or more times or four or more times as large as y₁/x₁. In this case, it is preferable that in the oxide semiconductor film 108b, y₁ be higher than or equal to x₁ because a transistor including the oxide semiconductor film 108b can have stable electric characteristics. However, when y₁ is three or more times as large as x₁, the field-effect mobility of the transistor including the oxide semiconductor film 108b is reduced. Accordingly, y₁ is preferably smaller than three times x₁.

In the case where the oxide semiconductor film 108b is an In-M-Zn oxide and a target having the atomic ratio of metal elements of In:M:Zn=x₁:y₁:z₁ is used for depositing the oxide semiconductor film 108b, x₁/y₁ is preferably greater than or equal to ⅓ and less than or equal to 6, and further preferably greater than or equal to 1 and less than or equal to 6, and z₁/y₁ is preferably greater than or equal to ⅓ and less than or equal to 6, and further preferably greater than or equal to 1 and less than or equal to 6. Note that when z₁/y₁ is greater than or equal to 1 and less than or equal to 6, a CAAC-OS to be described later is easily formed as the oxide semiconductor film 108b. Typical examples of the atomic ratio of the metal elements of the target include In:M:Zn=1:1:1, In:M:Zn=1:1:1.2, and In:M:Zn=3:1:2.

In the case where the oxide semiconductor films 108a and 108c are each an In-M-Zn oxide and a target having an atomic ratio of metal elements of In:M:Zn=x₂:y₂:z₂ is used for depositing the oxide semiconductor films 108a and 108c, x₂/y₂ is preferably less than x₁/y₁, and z₂/y₂ is preferably greater than or equal to ⅓ and less than or equal to 6, and further preferably greater than or equal to 1 and less than or equal to 6. When the atomic ratio of M with respect to indium is high, the energy gap of the oxide semiconductor films 108a and 108c can be large and the electron affinity thereof can be small; therefore, y₂/x₂ is preferably higher than or equal to 3 or higher than or equal to 4. Typical examples of the atomic ratio of the metal elements of the target include In:M:Zn=1:3:2, In:M:Zn=1:3:4, In:M:Zn=1:3:5, In:M:Zn=1:3:6, In:M:Zn=1:4:2, In:M:Zn=1:4:4, In:M:Zn=1:4:5, and In:M:Zn=1:5:5.

Furthermore, in the case where the oxide semiconductor films 108a and 108c are each an In-M oxide, when a divalent metal element (e.g., zinc) is not included as M, the oxide semiconductor films 108a and 108c which do not include a spinel crystal structure can be formed. As each of the oxide semiconductor films 108a and 108c, for example, an In—Ga oxide film can be used. The In—Ga oxide can be formed by a sputtering method using an In—Ga metal oxide target (In:Ga=7:93), for example. To deposit the oxide semiconductor films 108a and 108c by a sputtering method using DC discharge, on the assumption that an atomic ratio of In:M is x:y, it is preferable that y/(x+y) be less than or equal to 0.96, and further preferably less than or equal to 0.95, for example, 0.93.

In each of the oxide semiconductor films 108a, 108b, and 108c, the proportions of the atoms in the above atomic ratio vary within a range of ±40% as an error.

### <Concept of Stacked-Layer Structure of Oxide Semiconductor Film>

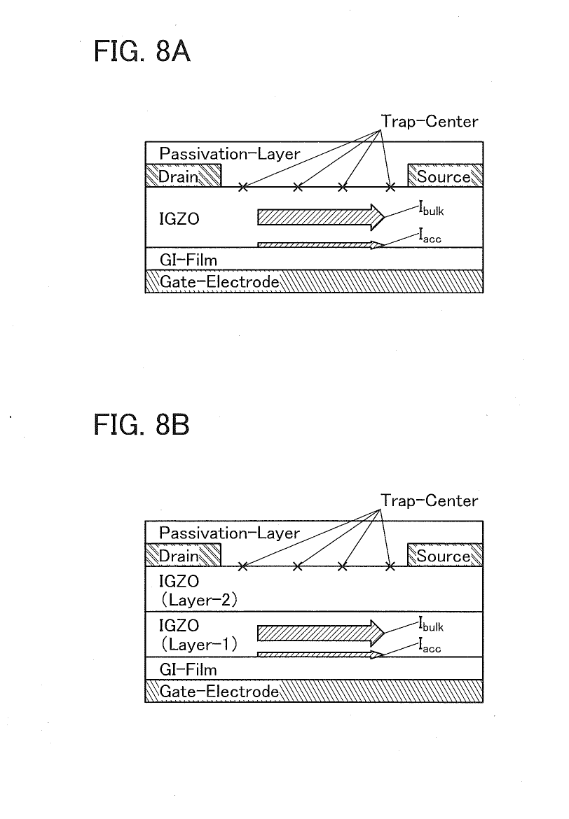

Next, in order to evaluate a stacked-layer structure of the oxide semiconductor films described above, a variety of kinds of verification were performed. First, the concept of the stacked-layer structure of the oxide semiconductor films will be described with reference to FIGS. 8A and 8B.

FIGS. 8A and 8B are each a schematic view of a concept when current flows in the oxide semiconductor film. FIG. 8A illustrates the case where the oxide semiconductor film has a single-layer structure, and FIG. 8B illustrates the case where the oxide semiconductor film has a stacked-layer structure.

Note that in FIG. 8A, the gate electrode, the gate insulating film, the oxide semiconductor film, the source electrode, the drain electrode, the protective insulating film, the trap state, the bulk current, and the accumulation current are referred to as “Gate-Electrode”, “GI-Film”, “IGZO”, “Source”, “Drain”, “Passivation-Layer”, “Trap-Center”, “I_{bulk}”, and “I_{acc}”, respectively. In FIG. 8B, the lower oxide semiconductor film and the upper oxide semiconductor film are referred to as “IGZO (Layer-1)” and “IGZO (Layer-2)”, respectively.

In a channel-etched FET, a wiring process is performed with a back channel exposed, which may cause a change in characteristics due to impurity contamination or damage in processing such as etching of a wiring. Furthermore, as illustrated in FIG. 8A, an OS-FET is operated by the accumulation of electrons that are majority carriers. There is a bulk current that is represented by the following formulae and flows in the entire oxide semiconductor film in addition to the accumulation current on the GI-Film side.

$$\begin{matrix}[ Formula 1 ] & \\ {I}_{on} = {I}_{bulk} + {I}_{acc} ( {V}_{G} > {V}_{D} + {V}_{th} ) & ( 1 ) \\ [ Formula 2 ] & \\ \{ \begin{matrix}{I}_{bulk} = \frac{W}{L} {μ}_{b} {eN}_{d} {t}_{s} {V}_{D} \\ {I}_{acc} = \frac{W}{L} {μ}_{s} {C}_{OX} [ ( {V}_{G} - {V}_{FB} ) {V}_{D} - \frac{{V}_{D}^{2}}{2} ]\end{matrix} & ( 2 )\end{matrix}$$

In the formulae (1) and (2), Iₒₙ, I_{bulk}, I_{acc}, V_{G}, V_{D}, and Vₜₕ represent the on-state current, the bulk current, the accumulation current, the gate voltage, the drain current, and the threshold voltage, respectively. In Formula (2), μ_{b}, μₛ, Cₒₓ, V_{FB}, and N_{d} represent the bulk mobility, the surface mobility, the GI capacitance, the flat band voltage, and the donor density, respectively.

As described above, in the case where a trap state exists on a back channel side, carriers are trapped easily.

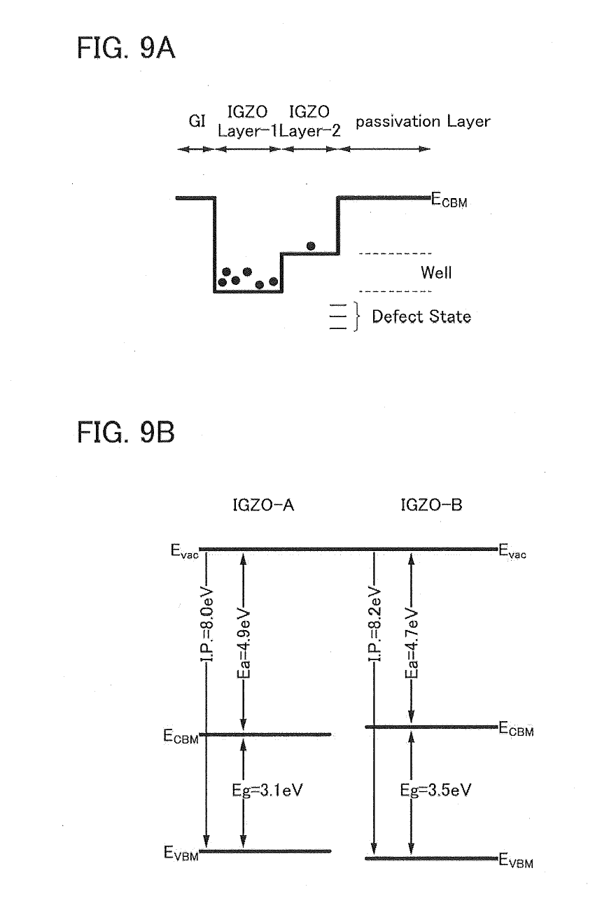

Therefore, as illustrated in FIG. 8B, by forming a film in which IGZO films having different compositions are stacked, the band structure of FIG. 9A can be obtained. Note that FIG. 9A is a model diagram of the band structure. As illustrated in FIG. 8B and FIG. 9A, the IGZO films having different compositions are stacked, and a well is formed at the energy level of the bottom of the conduction band (E_{CBM}), whereby current flowing on the back channel side can be suppressed, and influence of the electron traps existing in the vicinity of an interface between the protective insulating film and the oxide semiconductor film can be suppressed.

Next, in order to confirm whether a well can be formed at the energy level of the bottom of the conduction band (E_{CBM}) by formation of the stacked film of the IGZO films, the following evaluation was performed.

The ionization potentials and the energy gaps of the lower IGZO film containing In, Ga, and Zn at the atomic ratio of 1:1:1.2 (hereinafter, referred to as IGZO-A) and the upper IGZO film containing In, Ga, and Zn at the atomic ratio of 1:3:2 (hereinafter, referred to as IGZO-B) were measured. Note that the ionization potentials were measured by ultraviolet photoelectron spectroscopy (UPS), and the energy gaps were measured by a spectroscopic ellipsometry.

FIG. 9B is a band diagram of the IGZO films. Note that in FIG. 9B, I.P., Ea, and Eg represent an ionization potential, an electron affinity, and an energy gap, respectively.

As shown in FIG. 9B, I.P. (A), Ea (A), and Eg (A) of the IGZO-A were 8.0 eV 4.9 eV, and 3.1 eV, respectively, and I.P. (B), Ea (B), and Eg (B) of the IGZO-B were 8.2 eV, 4.7 eV, and 3.5 eV, respectively. That is, Eg of the IGZO-B was larger than that of the IGZO-A, and it was confirmed that a well with ΔE_{CBM} (Ea (A)−Ea (B)) of approximately 0.2 eV was formed.

Next, a transistor (a single-layer structure of IGZO-A) corresponding to the transistor 100 illustrated FIGS. 1A to 1C and a transistor (a stacked-layer structure of IGZO-A and IGZO-B) corresponding to the transistor 100B illustrated in FIGS. 5C and 5D were fabricated, and the reliability of the transistors was measured. Note that the size of each of the transistors was L/W=6 μm/50 μm.

The reliability of the transistors was measured by Positive Bias Temperature Stress (PBTS) test. Note that the PBTS test was performed under the following conditions: the gate voltage (Vg) was +30 V, the drain voltage (Vd) and the source voltage (Vs) were 0V (COMMON), the stress temperature was 60° C., and the stress application time was 3600 seconds, and the measurement environment was a dark environment. In other words, the source electrode and the drain electrode of each of the transistors were set at the same potential, and a potential different from that of the source and drain electrodes was applied to the gate electrode for a certain time. The potential supplied to the gate electrode was higher than that of the source electrode and the drain electrode.

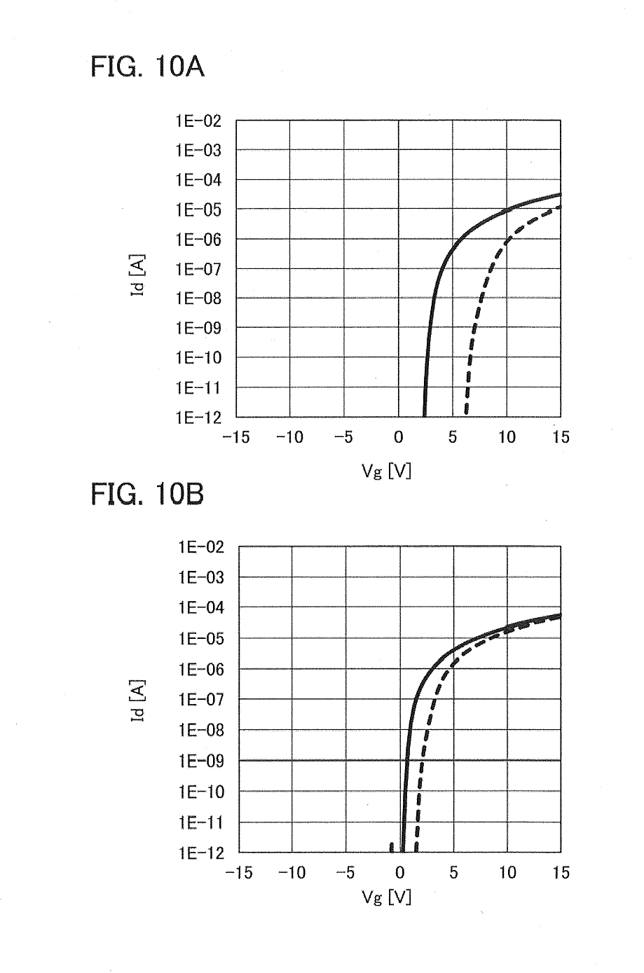

Results of the reliability tests are shown in FIGS. 10A and 10B.

Note that FIGS. 10A and 10B show a result of the single-layer structure of IGZO-A and a result of the stacked-layer structure of IGZO-A and IGZO-B, respectively. In FIGS. 10A and 10B, the solid line indicates the initial electric characteristics, and the dashed line indicates the electric characteristics after the reliability test.

From the result shown in FIG. 10A, in the single-layer structure of IGZO-A, the amount of change in the threshold voltage (ΔVth) was 4.4 V. From the result shown in FIG. 10B, in the stacked-layer structure of IGZO-A and IGZO-B, the amount of change in the threshold voltage (ΔVth) was 1.5 V. Thus, the amount of change in the threshold voltage (ΔVth) before and after the PBTS stress test can be suppressed in the IGZO films having a stacked structure more than in the IGZO film having a single-layer structure.

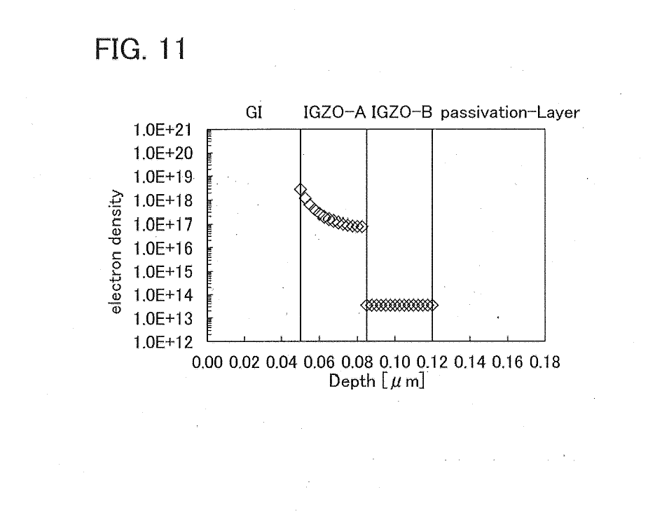

Next, the electron density distributions in the transistors were calculated on the basis of the physical properties of IGZO-A and IGZO-B. The physical properties used for the calculation are shown in Table 1, and the calculation results are shown in FIG. 11.

TABLE 1

| | IGZO-A | IGZO-B |
|---|---|---|
| thickness[nm] | 35 | 35 |
| electron mobility[cm²/Vs] | 10 | 0.1 |
| hole mobility[cm²/Vs] | 0.01 | 0.01 |
| Eg[eV] | 3.2 | 3.6 |
| electorn affinity[V] | 4.8 | 4.6 |
| εr | 15 | 15 |

As shown in FIG. 11, by forming the well of ΔE_{CBM}=0.2 eV, the electron density of a back channel side (IGZO-B) is reduced by three or more orders of magnitude as compared to the electron density of a channel side (IGZO-A). From the calculation results, it was found that hardly any current flows on the back channel side (IGZO-B).

According to the results shown in FIGS. 10A and 10B and FIG. 11, with the IGZO films having a stacked-layer structure, the electron density on the back channel side is reduced and the IGZO films are less likely to be affected by an electron trap, and thus the amount of change in the threshold voltage (ΔVth) before and after the PBTS stress test was suppressed.

The structures of the transistors of this embodiment can be freely combined with each other.

### <Method 1 for Manufacturing Semiconductor Device>

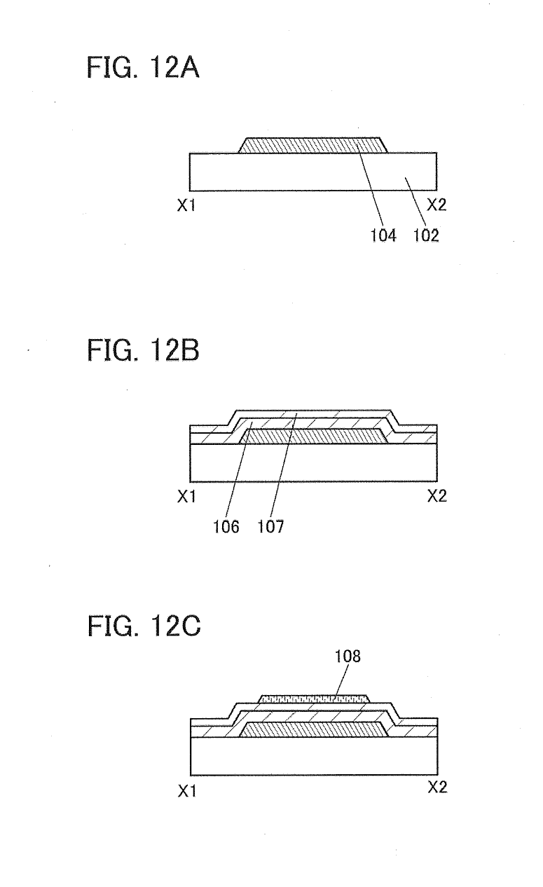

Next, a method for manufacturing the transistor 100 that is a semiconductor device of one embodiment of the present invention will be described with reference to FIGS. 12A to 12C, FIGS. 13A to 13C, FIGS. 14A to 14C, and FIGS. 15A and 15B. Note that FIGS. 12A to 12C, FIGS. 13A to 13C, FIGS. 14A to 14C, and FIGS. 15A and 15B are cross-sectional views illustrating the method for manufacturing the semiconductor device.

### <Step of Forming Gate Electrode>

First, a conductive film is formed over the substrate 102 and processed through a lithography process and an etching process, whereby the conductive film 104 functioning as a gate electrode is formed (see FIG. 12A).

In this embodiment, a glass substrate is used as the substrate 102, and as the conductive film 104 functioning as a gate electrode, a 100-nm-thick tungsten film is formed by a sputtering method.

### <Step of Forming Gate Insulating Film>

Then, the insulating films 106 and 107 functioning as gate insulating films are formed over the conductive film 104 (see FIG. 12B).

In this embodiment, a 400-nm-thick silicon nitride film as the insulating film 106 and a 50-nm-thick silicon oxynitride film as the insulating film 107 are formed by a PECVD method.

The insulating film 106 has a stacked-layer structure of silicon nitride films. Specifically, the insulating film 106 can have a three-layer stacked-layer structure of a first silicon nitride film, a second silicon nitride film, and a third silicon nitride film. An example of the three-layer stacked-layer structure can be formed as follows.

For example, the first silicon nitride film can be formed to have a thickness of 50 nm under the conditions where silane at a flow rate of 200 sccm, nitrogen at a flow rate of 2000 sccm, and an ammonia gas at a flow rate of 100 sccm are supplied as a source gas to a reaction chamber of a PECVD apparatus, the pressure in the reaction chamber is controlled to 100 Pa, and a power of 2000 W is supplied using a 27.12 MHz high-frequency power source.

The second silicon nitride film can be formed to have a thickness of 300 nm under the conditions where silane at a flow rate of 200 sccm, nitrogen at a flow rate of 2000 sccm, and an ammonia gas at a flow rate of 2000 sccm are supplied as a source gas to the reaction chamber of the PECVD apparatus; the pressure in the reaction chamber is controlled to 100 Pa, and a power of 2000 W is supplied using a 27.12 MHz high-frequency power source.

The third silicon nitride film can be formed to have a thickness of 50 nm under the conditions where silane at a flow rate of 200 sccm and nitrogen at a flow rate of 5000 sccm are supplied as a source gas to the reaction chamber of the PECVD apparatus; the pressure in the reaction chamber is controlled to 100 Pa, and a power of 2000 W is supplied using a 27.12 MHz high-frequency power source.

Note that the first silicon nitride film, the second silicon nitride film, and the third silicon nitride film can be each formed at a substrate temperature of 350° C.

When the insulating film 106 has the three-layer stacked-layer structure of silicon nitride films, for example, in the case where a conductive film containing copper (Cu) is used as the conductive film 104, the following effect can be obtained.

The first silicon nitride film can inhibit diffusion of a copper (Cu) element from the conductive film 104. The second silicon nitride film has a function of releasing hydrogen and can improve withstand voltage of the insulating film functioning as a gate insulating film. The third silicon nitride film releases a small amount of hydrogen and can inhibit diffusion of hydrogen released from the second silicon nitride film.

The insulating film 107 is preferably an insulating film containing oxygen to improve characteristics of an interface with the oxide semiconductor film 108 formed later.

### <Step of Forming Oxide Semiconductor Film>

Next, the oxide semiconductor film 108 is formed over the insulating film 107 (see FIG. 12C).

In this embodiment, an oxide semiconductor film is formed by a sputtering method using an In—Ga—Zn metal oxide target (having an atomic ratio of In:Ga:Zn=1:1:1.2), a mask is formed over the oxide semiconductor film through a lithography process, and the oxide semiconductor film is processed into a desired shape, whereby the oxide semiconductor film 108 having an island shape is formed.

After the oxide semiconductor film 108 is formed, heat treatment may be performed at a temperature higher than or equal to 150° C. and lower than the strain point of the substrate, preferably higher than or equal to 200° C. and lower than or equal to 450° C., further preferably higher than or equal to 300° C. and lower than or equal to 450° C. The heat treatment performed here serves as one kind of treatment for increasing the purity of the oxide semiconductor film and can reduce hydrogen, water, and the like contained in the oxide semiconductor film 108. Note that the heat treatment for the purpose of reducing hydrogen, water, and the like may be performed before the oxide semiconductor film 108 is processed into an island shape.

A gas baking furnace, an electric furnace, a rapid thermal annealing (RTA) apparatus, or the like can be used for the heat treatment performed on the oxide semiconductor film 108. With the use of an RTA apparatus, the heat treatment can be performed at a temperature higher than or equal to the strain point of the substrate if the heating time is short. Therefore, the heat treatment time can be shortened.

The heat treatment may be performed on the oxide semiconductor film 108 in an atmosphere of nitrogen gas, oxygen gas, clean dry air (also referred to as CDA, which is an air with a water content of 20 ppm or less, preferably 1 ppm or less, further preferably 10 ppb or less), or rare gas (e.g., argon or helium). The atmosphere of nitrogen gas, oxygen gas, CDA, or rare gas preferably does not contain hydrogen, water, and the like.

The purity of the nitrogen gas, the oxygen gas, or CDA is preferably increased, for example. Specifically, the purity of the nitrogen gas, the oxygen gas, or CDA is preferably 6N (99.9999%) or 7N (99.99999%). When a gas which is highly purified to have a dew point of −60° C. or lower, preferably −100° C. or lower, is used as the nitrogen gas, the oxygen gas, or CDA, entry of moisture and the like into the oxide semiconductor film 108 can be minimized.

Further, another heat treatment may be performed on the oxide semiconductor film 108 in an oxygen atmosphere or a CDA atmosphere after the heat treatment in a nitrogen atmosphere or a rare gas atmosphere. As a result, hydrogen, water, and the like can be released from the oxide semiconductor film 108 and oxygen can be supplied to the oxide semiconductor film 108 at the same time. Consequently, the amount of oxygen vacancies in the oxide semiconductor film 108 can be reduced.

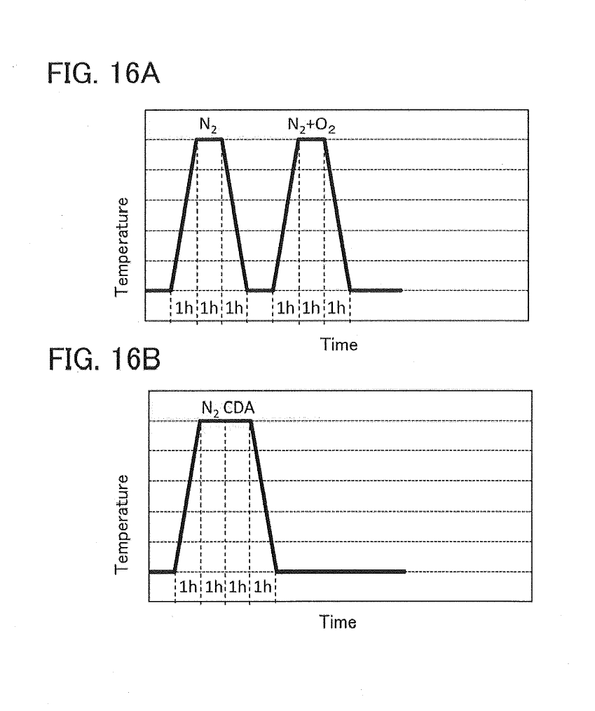

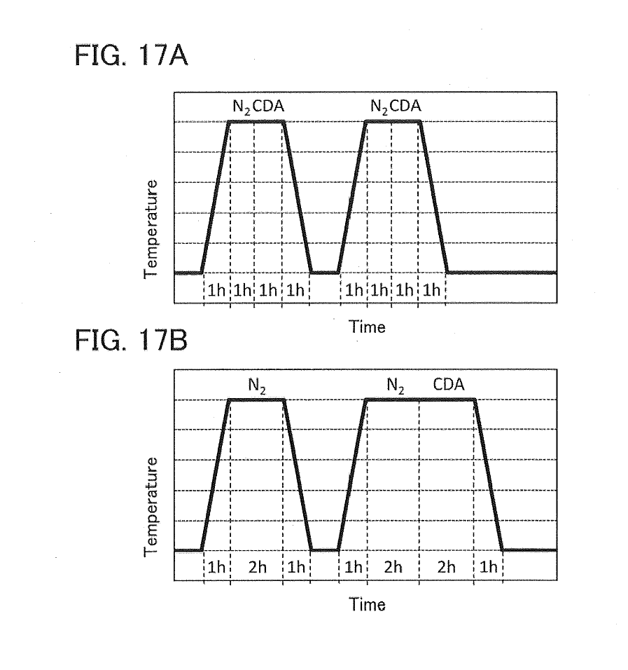

Here, thermal profiles of heat treatment performed on the oxide semiconductor film 108 in a gas baking furnace will be described with reference to FIGS. 16A and 16B and FIGS. 17A and 17B. FIGS. 16A and 16B and FIGS. 17A and 17B each show a thermal profile of heat treatment in a gas baking furnace.

Note that each of FIGS. 16A and 16B and FIGS. 17A and 17B is a thermal profile showing the temperature raised to a predetermined temperature (here, 450° C.; hereinafter referred to as a first temperature) and dropped to a predetermined temperature (here, higher than or equal to room temperature and lower than or equal to 150° C.; hereinafter referred to as a second temperature).

When the oxide semiconductor film 108 is subjected to heat treatment, the treatment can be divided into two steps using two kinds of gases as shown in FIG. 16A. For example, a nitrogen gas is introduced into a gas baking furnace in the first step. Then, the temperature is raised to the first temperature over one hour, and the heat treatment is performed at the first temperature for another one hour. After that, the temperature is dropped to the second temperature over the next one hour. In the second step, the nitrogen gas is replaced by a mixed gas of nitrogen and oxygen. Then, the time taken to raise the temperature to the first temperature is one hour, and the heat treatment is performed at the first temperature for another one hour. After that, the temperature is dropped to the second temperature over the next one hour.

Alternatively, when the oxide semiconductor film 108 is subjected to heat treatment, the treatment can be performed in one step using two kinds of gases as shown in FIG. 16B. For example, first, a nitrogen gas is introduced into a gas baking furnace. Then, the temperature is raised to the first temperature over one hour, and the heat treatment is performed at the first temperature for another one hour. After that, the gas is changed from the nitrogen gas to CDA. After the gas change, the heat treatment is performed for another one hour, and the temperature is dropped to the second temperature over the next one hour.

The thermal profile of the heat treatment in the gas baking furnace shown in FIG. 16B requires less processing time than the thermal profile of the heat treatment in the gas baking furnace shown in FIG. 16A; accordingly, semiconductor devices can be provided with higher productivity.

Alternatively, when the oxide semiconductor film 108 is subjected to heat treatment, the treatment can be performed in two steps using two kinds of gases as shown in FIG. 17A. For example, first, a nitrogen gas is introduced into a gas baking furnace in the first step. Then, the temperature is raised to the first temperature over one hour, and the heat treatment is performed at the first temperature for another one hour. After that, the gas is changed from the nitrogen gas to CDA. After the gas change, the heat treatment is performed for another one hour, and the temperature is dropped to the second temperature over the next one hour. In the second step, CDA is replaced by a nitrogen gas. Then, the temperature is raised to the first temperature over one hour, and the heat treatment is performed at the first temperature for another one hour. After that, the gas is changed from the nitrogen gas to CDA. After the gas change, the heat treatment is performed for another one hour, and the temperature is dropped to the second temperature over the next one hour.

Alternatively, when the oxide semiconductor film 108 is subjected to heat treatment, the treatment can be performed in two steps using two kinds of gases as shown in FIG. 17B. For example, first, a nitrogen gas is introduced into a gas baking furnace in the first step. Then, the temperature is raised to the first temperature over one hour, and the heat treatment is performed at the first temperature for two hours. After that, the temperature is dropped to the second temperature over the next one hour. In the second step, the temperature is raised to the first temperature over one hour, and the heat treatment is performed at the first temperature for two hours. After that, the gas is changed from the nitrogen gas to CDA. After the gas change, the heat treatment is performed for another two hours, and then the temperature is dropped to the second temperature over the next one hour.

As far as the thermal profiles of heat treatment performed on the oxide semiconductor film 108 in a gas baking furnace are concerned, it is preferable that the oxide semiconductor film 108 be first heated in a nitrogen gas as shown in FIGS. 16A and 16B and FIGS. 17A and 17B.

When the oxide semiconductor film 108 is first heated in a nitrogen gas, oxygen, which is one of the principal components of the oxide semiconductor film 108, and hydrogen in the oxide semiconductor film 108 react with each other to form an OH group. Then, the OH group is released from the surface of the oxide semiconductor film 108 as H₂O. In other words, owing to the first nitrogen gas, hydrogen in the oxide semiconductor film 108 can be captured.

However, heating the oxide semiconductor film 108 with only a nitrogen gas makes oxygen be released from the oxide semiconductor film 108 as H₂O, whereby oxygen vacancies are formed in the oxide semiconductor film 108 in some cases. Thus, the nitrogen gas is replaced by either a mixed gas of nitrogen and oxygen or CDA as shown in FIGS. 16A and 16B and FIGS. 17A and 17B, in which case oxygen contained in the gas can fill the oxygen vacancies in the oxide semiconductor film 108.

Note that although the heat treatment is performed for one or two consecutive hours after the temperature becomes stable at the predetermined temperature in FIGS. 16A and 16B and FIGS. 17A and 17B, one embodiment of the present invention is not limited thereto. For example, the processing time of heat treatment in the nitrogen gas in the first step in FIG. 17B may be one to 10 hours inclusive. As the processing time of the first step in FIG. 17B is increased, a larger amount of hydrogen can be released from the oxide semiconductor film 108, which is preferable.

In addition, time for baking with the use of either a mixed gas of nitrogen and oxygen or CDA may be set longer (e.g., one to 10 hours inclusive) as necessary. Increasing the heating time in an oxygen-containing atmosphere makes it possible to favorably fill the oxygen vacancies formed in the oxide semiconductor film 108.

In the case where the oxide semiconductor film is formed by a sputtering method, a rare gas (typically argon), oxygen, or a mixed gas of a rare gas and oxygen is used as a sputtering gas, as appropriate. In the case where the mixed gas of a rare gas and oxygen is used, the proportion of oxygen to a rare gas is preferably increased. In addition, increasing the purity of a sputtering gas is necessary. For example, as an oxygen gas or an argon gas used for a sputtering gas, a gas that is highly purified to have a dew point of −60° C. or lower, further preferably −100° C. or lower is used, whereby entry of moisture or the like into the oxide semiconductor film 108 can be minimized.

In the case where the oxide semiconductor film 108 is formed by a sputtering method, a chamber in a sputtering apparatus is preferably evacuated to be a high vacuum state (to the degree of about 5×10⁻⁷ Pa to 1×10⁻⁴ Pa) with an adsorption vacuum evacuation pump such as a cryopump in order to remove water or the like, which serves as an impurity for the oxide semiconductor film 108, as much as possible. Alternatively, a turbo molecular pump and a cold trap are preferably combined so as to prevent a backflow of a gas, especially a gas containing carbon or hydrogen from an exhaust system to the inside of the chamber.

### <Step of Forming Region Having Oxygen Vacancies in Oxide Semiconductor Film>

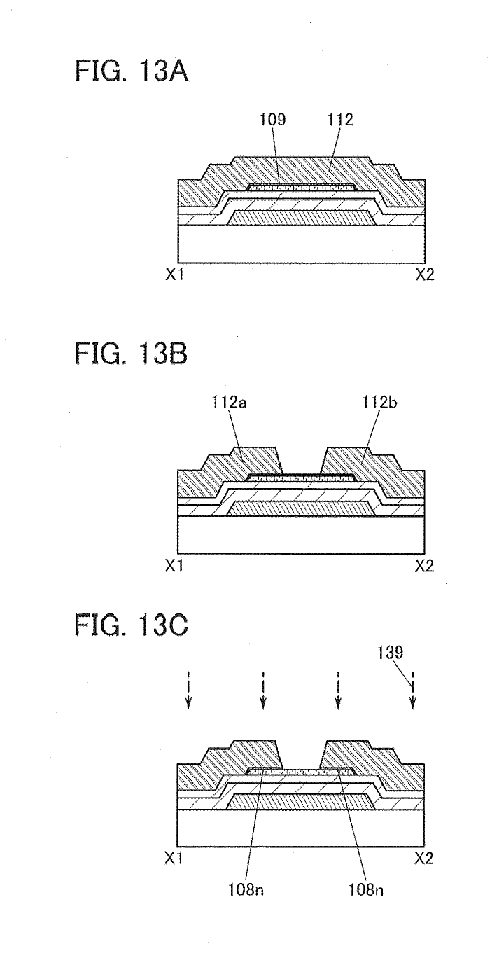

Next, a conductive film 112 is formed over the insulating film 107 and the oxide semiconductor film 108. Note that a modified layer 109 is formed in the vicinity of a surface of the oxide semiconductor film 108 in forming the conductive film 112 (see FIG. 13A).

The modified layer 109 is a region of the oxide semiconductor film 108, which has many oxygen vacancies. Note that for example in the case where the conductive film 112 is formed by a sputtering method, the modified layer 109 is formed in the vicinity of the surface of the oxide semiconductor film 108 by plasma damage at the time of sputtering, damage due to recoil argon in sputtering, or collision of atoms or molecules of a material used for the conductive film 112 in sputtering. Accordingly, the conductive film 112 is particularly preferably formed by a sputtering method or a PLD method. Electric power used in a sputtering apparatus is supplied from, for example, a direct-current (DC) power source, a radio-frequency (RF) source, an alternating-current (AC) power source, or the like. It is particularly preferable to use a DC power source or an AC power source for sputtering because high productivity can be achieved.

In this embodiment, as the conductive film 112, a stacked film including a 50-nm-thick tungsten film, a 400-nm-thick aluminum film, and a 100-nm-thick titanium film is formed by a sputtering method. Note that deposition power for the conductive film 112 is important in formation of the modified layer 109. For example, when the power density in sputtering is greater than or equal to 1 W/cm² and less than or equal to 4 W/cm², the modified layer 109 having a thickness less than or equal to 5 nm can be formed.

### <Step of Forming Source Electrode and Drain Electrode>

Next, a resist mask is formed in a desired region over the conductive film 112, and the conductive film 112 is processed to form the conductive films 112a and 112b serving as a source electrode and a drain electrode. After the conductive films 112a and 112b are formed, the resist mask is removed (see FIG. 13B).

### <Step of Removing Region Having Oxygen Vacancies>

Next, part of the modified layer 109, which is between the conductive films 112a and 112b, is removed with an etchant 139 supplied from above the conductive films 112a and 112b. By removal of the part of the modified layer 109, the n-type regions 108n in contact with the conductive films 112a and 112b are formed in the oxide semiconductor film 108 (see FIG. 13C).

As the etchant 139, a chemical solution or an etching gas that can remove the modified layer 109 is used. It is particularly preferable to use a chemical solution as the etchant 139 because damage to the surface of the channel region 108i can be reduced. In this embodiment, the part of the modified layer 109 is removed using a phosphoric acid solution as the etchant 139. Note that in the step of etching, the channel region 108i may partly have a depression.

Through the above steps, the transistor 100 is formed.

### <Step of Forming Oxide Insulating Film>

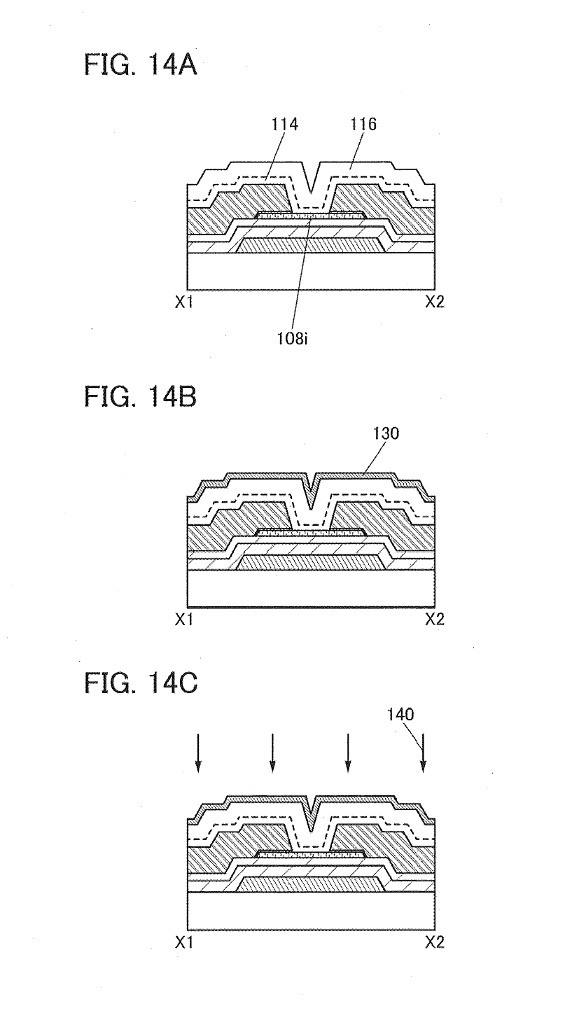

Next, over the transistor 100, specifically, over the oxide semiconductor film 108 and the conductive films 112a and 112b, the insulating films 114 and 116 functioning as protective insulating films of the transistor 100 are formed. By heat treatment at the time of forming the insulating films 114 and 116 or after formation of the insulating films 114 and 116, oxygen vacancies in the oxide semiconductor film 108 are filled, so that the channel region 108i is formed (see FIG. 14A).

Note that after the insulating film 114 is formed, the insulating film 116 is preferably formed in succession without exposure to the air. After the insulating film 114 is formed, the insulating film 116 is formed in succession by adjusting at least one of the flow rate of a source gas, pressure, a high-frequency power, and a substrate temperature without exposure to the air, whereby the concentration of impurities attributed to the atmospheric component at the interface between the insulating film 114 and the insulating film 116 can be reduced and oxygen in the insulating films 114 and 116 can be moved to the channel region 108i in the oxide semiconductor film 108; accordingly, the amount of oxygen vacancies in the channel region 108i can be reduced.

For example, as the insulating film 114, a silicon oxynitride film can be formed by a PECVD method. In this case, a deposition gas containing silicon and an oxidizing gas are preferably used as a source gas. Typical examples of the deposition gas containing silicon include silane, disilane, trisilane, and silane fluoride. Examples of the oxidizing gas include dinitrogen monoxide and nitrogen dioxide. An insulating film containing nitrogen and having a small number of defects can be formed as the insulating film 114 by a PECVD method under the conditions where the flow rate of the oxidizing gas is higher than 20 times and lower than 100 times, preferably higher than or equal to 40 times and lower than or equal to 80 times, that of the deposition gas; and the pressure in a treatment chamber is lower than 100 Pa, preferably lower than or equal to 50 Pa.

In this embodiment, a silicon oxynitride film is formed as the insulating film 114 by a PECVD method under the conditions where the substrate 102 is held at a temperature of 220° C., silane at a flow rate of 50 sccm and dinitrogen monoxide at a flow rate of 2000 sccm are used as a source gas, the pressure in the treatment chamber is 20 Pa, and a high-frequency power of 100 W at 13.56 MHz (1.6×10⁻² W/cm² as the power density) is supplied to parallel-plate electrodes.

As the insulating film 116, a silicon oxide film or a, silicon oxynitride film is formed under the following conditions: the substrate placed in a treatment chamber of the PECVD apparatus that is vacuum-evacuated is held at a temperature higher than or equal to 180° C. and lower than or equal to 280° C., preferably higher than or equal to 200° C. and lower than or equal to 240° C., the pressure is greater than or equal to 100 Pa and less than or equal to 250 Pa, preferably greater than or equal to 100 Pa and less than or equal to 200 Pa with introduction of a source gas into the treatment chamber, and a high-frequency power of greater than or equal to 0.17 W/cm² and less than or equal to 0.5 W/cm², preferably greater than or equal to 0.25 W/cm² and less than or equal to 0.35 W/cm² is supplied to an electrode provided in the treatment chamber.

As the deposition conditions of the insulating film 116, the high-frequency power having the above power density is supplied to the reaction chamber having the above pressure, whereby the decomposition efficiency of the source gas in plasma is increased, oxygen radicals are increased, and oxidation of the source gas is promoted; therefore, the oxygen content of the insulating film 116 becomes higher than that in the stoichiometric composition. On the other hand, in the film formed at a substrate temperature within the above temperature range, a bond between silicon and oxygen is weak, and accordingly, part of oxygen in the film is released by heat treatment in a later step. Thus, it is possible to form an oxide insulating film which contains oxygen at a higher proportion than oxygen in the stoichiometric composition and from which part of oxygen is released by heating.

Note that the insulating film 114 functions as a protective film of the channel region 108i in the oxide semiconductor film 108 in the step of forming the insulating film 116. Consequently, the insulating film 116 can be formed using the high-frequency power having a high power density while damage to the channel region 108i is reduced.

Note that in the deposition conditions of the insulating film 116, when the flow rate of the deposition gas containing silicon with respect to the oxidizing gas is increased, the amount of defects in the insulating film 116 can be reduced. Typically, it is possible to form an oxide insulating film in which the amount of defects is small, i.e., the spin density corresponding to a signal which appears at g=2.001 due to a dangling bond of silicon is lower than 6×10¹⁷ spins/cm³, preferably lower than or equal to 3×10¹⁷ spins/cm³, further preferably lower than or equal to 1.5×10¹⁷ spins/cm³ by ESR measurement. As a result, the reliability of the transistor can be improved.

Heat treatment may be performed after the insulating films 114 and 116 are formed. The heat treatment can reduce nitrogen oxide contained in the insulating films 114 and 116. By the heat treatment, part of oxygen contained in the insulating films 114 and 116 can be moved to the channel region 108i in the oxide semiconductor film 108, so that the amount of oxygen vacancies included in the channel region 108i can be reduced.

The temperature of the heat treatment performed on the insulating films 114 and 116 is typically higher than or equal to 150° C. and lower than or equal to 400° C., preferably higher than or equal to 300° C. and lower than or equal to 400° C., further preferably higher than or equal to 320° C. and lower than or equal to 370° C. The heat treatment may be performed under an atmosphere of nitrogen, oxygen, CDA, or a rare gas (argon, helium, and the like). Note that a gas baking furnace, an electric furnace, an RTA apparatus, or the like can be used for the heat treatment, in which it is preferable that hydrogen, water, and the like not be contained in the nitrogen, oxygen, ultra-dry air, or a rare gas.

In this embodiment, the heat treatment is performed at 350° C. for one hour in an atmosphere of nitrogen and oxygen.

### <Step of Adding Oxygen to Oxide Insulating Film>

Next, the protective film 130 that inhibits release of oxygen is formed over the insulating film 116 (see FIG. 14B).

The protective film 130 can be formed using a conductive film including indium or a semiconductor film including indium. In this embodiment, as the protective film 130, a 5-nm-thick ITSO film is formed with a sputtering apparatus. Note that the thickness of the protective film 130 is preferably greater than or equal to 1 nm and less than or equal to 20 nm or greater than or equal to 2 nm and less than or equal to 10 nm, in which case oxygen is favorably transmitted and release of oxygen can be inhibited.

Next, oxygen 140 is added to the insulating films 114 and 116 through the protective film 130 (see FIG. 14C).

Examples of a method for adding the oxygen 140 to the insulating films 114 and 116 through the protective film 130 include an ion doping method, an ion implantation method (e.g. ion implantation, plasma-based ion implantation, plasma immersion ion implantation, or plasma source ion implantation), and a plasma treatment method. In the case of the plasma treatment method, high-density plasma may be generated by exciting a halogen element and oxygen with a microwave.

By application of a bias voltage to the substrate side when the oxygen 140 is added, the oxygen 140 can be effectively added to the insulating films 114 and 116. The bias voltage is applied, for example, by an ashing apparatus with the power density applied to the substrate side of the ashing apparatus be set to be greater than or equal to 0.5 W/cm² and less than or equal to 5 W/cm². The substrate temperature during addition of the oxygen 140 is higher than or equal to room temperature and lower than or equal to 300° C., preferably higher than or equal to 100° C. and lower than or equal to 250° C., whereby the oxygen can be added efficiently to the insulating films 114 and 116.

In this embodiment, an ashing apparatus is used. An oxygen gas is introduced into the ashing apparatus and a bias is applied to the substrate side, so that the oxygen 140 is added to the insulating films 114 and 116.

When the protective film 130 is provided over the insulating film 116 and then oxygen is added, the protective film 130 functions as a protective film for inhibiting release of oxygen from the insulating film 116. Thus, a larger amount of oxygen can be added to the insulating films 114 and 116.

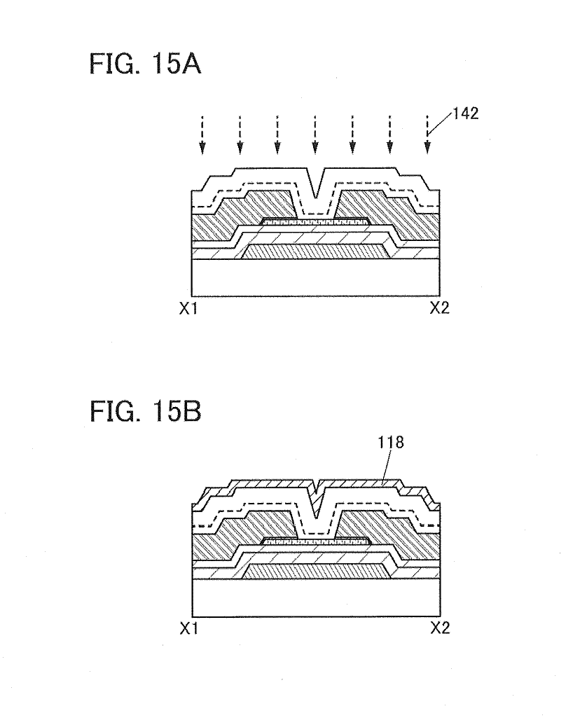

Then, the protective film 130 is removed using an etchant 142 (see FIG. 15A).

As the etchant 142, a chemical solution or an etching gas that can remove the protective film 130 is used. In this embodiment, an oxalic acid solution containing an oxalic acid at a concentration of 5% is used as the etchant 142. As the etchant 142, after the oxalic acid solution containing an oxalic acid at a concentration of 5% is used, hydrofluoric acid containing a hydrofluoric acid at a concentration of 0.5% may be used. With the use of the hydrofluoric acid containing a hydrofluoric acid at a concentration of 0.5%, the protective film 130 that inhibits release of oxygen can be favorably removed.

Next, the insulating film 118 is formed over the insulating film 116, whereby the transistor 100 in FIGS. 1A to 1C is foamed (see FIG. 15B).

In the case where the insulating film 118 is formed by a PECVD method, the substrate temperature is preferably set to higher than or equal to 300° C. and lower than or equal to 400° C., more preferably higher than or equal to 320° C. and lower than or equal to 370° C., so that a dense film can be formed.

For example, in the case where a silicon nitride film is formed by a PE-CVD method as the insulating film 118, a deposition gas containing silicon, nitrogen, and ammonia are preferably used as a source gas. As the source gas, a small amount of ammonia compared to the amount of nitrogen is used, whereby ammonia is dissociated in the plasma and activated species are generated. The activated species cleave a bond between silicon and hydrogen which are contained in a deposition gas containing silicon and a triple bond between nitrogen molecules. As a result, a dense silicon nitride film having few defects, in which bonds between silicon and nitrogen are promoted and bonds between silicon and hydrogen is few, can be formed. On the other hand, when the amount of ammonia with respect to nitrogen is large, decomposition of a deposition gas containing silicon and decomposition of nitrogen are not promoted, so that a sparse silicon nitride film in which bonds between silicon and hydrogen remain and defects are increased is formed. Therefore, in a source gas, the flow ratio of the nitrogen to the ammonia is set to be preferably greater than or equal to 5 and less than or equal to 50, more preferably greater than or equal to 10 and less than or equal to 50.

In this embodiment, with the use of a PECVD apparatus, a 50-nm-thick silicon nitride film is forced as the insulating film 118 using silane, nitrogen, and ammonia as a source gas. The flow rate of silane is 50 sccm, the flow rate of nitrogen is 5000 sccm, and the flow rate of ammonia is 100 sccm. The pressure in the treatment chamber is 100 Pa, the substrate temperature is 350° C., and high-frequency power of 1000 W is supplied to parallel-plate electrodes with a 27.12 MHz high-frequency power source. Note that the PECVD apparatus is a parallel-plate PECVD apparatus in which the electrode area is 6000 cm², and the power per unit area (power density) into which the supplied power is converted is 1.7×10⁻¹ W/cm².

In the case where the insulating film 118 is formed by thermal deposition, it is preferable that preheating be not performed before formation of the insulating film 118. For example, in the case where preheating is performed before the insulating film 118 is formed, excess oxygen in the insulating films 114 and 116 may be released to the outside. Therefore, when the insulating film 118 is formed, excess oxygen in the insulating films 114 and 116 can be prevented from being released to the outside without preheating by, specifically, forming the insulating film 118 over the insulating film 116 within preferably three minutes, further preferably within one minute after the substrate is transferred to a heated chamber.

Note that heat treatment may be performed before or after the formation of the insulating film 118, so that excess oxygen included in the insulating films 114 and 116 can be diffused to the channel region 108i in the oxide semiconductor film 108 to fill oxygen vacancies in the channel region 108i. Alternatively, the insulating film 118 may be formed by thermal deposition, so that excess oxygen included in the insulating films 114 and 116 can be diffused to the channel region 108i to fill oxygen vacancies in the channel region 108i. The temperature of the heat treatment that can be performed before or after the formation of the insulating film 118 is typically higher than or equal to 150° C. and lower than or equal to 400° C., preferably higher than or equal to 300° C. and lower than or equal to 400° C. and further preferably higher than or equal to 320° C. and lower than or equal to 370° C.

Through the above-described process, the transistor 100 illustrated in FIGS. 1A to 1C can be fabricated.

### <Method 2 for Manufacturing Semiconductor Device>

Next, a method for manufacturing the transistor 170 illustrated in FIGS. 3A to 3C will be described with reference to FIGS. 18A to 18D and FIGS. 19A to 19D. FIGS. 18A and 18C and FIGS. 19A and 19C are each a cross-sectional view in the channel length direction of the transistor 170 in the manufacturing process, and FIGS. 18B and 18D and FIGS. 19B and 19D are each a cross-sectional view in the channel width direction of the transistor 170 in the manufacturing process.

First, the steps up to the step illustrated in FIG. 15B are performed (see FIGS. 18A and 18B).

Next, a mask is formed over the insulating film 118 through a lithography process, and the opening 142c is formed in a desired region in the insulating films 114, 116, and 118. In addition, a mask is formed over the insulating film 118 through a lithography process, and the openings 142a and 142b are formed in desired regions in the insulating films 106, 107, 114, 116, and 118. Note that the opening 142c reaches the conductive film 112b. The openings 142a and 142b reach the conductive film 104 (see FIGS. 18C and 18D).

Note that the openings 142a and 142b and the opening 142c may be formed at a time or may be formed by different steps. In the case where the openings 142a and 142b and the opening 142c are formed at a time, for example, a gray-tone mask or a half-tone mask may be used.

Next, a conductive film 120 is formed over the insulating film 118 to cover the openings 142a, 142b, and 142c (see FIGS. 19A and 19B).

For the conductive film 120, for example, a material including one of indium (In), zinc (Zn), and tin (Sn) can be used. In particular, for the conductive film 120, a light-transmitting conductive material such as indium oxide including tungsten oxide, indium zinc oxide including tungsten oxide, indium oxide including titanium oxide, indium tin oxide including titanium oxide, indium tin oxide, indium zinc oxide, or indium tin oxide including silicon oxide can be used. Moreover, the conductive film 120 is favorably formed using the same kind of material as the protective film 130 capable of inhibiting release of oxygen, in which case the manufacturing cost can be reduced.

The conductive film 120 can be formed by a sputtering method, for example. In this embodiment, a 110-nm-thick ITSO film is formed by a sputtering method.

Next, a mask is formed over the conductive film 120 through a lithography process, and the conductive film 120 is processed into desired regions to form the conductive films 120a and 120b (see FIGS. 19C and 19D).

Through the above process, the transistor 170 illustrated in FIGS. 3A to 3C can be manufactured.

The structure and method described in this embodiment can be combined as appropriate with any of the other structures and methods described in the other embodiments and examples.

### Embodiment 2

In this embodiment, an oxide semiconductor included in a semiconductor device of one embodiment of the present invention will be described in detail below.

### <Structure of Oxide Semiconductor>

First, a structure of an oxide semiconductor is described.

An oxide semiconductor is classified into a single crystal oxide semiconductor and a non-single-crystal oxide semiconductor. Examples of a non-single-crystal oxide semiconductor include a c-axis aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and an nc-OS.

It is known that an amorphous structure is generally defined as being metastable and unfixed, and being isotropic and having no non-uniform structure. In other words, an amorphous structure has a flexible bond angle and a short-range order but does not have a long-range order.

This means that an inherently stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. Note that an a-like OS has a periodic structure in a microscopic region, but at the same time has a void and has an unstable structure. For this reason, an a-like OS has physical properties similar to those of an amorphous oxide semiconductor.

### <CAAC-OS>

First, a CAAC-OS is described.

A CAAC-OS is one of oxide semiconductors having a plurality of c-axis aligned crystal parts (also referred to as pellets).

In a combined analysis image (also referred to as a high-resolution TEM image) of a bright-field image and a diffraction pattern of a CAAC-OS, which is obtained using a transmission electron microscope (TEM), a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

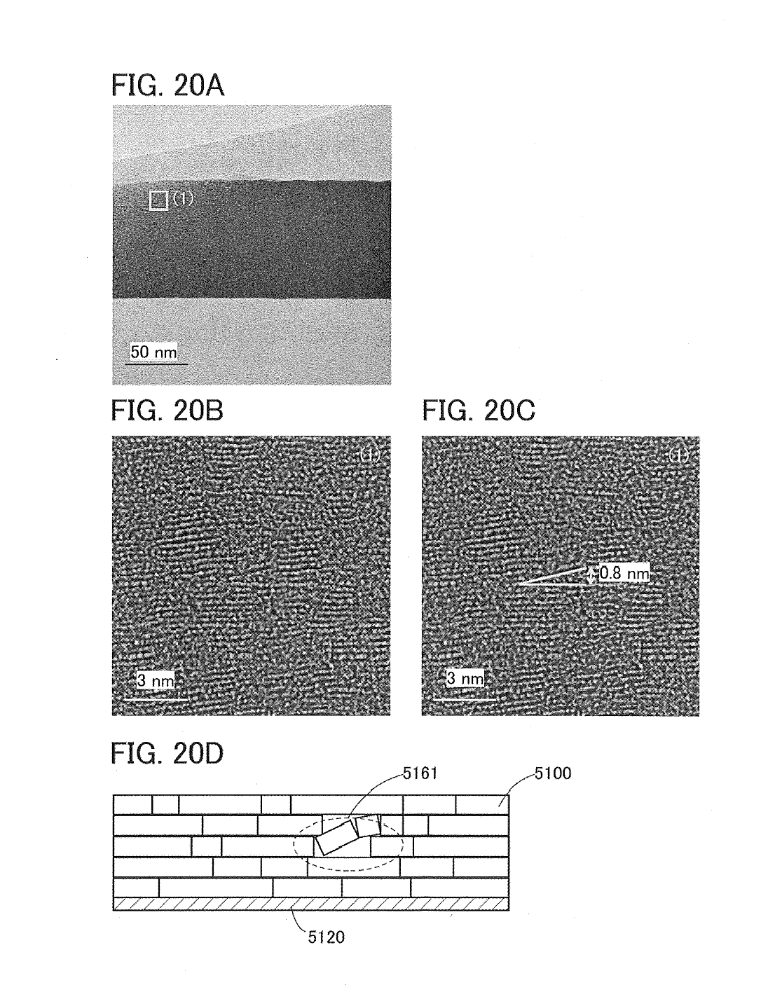

The CAAC-OS observed with a TEM is described below. FIG. 20A shows a high-resolution TEM image of a cross section of the CAAC-OS which is observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be obtained with, for example, an atomic resolution analytical electron microscope JEM-ARM200F manufactured by JEOL Ltd.

FIG. 20B is an enlarged Cs-corrected high-resolution TEM image of a region (1) in FIG. 20A. FIG. 20B shows that metal atoms are arranged in a layered manner in a pellet. Each metal atom layer has a configuration reflecting unevenness of a surface over which the CAAC-OS is formed (hereinafter, the surface is referred to as a formation surface) or a top surface of the CAAC-OS, and is arranged parallel to the formation surface or the top surface of the CAAC-OS.

As shown in FIG. 20B, the CAAC-OS has a characteristic atomic arrangement. The characteristic atomic arrangement is denoted by an auxiliary line in FIG. 20C. FIGS. 20B and 20C prove that the size of a pellet is approximately 1 nm to 3 nm, and the size of a space caused by tilt of the pellets is approximately 0.8 nm. Therefore, the pellet can also be referred to as a nanocrystal (nc). Furthermore, the CAAC-OS can also be referred to as an oxide semiconductor including c-axis aligned nanocrystals (CANC).

Here, according to the Cs-corrected high-resolution TEM images, the schematic arrangement of pellets 5100 of a CAAC-OS over a substrate 5120 is illustrated by such a structure in which bricks or blocks are stacked (see FIG. 20D). The part in which the pellets are tilted as observed in FIG. 20C corresponds to a region 5161 shown in FIG. 20D.

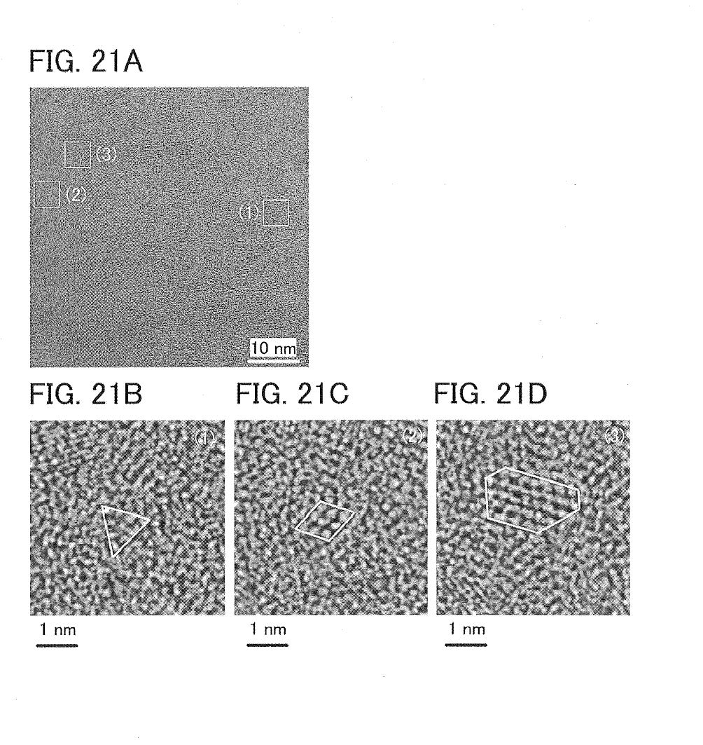

FIG. 21A shows a Cs-corrected high-resolution TEM image of a plane of the CAAC-OS observed from a direction substantially perpendicular to the sample surface. FIGS. 21B, 21C, and 21D are enlarged Cs-corrected high-resolution TEM images of regions (1), (2), and (3) in FIG. 21A, respectively. FIGS. 21B, 21C, and 21D indicate that metal atoms are arranged in a triangular, quadrangular, or hexagonal configuration in a pellet. However, there is no regularity of arrangement of metal atoms between different pellets.

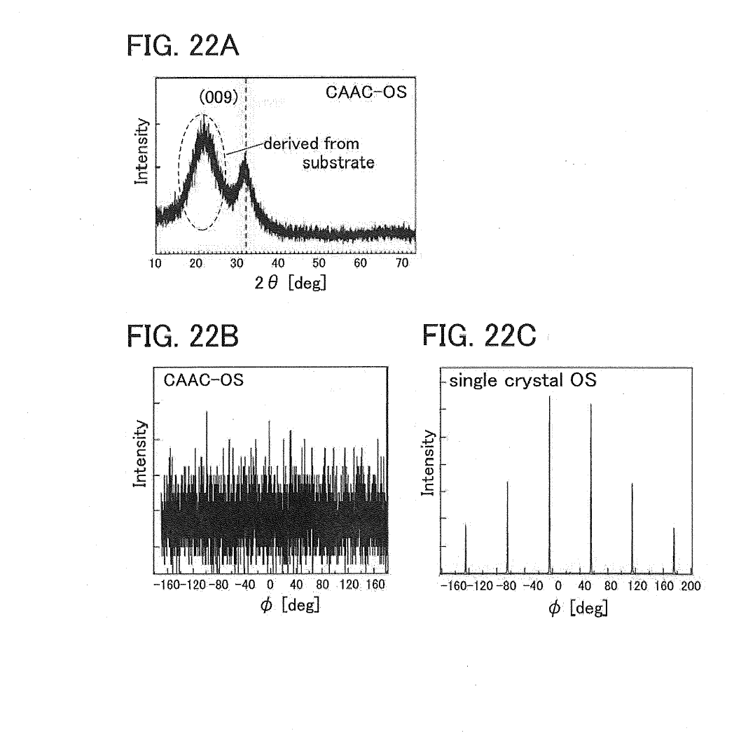

Next, a CAAC-OS analyzed by X-ray diffraction (XRD) is described. For example, when the structure of a CAAC-OS including an InGaZnO₄ crystal is analyzed by an out-of-plane method, a peak appears at a diffraction angle (2θ) of around 31° as shown in FIG. 22A. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

Note that in structural analysis of the CAAC-OS by an out-of-plane method, another peak may appear when 2θ is around 36°, in addition to the peak at 2θ of around 31°. The peak of 2θ at around 36° indicates that a crystal having no c-axis alignment is included in part of the CAAC-OS. It is preferable that in the CAAC-OS analyzed by an out-of-plane method, a peak appear when 2θ is around 31° and that a peak not appear when 2θ is around 36°.

On the other hand, in structural analysis of the CAAC-OS by an in-plane method in which an X-ray is incident on a sample in a direction substantially perpendicular to the c-axis, a peak appears when 2θ is around 56°. This peak is derived from the (110) plane of the InGaZnO₄ crystal. In the case of the CAAC-OS, when analysis (φ scan) is performed with 2θ fixed at around 56° and with the sample rotated using a normal vector of the sample surface as an axis (φ axis), as shown in FIG. 22B, a peak is not clearly observed. In contrast, in the case of a single crystal oxide semiconductor of InGaZnO₄, when φ scan is performed with 2θ fixed at around 56°, as shown in FIG. 22C, six peaks which are derived from crystal planes equivalent to the (110) plane are observed. Accordingly, the structural analysis using XRD shows that the directions of a-axes and b-axes are irregularly oriented in the CAAC-OS.

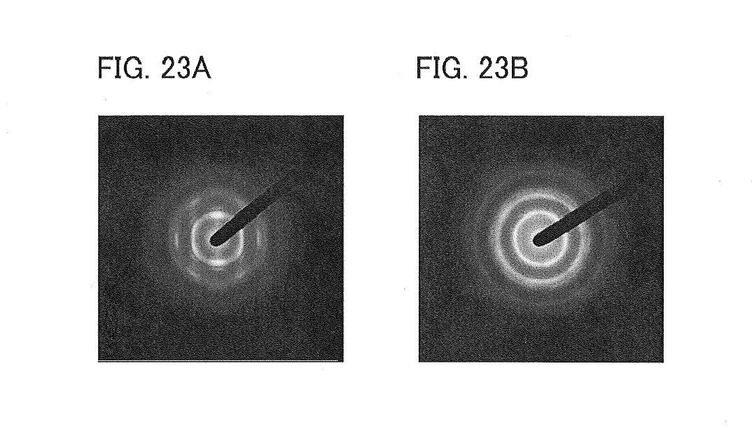

Next, a CAAC-OS analyzed by electron diffraction is described. For example, when an electron beam with a probe diameter of 300 nm is incident on a CAAC-OS including an InGaZnO₄ crystal in a direction parallel to the sample surface, a diffraction pattern (also referred to as a selected-area transmission electron diffraction pattern) shown in FIG. 23A can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 23B shows a diffraction pattern obtained in such a manner that an electron beam with a probe diameter of 300 nm is incident on the same sample in a direction perpendicular to the sample surface. As shown in FIG. 23B, a ring-like diffraction pattern is observed. Thus, the electron diffraction also indicates that the a-axes and b-axes of the pellets included in the CAAC-OS do not have regular alignment. The first ring in FIG. 23B is considered to be derived from the (010) plane, the (100) plane, and the like of the InGaZnO₄ crystal. The second ring in FIG. 23B is considered to be derived from the (110) plane and the like.

As described above, the CAAC-OS is an oxide semiconductor with high crystallinity. Entry of impurities, formation of defects, or the like might decrease the crystallinity of an oxide semiconductor. This means that the CAAC-OS has small amounts of impurities and defects (e.g., oxygen vacancies).

Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. Impurities contained in the oxide semiconductor might serve as carrier traps or carrier generation sources, for example. Furthermore, oxygen vacancies in the oxide semiconductor serve as carrier traps or serve as carrier generation sources when hydrogen is captured therein.

The CAAC-OS having small amounts of impurities and oxygen vacancies is an oxide semiconductor with low carrier density (specifically, lower than 8×10¹¹/cm³, preferably lower than 1×10¹¹/cm³, and further preferably lower than 1×10¹⁰/cm³, and is higher than or equal to 1×10⁻⁹/cm³). Such an oxide semiconductor is referred to as a highly purified intrinsic or substantially highly purified intrinsic oxide semiconductor. A CAAC-OS has a low impurity concentration and a low density of defect states. Thus, the CAAC-OS can be referred to as an oxide semiconductor having stable characteristics.

<nc-OS>

Next, an nc-OS is described.

An nc-OS has a region in which a crystal part is observed and a region in which a crystal part is not clearly observed in a high-resolution TEM image. In most cases, the size of a crystal part included in the nc-OS film is greater than or equal to 1 nm and less than or equal to 10 nm, or greater than or equal to 1 nm and less than or equal to 3 nm. Note that an oxide semiconductor including a crystal part whose size is greater than 10 nm and less than or equal to 100 nm is sometimes referred to as a microcrystalline oxide semiconductor. In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not observed. Accordingly, the nc-OS cannot be distinguished from an a-like OS or an amorphous oxide semiconductor, depending on an analysis method. For example, when the nc-OS is analyzed by an out-of-plane method using an X-ray beam having a diameter larger than the size of a pellet, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a pellet. Meanwhile, spots appear in a nanobeam electron diffraction pattern of the nc-OS when an electron beam having a probe diameter close to or smaller than the size of a pellet is applied. Moreover, in a nanobeam electron diffraction pattern of the nc-OS, regions with high luminance in a circular (ring) pattern are shown in some cases. Also in a nanobeam electron diffraction pattern of the nc-OS, a plurality of spots is shown in a ring-like region in some cases.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

Thus, the nc-OS is an oxide semiconductor that has high regularity as compared to an amorphous oxide semiconductor. Therefore, the nc-OS is likely to have a lower density of defect states than an a-like OS and an amorphous oxide semiconductor. Note that there is no regularity of crystal orientation between different pellets in the nc-OS. Therefore, the nc-OS has a higher density of defect states than the CAAC-OS.

<a-like OS>

An a-like OS has a structure between those of the nc-OS and the amorphous oxide semiconductor.

In a high-resolution TEM image of the a-like OS film, a void may be observed. Furthermore, in the high-resolution TEM image, there are a region where a crystal part is clearly observed and a region where a crystal part is not observed.

The a-like OS has an unstable structure because it contains a void. To verify that an a-like OS has an unstable structure as compared with a CAAC-OS and an nc-OS, a change in structure caused by electron irradiation is described below.

An a-like OS (referred to as Sample A), an nc-OS (referred to as Sample B), and a CAAC-OS (referred to as Sample C) are prepared as samples subjected to electron irradiation. Each of the samples is an In—Ga—Zn oxide.

First, a high-resolution cross-sectional TEM image of each sample is obtained. The high-resolution cross-sectional TEM images show that all the samples have crystal parts.

Note that which part is regarded as a crystal part is determined as follows. It is known that a unit cell of the InGaZnO₄ crystal has a structure in which nine layers including three In—O layers and six Ga—Zn—O layers are stacked in the c-axis direction. Accordingly, the distance between the adjacent layers is equivalent to the lattice spacing on the (009) plane (also referred to as d value). The value is calculated to be 0.29 nm from crystal structural analysis. Accordingly, a portion where the lattice spacing between lattice fringes is greater than or equal to 0.28 nm and less than or equal to 0.30 nm is regarded as a crystal part of InGaZnO₄. Each of lattice fringes corresponds to the a-b plane of the InGaZnO₄ crystal.

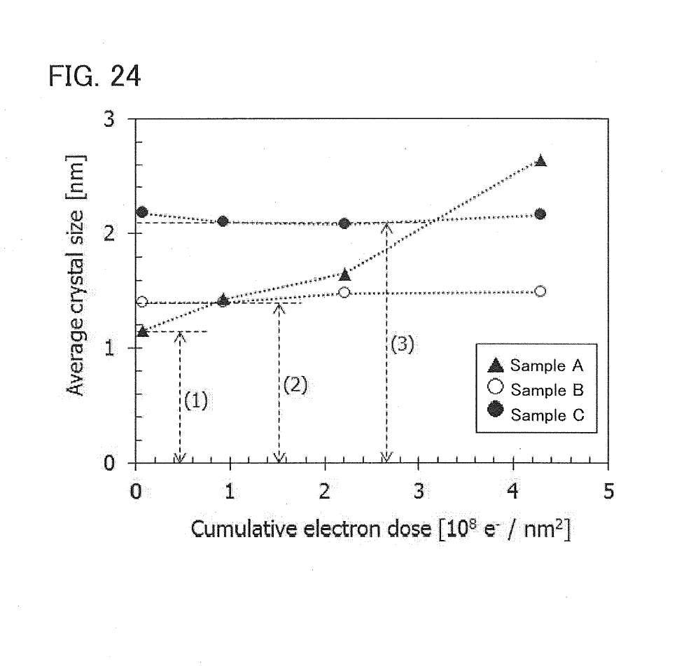

FIG. 24 shows change in the average size of crystal parts (at 22 points to 45 points) in each sample. Note that the crystal part size corresponds to the length of a lattice fringe. FIG. 24 indicates that the crystal part size in the a-like OS increases with an increase in the cumulative electron dose. Specifically, as shown by (1) in FIG. 24, a crystal part of approximately 1.2 nm (also referred to as an initial nucleus) at the start of TEM observation grows to a size of approximately 2.6 nm at a cumulative electron dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². Specifically, as shown by (2) and (3) in FIG. 24, the average crystal sizes in an nc-OS and a CAAC-OS are approximately 1.4 nm and approximately 2.1 nm, respectively, regardless of the cumulative electron dose.

In this manner, growth of the crystal part in the a-like OS is induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that it is difficult to deposit an oxide semiconductor having a density of lower than 78% of the density of the single crystal oxide semiconductor.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that single crystals with the same composition do not exist in some cases. In that case, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

As described above, oxide semiconductors have various structures and various properties. Note that an oxide semiconductor may be a stacked layer including two or more of an amorphous oxide semiconductor, an a-like OS, an nc-OS, and a CAAC-OS, for example.

<Formation Method of CAAC-OS and nc-OS>

Next, an example of a method for forming a CAAC-OS film will be described.

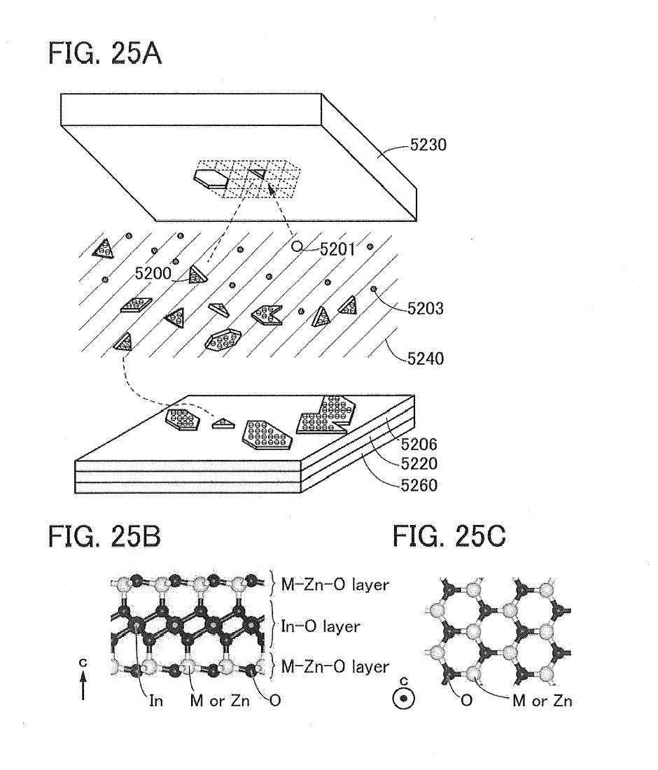

FIG. 25A is a schematic view of the inside of a film formation chamber. The CAAC-OS film can be formed by a sputtering method.

As shown in FIG. 25A, a substrate 5220 and a target 5230 are arranged to face each other. Plasma 5240 is generated between the substrate 5220 and the target 5230. A heating mechanism 5260 is under the substrate 5220. The target 5230 is attached to a backing plate (not illustrated in the drawing). A plurality of magnets is arranged to face the target 5230 with the backing plate positioned therebetween. A sputtering method in which the disposition speed is increased by utilizing a magnetic field of magnets is referred to as a magnetron sputtering method.

The distance d between the substrate 5220 and the target 5230 (also referred to as a target-substrate distance (T-S distance)) is greater than or equal to 0.01 m and less than or equal to 1 m, preferably greater than or equal to 0.02 m and less than or equal to 0.5 m. The deposition chamber is mostly filled with a deposition gas (e.g., an oxygen gas, an argon gas, or a mixed gas containing oxygen at 5 vol % or higher) and the pressure in the deposition chamber is controlled to be higher than or equal to 0.01 Pa and lower than or equal to 100 Pa, preferably higher than or equal to 0.1 Pa and lower than or equal to 10 Pa. Here, discharge starts by application of a voltage at a constant value or higher to the target 5230, and the plasma 5240 is observed. The magnetic field forms a high-density plasma region in the vicinity of the target 5230. In the high-density plasma region, the deposition gas is ionized, so that an ion 5201 is generated. Examples of the ion 5201 include an oxygen cation (O⁺) and an argon cation (Ar⁺).

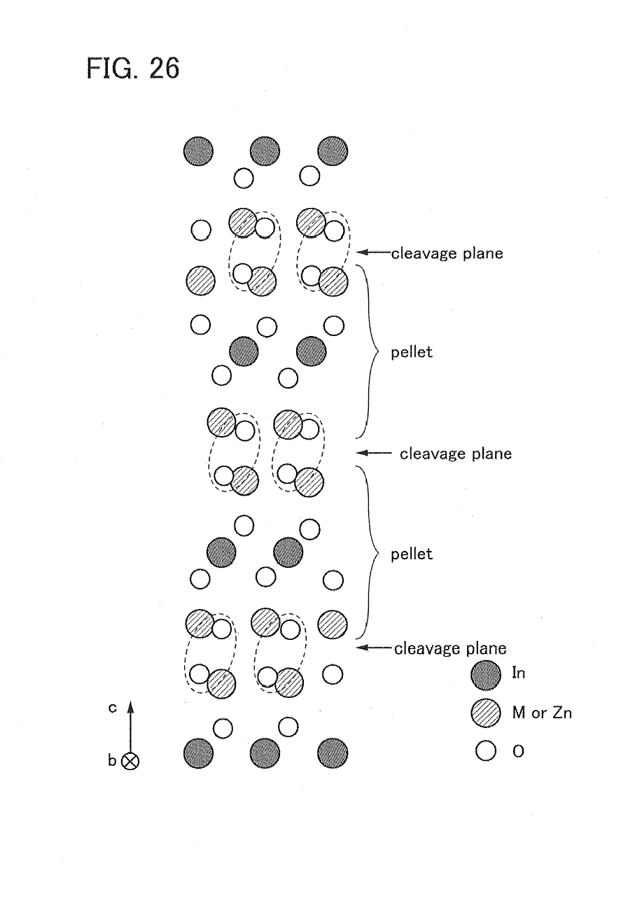

The target 5230 has a polycrystalline structure which includes a plurality of crystal grains and in which a cleavage plane exists in any of the crystal grains. FIG. 26 shows a crystal structure of InMZnO₄ (the element M is Ga or Sn, for example) included in the target 5230 as an example. Note that the crystal structure shown in FIG. 26 is InMZnO₄ observed from a direction parallel to a b-axis. In the crystal of InMZnO₄, oxygen atoms are negatively charged, whereby repulsive force is generated between the two adjacent M-Zn—O layers. Thus, the InMZnO₄ crystal has a cleavage plane between the two adjacent M-Zn—O layers.

The ion 5201 generated in the high-density plasma region is accelerated to move toward the target 5230 side by an electric field, and then collides with the target 5230. At this time, the pellet 5200 which is a flat-plate-like or pellet-like sputtered particle is separated from the cleavage plane (see FIG. 25A).

The pellet 5200 corresponds to a portion between the two cleavage planes shown in FIG. 26. Thus, when the pellet 5200 is observed, the cross-section thereof is as shown in FIG. 25B, and the top surface thereof is as shown in FIG. 25C. Note that structure of the pellet 5200 may be distorted by an impact of collision of the ion 5201. Note that along with the separation of the pellet 5200, a particle 5203 is also sputtered from the target 5230. The particle 5203 has an atom or an aggregate of several atoms. Therefore, the particle 5203 can be referred to as an atomic particle.

The pellet 5200 is a flat-plate-like (pellet-like) sputtered particle having a triangle plane, e.g., regular triangle plane. Alternatively, the pellet 5200 is a flat-plate-like (pellet-like) sputtered particle having a hexagon plane, e.g., regular hexagon plane. However, the shape of a flat plane of the pellet 5200 is not limited to a triangle or a hexagon. For example, the flat plane may have a shape formed by combining two or more triangles. For example, a quadrangle (e.g., rhombus) may be formed by combining two triangles (e.g., regular triangles).

The thickness of the pellet 5200 is determined depending on the kind of deposition gas and the like. For example, the thickness of the pellet 5200 is greater than or equal to 0.4 nm and less than or equal to 1 nm, preferably greater than or equal to 0.6 nm and less than or equal to 0.8 nm. In addition, the width of the pellet 5200 is, for example, greater than or equal to 1 nm and less than or equal to 3 nm, preferably greater than or equal to 1.2 nm and less than or equal to 2.5 nm. For example, the ion 5201 collides with the target 5230 including the In-M-Zn oxide. Then, the pellet 5200 including three layers of an M-Zn—O layer, an In—O layer, and an M-Zn—O layer is separated. Note that along with the separation of the pellet 5200, a particle 5203 is also sputtered from the target 5230.

The pellet 5200 may receive a charge when passing through the plasma 5240, so that surfaces thereof are negatively or positively charged. For example, the pellet 5200 receives a negative charge from O²⁻ in the plasma 5240. As a result, oxygen atoms on the surfaces of the pellet 5200 may be negatively charged. In addition, when passing through the plasma 5240, the pellet 5200 is sometimes combined with indium, the element M, zinc, oxygen, or the like in the plasma 5240 to grow up.

The pellet 5200 and the particle 5203 that have passed through the plasma 5240 reach the surface of the substrate 5220. Note that part of the particle 5203 is discharged to the outside by a vacuum pump or the like because the particle 5203 is small in mass.

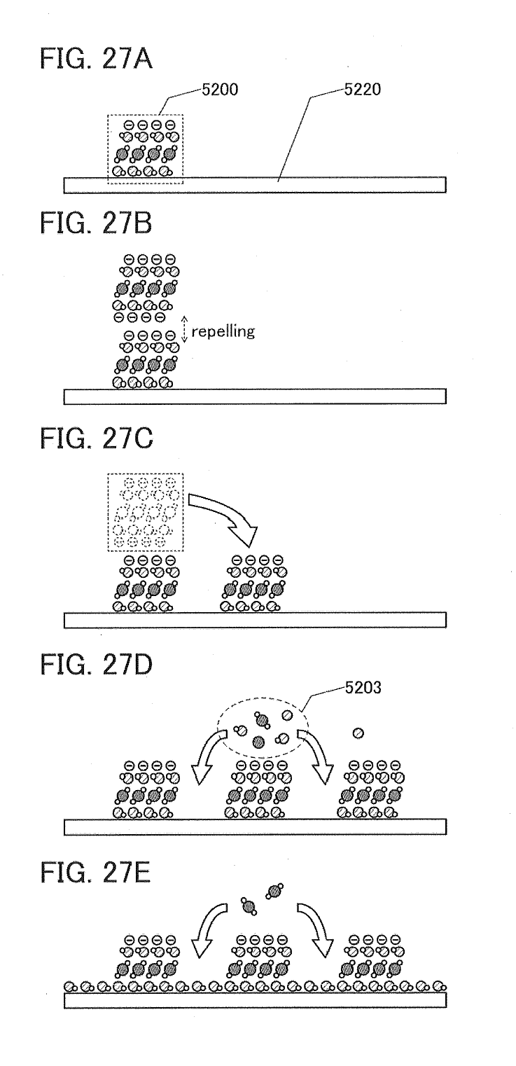

Next, deposition of the pellet 5200 and the particle 5203 over the surface of the substrate 5220 is described with reference to FIGS. 27A to 27E.

First, a first of the pellets 5200 is deposited over the substrate 5220. Since the pellet 5200 has a flat-plate-like shape, it is deposited so that the flat plane faces the surface of the substrate 5220 (FIG. 27A). Here, a charge on a surface of the pellet 5200 on the substrate 5220 side is lost through the substrate 5220.

Next, a second of the pellets 5200 reaches the substrate 5220. Here, since the surface of the first of the pellets 5200 and the surface of the second of the pellets 5200 are charged, they repel each other (FIG. 27B).

As a result, the second of the pellets 5200 avoids being deposited over the first of the pellets 5200, and is deposited over the surface of the substrate 5220 so as to be a little distance away from the first of the pellets 5200 (FIG. 27C). With repetition of this, millions of pellets 5200 are deposited over the surface of the substrate 5220 to have a thickness of one layer. A region where any pellet 5200 is not deposited is generated between adjacent pellets 5200.

Next, the particle 5203 reaches the surface of the substrate 5220 (FIG. 27D).

The particle 5203 cannot be deposited over an active region such as the surface of the pellet 5200. Therefore, the particle 5203 is deposited so as to fill a region where the pellets 5200 are not deposited. The particles 5203 grow in the horizontal (lateral) direction between the pellets 5200, thereby connecting the pellets 5200. In this way, the particles 5203 are deposited until they fill regions where the pellets 5200 are not deposited. This mechanism is similar to a deposition mechanism of an atomic layer deposition (ALD) method.

Note that there can be several mechanisms for the lateral growth of the particles 5203 between the pellets 5200. For example, as shown in FIG. 27E, the pellets 5200 can be connected from side surfaces of the first M-Zn—O layers. In this case, after the first M-Zn—O layers make connection, the In—O layers and the second M-Zn—O layers are connected in this order (the first mechanism).

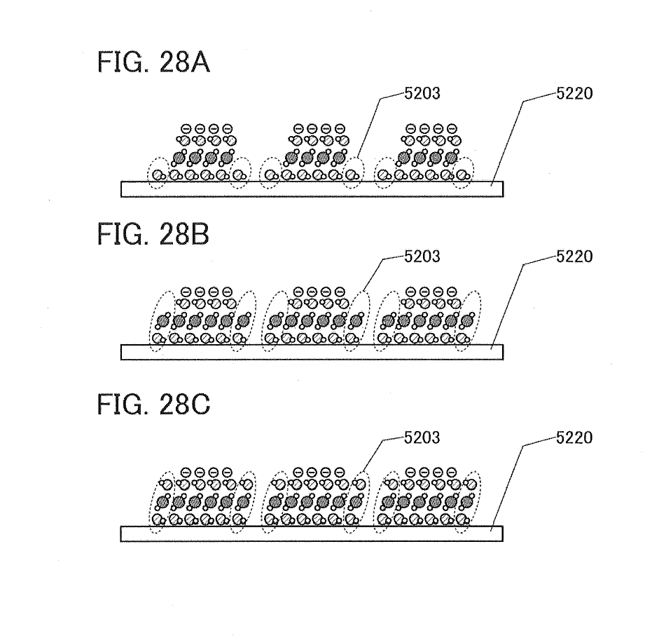

Alternatively, as shown in FIG. 28A, first, the particles 5203 are connected to the sides of the first M-Zn—O layers so that each side of the first M-Zn—O layer has one particle 5203. Then, as shown in FIG. 28B, the particle 5203 is connected to each side of the In—O layers. After that, as shown in FIG. 28C, the particle 5203 is connected to each side of the second M-Zn—O layers (the second mechanism).

Note that the connection can also be made by the simultaneous occurrence of the deposition in FIGS. 28A, 28B, and 28C (the third mechanism).

As shown in the above, the above three mechanisms are considered as the mechanisms of the lateral growth of the particles 5203 between the pellets 5200. However, the particles 5203 may grow up laterally between the pellets 5200 by other mechanisms.

Therefore, even when the orientations of a plurality of pellets 5200 are different from each other, generation of crystal boundaries can be suppressed since the particles 5203 laterally grow to fill gaps between the plurality of pellets 5200. In addition, as the particles 5203 make smooth connection between the plurality of pellets 5200, a crystal structure different from a single crystal and a polycrystal is formed. In other words, a crystal structure including distortion between minute crystal regions (pellets 5200) is formed. The regions filling the gaps between the crystal regions are distorted crystal regions, and thus, it will be not appropriate to say that the regions have an amorphous structure.

After the gaps between the pellets 5200 are filled with the particles 5203, a first layer with a thickness approximately the same as that of the pellet 5200 is formed. Then, a new first of the pellets 5200 is deposited over the first layer, and a second layer is formed. With repetition of this cycle, the stacked-layer thin film structure is formed.

A deposition way of the pellets 5200 changes depending on the surface temperature of the substrate 5220 or the like. For example, if the surface temperature of the substrate 5220 is high, migration of the pellets 5200 occurs over the substrate 5220. As a result, a proportion of the pellets 5200 that are directly connected with each other without the particles 5203 increases, whereby a CAAC-OS with high orientation is made. The surface temperature of the substrate 5220 for formation of the CAAC-OS is higher than or equal to 100° C. and lower than 500° C., preferably higher than or equal to 140° C. and lower than 450° C., and further preferably higher than or equal to 170° C. and lower than 400° C. Therefore, even when a large-sized substrate of the 8th generation or more is used as the substrate 5220, a warp or the like hardly occurs.

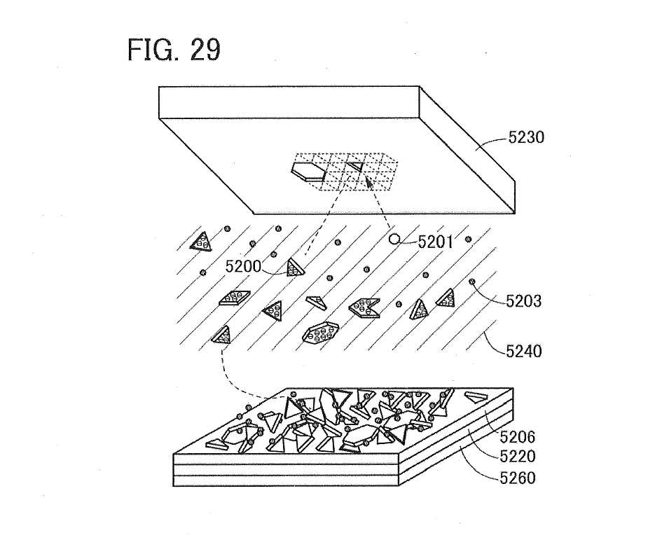

On the other hand, if the surface temperature of the substrate 5220 is low, the migration of the pellets 5200 over the substrate 5220 does not easily occur. As a result, the pellets 5200 overlap with each other, whereby an nc-OS with low orientation or the like is made (see FIG. 29). In the nc-OS, the pellets 5200 are possibly deposited with certain gaps because the pellets 5200 are negatively charged. Therefore, the nc-OS film has low orientation but some regularity, and thus it has a denser structure than an amorphous oxide semiconductor.

When gaps between the pellets are extremely small in a CAAC-OS, the pellets may form a large pellet. The inside of the large pellet has a single crystal structure. For example, the size of the pellet may be greater than or equal to 10 nm and less than or equal to 200 nm, greater than or equal to 15 nm and less than or equal to 100 nm, or greater than or equal to 20 nm and less than or equal to 50 nm, when seen from the above.

According to such a model, the pellets 5200 are considered to be deposited on the surface of the substrate 5220. Thus, a CAAC-OS can be deposited even when a formation surface does not have a crystal structure; therefore, a growth mechanism in this case is different from epitaxial growth. In addition, a uniform film of a CAAC-OS or an nc-OS can be formed even over a large-sized glass substrate or the like. For example, even when the surface of the substrate 5220 (formation surface) has an amorphous structure (e.g., amorphous silicon oxide), a CAAC-OS can be formed.

Furthermore, it is found that the pellets 5200 are arranged in accordance with a surface shape of the substrate 5220 that is the film formation surface even when the film formation surface has unevenness.

The structure and method described in this embodiment can be combined as appropriate with any of the other structures and methods described in the other embodiments and examples.

### Embodiment 3

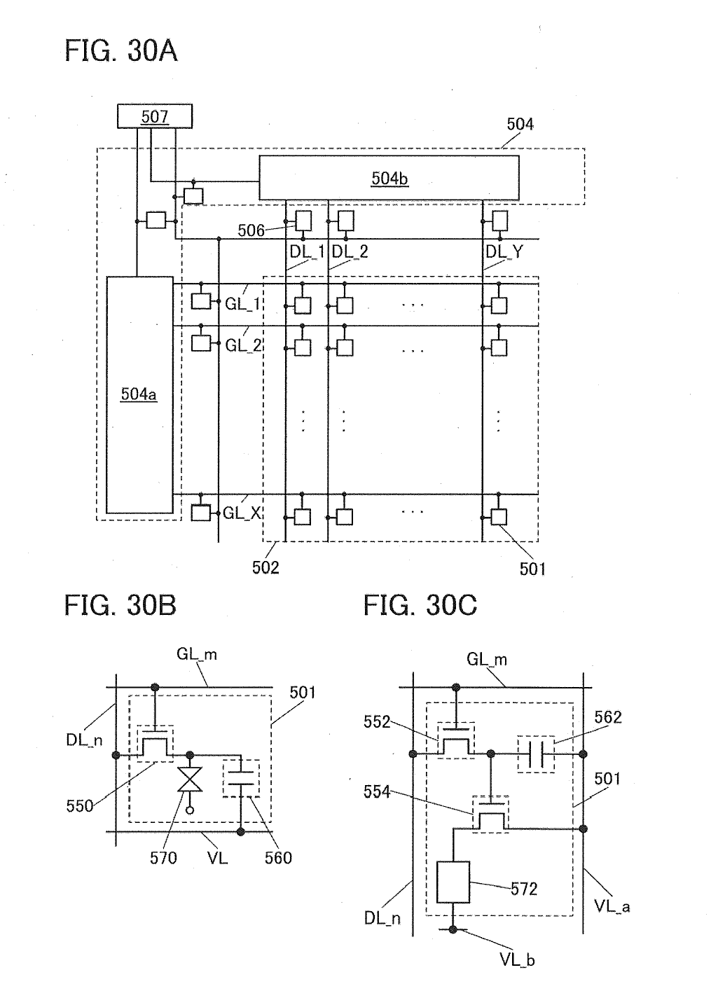

In this embodiment, a display device that includes a semiconductor device of one embodiment of the present invention is described with reference to FIGS. 30A to 30C.

### <Display Device>

The display device illustrated in FIG. 30A includes a region including pixels of display elements (hereinafter the region is referred to as a pixel portion 502), a circuit portion provided outside the pixel portion 502 and including a circuit for driving the pixels (hereinafter the portion is referred to as a driver circuit portion 504), circuits each having a function of protecting an element (hereinafter the circuits are referred to as protection circuits 506), and a terminal portion 507. Note that the protection circuits 506 are not necessarily provided.

A part or the whole of the driver circuit portion 504 is preferably formed over a substrate over which the pixel portion 502 is formed, in which case the number of components and the number of terminals can be reduced. When a part or the whole of the driver circuit portion 504 is not formed over the substrate over which the pixel portion 502 is formed, the part or the whole of the driver circuit portion 504 can be mounted by COG or tape automated bonding (TAB).

The pixel portion 502 includes a plurality of circuits for driving display elements arranged in X rows (X is a natural number of 2 or more) and Y columns (Y is a natural number of 2 or more) (hereinafter, such circuits are referred to as pixel circuits 501). The driver circuit portion 504 includes driver circuits such as a circuit for supplying a signal (scan signal) to select a pixel (hereinafter, the circuit is referred to as a gate driver 504a) and a circuit for supplying a signal (data signal) to drive a display element in a pixel (hereinafter, the circuit is referred to as a source driver 504b).

The gate driver 504a includes a shift register or the like. The gate driver 504a receives a signal for driving the shift register through the terminal portion 507 and outputs a signal. For example, the gate driver 504a receives a start pulse signal, a clock signal, or the like and outputs a pulse signal. The gate driver 504a has a function of controlling the potentials of wirings supplied with scan signals (hereinafter, such wirings are referred to as scan lines GL_1 to GL_X). Note that a plurality of gate drivers 504a may be provided to control the scan lines GL_1 to GL_X separately. Alternatively, the gate driver 504a has a function of supplying an initialization signal. Without being limited thereto, the gate driver 504a can supply another signal.

The source driver 504b includes a shift register or the like. The source driver 504b receives a signal (video signal) from which a data signal is derived, as well as a signal for driving the shift register, through the terminal portion 507. The source driver 504b has a function of generating a data signal to be written to the pixel circuit 501 which is based on the video signal. In addition, the source driver 504b has a function of controlling output of a data signal in response to a pulse signal produced by input of a start pulse signal, a clock signal, or the like. Furthermore, the source driver 504b has a function of controlling the potentials of wirings supplied with data signals (hereinafter such wirings are referred to as data lines DL_1 to DL_Y). Alternatively, the source driver 504b has a function of supplying an initialization signal. Without being limited thereto, the source driver 504b can supply another signal.

The source driver 504b includes a plurality of analog switches or the like, for example. The source driver 504b can output, as the data signals, signals obtained by time-dividing the video signal by sequentially turning on the plurality of analog switches. The source driver 504b may include a shift register or the like.

A pulse signal and a data signal are input to each of the plurality of pixel circuits 501 through one of the plurality of scan lines GL supplied with scan signals and one of the plurality of data lines DL supplied with data signals, respectively. Writing and holding of the data signal to and in each of the plurality of pixel circuits 501 are controlled by the gate driver 504a. For example, to the pixel circuit 501 in the m-th row and the n-th column (m is a natural number of less than or equal to X, and n is a natural number of less than or equal to Y), a pulse signal is input from the gate driver 504a through the scan line GL_m, and a data signal is input from the source driver 504b through the data line DL_n in accordance with the potential of the scan line GL_m.

The protection circuit 506 shown in FIG. 30A is connected to, for example, the scan line GL between the gate driver 504a and the pixel circuit 501. Alternatively, the protection circuit 506 is connected to the data line DL between the source driver 504b and the pixel circuit 501. Alternatively, the protection circuit 506 can be connected to a wiring between the gate driver 504a and the terminal portion 507. Alternatively, the protection circuit 506 can be connected to a wiring between the source driver 504b and the terminal portion 507. Note that the terminal portion 507 means a portion having terminals for inputting power, control signals, and video signals to the display device from external circuits.

The protection circuit 506 is a circuit that electrically connects a wiring connected to the protection circuit to another wiring when a potential out of a certain range is applied to the wiring connected to the protection circuit.

As illustrated in FIG. 30A, the protection circuits 506 are provided for the pixel portion 502 and the driver circuit portion 504, so that the resistance of the display device to overcurrent generated by electrostatic discharge (ESD) or the like can be improved. Note that the configuration of the protection circuits 506 is not limited to that, and for example, the protection circuit 506 may be configured to be connected to the gate driver 504a or the protection circuit 506 may be configured to be connected to the source driver 504b. Alternatively, the protection circuit 506 may be configured to be connected to the terminal portion 507.

In FIG. 30A, an example in which the driver circuit portion 504 includes the gate driver 504a and the source driver 504b is shown; however, the structure is not limited thereto. For example, only the gate driver 504a may be formed and a separately prepared substrate where a source driver circuit is formed (e.g., a driver circuit substrate formed with a single crystal semiconductor film or a polycrystalline semiconductor film) may be mounted.

Each of the plurality of pixel circuits 501 in FIG. 30A can have the structure illustrated in FIG. 30B, for example.

The pixel circuit 501 illustrated in FIG. 30B includes a liquid crystal element 570, a transistor 550, and a capacitor 560. As the transistor 550, any of the transistors described in the above embodiments can be used.

The potential of one of a pair of electrodes of the liquid crystal element 570 is set in accordance with the specifications of the pixel circuit 501 as appropriate. The alignment state of the liquid crystal element 570 depends on written data. A common potential may be supplied to one of the pair of electrodes of the liquid crystal element 570 included in each of the plurality of pixel circuits 501. Furthermore, the potential supplied to one of the pair of electrodes of the liquid crystal element 570 in the pixel circuit 501 in one row may be different from the potential supplied to one of the pair of electrodes of the liquid crystal element 570 in the pixel circuit 501 in another row.

As a driving method of the display device including the liquid crystal element 570, any of the following modes can be used, for example: a twisted nematic (TN) mode, a super-twisted nematic (STN) mode, a vertical alignment (VA) mode, a multi-domain vertical alignment (MVA) mode, a patterned vertical alignment (PVA) mode, an in-plane-switching (IPS) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, an FFS mode, a transverse bend alignment (TBA) mode, and the like.

Other examples of the driving method of the display device include an electrically controlled birefringence (ECB) mode, a polymer dispersed liquid crystal (PDLC) mode, a polymer network liquid crystal (PNLC) mode, and a guest-host mode. Note that the present invention is not limited to these examples, and various liquid crystal elements and driving methods can be applied to the liquid crystal element and the driving method thereof.

In the pixel circuit 501 in the m-th row and the n-th column, one of a source electrode and a drain electrode of the transistor 550 is electrically connected to the data line DL_n, and the other is electrically connected to the other of the pair of electrodes of the liquid crystal element 570. A gate electrode of the transistor 550 is electrically connected to the scan line GL_m. The transistor 550 has a function of controlling whether to write a data signal by being turned on or off.

One of a pair of electrodes of the capacitor 560 is electrically connected to a wiring to which a potential is supplied (hereinafter referred to as a potential supply line VL), and the other is electrically connected to the other of the pair of electrodes of the liquid crystal element 570. The potential of the potential supply line VL is set in accordance with the specifications of the pixel circuit 501 as appropriate. The capacitor 560 functions as a storage capacitor for storing written data.

For example, in the display device including the pixel circuit 501 in FIG. 30B, the pixel circuits 501 are sequentially selected row by row by the gate driver 504a illustrated in FIG. 30A, whereby the transistors 550 are turned on and a data signal is written.

When the transistors 550 are turned off, the pixel circuits 501 in which the data has been written are brought into a holding state. This operation is sequentially performed row by row; thus, an image can be displayed.

Alternatively, each of the plurality of pixel circuits 501 in FIG. 30A can have the structure illustrated in FIG. 30C, for example.

The pixel circuit 501 illustrated in FIG. 30C includes transistors 552 and 554, a capacitor 562, and a light-emitting element 572. Any of the transistors described in the above embodiments can be used as one or both of the transistors 552 and 554.

One of a source electrode and a drain electrode of the transistor 552 is electrically connected to a wiring to which a data signal is supplied (hereinafter referred to as a signal line DL_n). A gate electrode of the transistor 552 is electrically connected to a wiring to which a gate signal is supplied (hereinafter referred to as a scan line GL_m).

The transistor 552 has a function of controlling whether to write a data signal by being turned on or off.

One of a pair of electrodes of the capacitor 562 is electrically connected to a wiring to which a potential is supplied (hereinafter referred to as a potential supply line VL_a), and the other is electrically connected to the other of the source electrode and the drain electrode of the transistor 552.

The capacitor 562 functions as a storage capacitor for storing written data.

One of a source electrode and a drain electrode of the transistor 554 is electrically connected to the potential supply line VL_a. Furthermore, a gate electrode of the transistor 554 is electrically connected to the other of the source electrode and the drain electrode of the transistor 552.

One of an anode and a cathode of the light-emitting element 572 is electrically connected to a potential supply line VL_b, and the other is electrically connected to the other of the source electrode and the drain electrode of the transistor 554.

As the light-emitting element 572, an organic electroluminescent element (also referred to as an organic EL element) or the like can be used, for example. Note that the light-emitting element 572 is not limited to an organic EL element; an inorganic EL element including an inorganic material may be used.

A high power supply potential VDD is supplied to one of the potential supply line VL_a and the potential supply line VL_b, and a low power supply potential VSS is supplied to the other.

For example, in the display device including the pixel circuit 501 in FIG. 30C, the pixel circuits 501 are sequentially selected row by row by the gate driver 504a illustrated in FIG. 30A, whereby the transistors 552 are turned on and a data signal is written.

When the transistors 552 are turned off, the pixel circuits 501 in which the data has been written are brought into a holding state. Furthermore, the amount of current flowing between the source electrode and the drain electrode of the transistor 554 is controlled in accordance with the potential of the written data signal. The light-emitting element 572 emits light with a luminance corresponding to the amount of flowing current. This operation is sequentially performed row by row; thus, an image can be displayed.

Although the structures including the liquid crystal element 570 or the light-emitting element 572 as a display element of the display device are described in this embodiment, one embodiment of the present invention is not limited to these structures and a variety of elements may be included in the display device.

For example, the display device includes at least one of a liquid crystal element, an EL element (e.g., an EL element including organic and inorganic materials, an organic EL element, or an inorganic EL element), an LED (e.g., a white LED, a red LED, a green LED, or a blue LED), a transistor (a transistor that emits light depending on current), an electron emitter, electronic ink, an electrophoretic element, a grating light valve (GLV), a plasma display panel (PDP), a display element using micro electro mechanical systems (MEMS), a digital micromirror device (DMD), a digital micro shutter (DMS), MIRASOL (registered trademark), an interferometric modulator display (IMOD) element, a MEMS shutter display element, an optical-interference-type MEMS display element, an electrowetting element, a piezoelectric ceramic display, a display element using a carbon nanotube, and the like. Alternatively, the display device may include a display medium whose contrast, luminance, reflectivity, transmittance, or the like is changed by electrical or magnetic effect. Examples of display devices including electron emitters are a field emission display (FED) and an SED-type flat panel display (SED: surface-conduction electron-emitter display). Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display). An example of a display device including electronic ink or electrophoretic elements is electronic paper. In the case of a transflective liquid crystal display or a reflective liquid crystal display, some of or all of pixel electrodes function as reflective electrodes. For example, some or all of pixel electrodes are formed to contain aluminum, silver, or the like. In such a case, a memory circuit such as an SRAM can be provided under the reflective electrodes. Thus, the power consumption can be further reduced.

A progressive type display, an interlace type display, or the like can be employed as the display type of the display device of this embodiment. Further, color elements controlled in a pixel at the time of color display are not limited to three colors: R, G, and B (R, G, and B correspond to red, green, and blue, respectively). For example, four pixels of the R pixel, the G pixel, the B pixel, and a W (white) pixel may be included. Alternatively, a color element may be composed of two colors among R, G, and B as in PenTile layout. The two colors may differ among color elements. Alternatively, one or more colors of yellow, cyan, magenta, and the like may be added to RGB. Further, the size of a display region may be different depending on respective dots of the color elements. Embodiments of the disclosed invention are not limited to a display device for color display; the disclosed invention can also be applied to a display device for monochrome display.

White light (W) may be emitted from a backlight (e.g., an organic EL element, an inorganic EL element, an LED, or a fluorescent lamp) in the display device. Furthermore, a coloring layer (also referred to as a color filter) may be provided in the display device. As the coloring layer, red (R), green (G), blue (B), yellow (Y), or the like may be combined as appropriate, for example. With the use of the coloring layer, higher color reproducibility can be obtained than in the case without the coloring layer. In this case, by providing a region with the coloring layer and a region without the coloring layer, white light in the region without the coloring layer may be directly utilized for display. By partly providing the region without the coloring layer, a decrease in luminance due to the coloring layer can be suppressed, and 20% to 30% of power consumption can be reduced in some cases when an image is displayed brightly. Note that in the case where full-color display is performed using self-luminous elements such as organic EL elements or inorganic EL elements, the elements may emit light of their respective colors R, G, B, Y, and W. By using self-luminous elements, power consumption can be further reduced as compared to the case of using the coloring layer in some cases.

The structure described in this embodiment can be combined as appropriate with any of the structures described in the other embodiments and examples.

### Embodiment 4

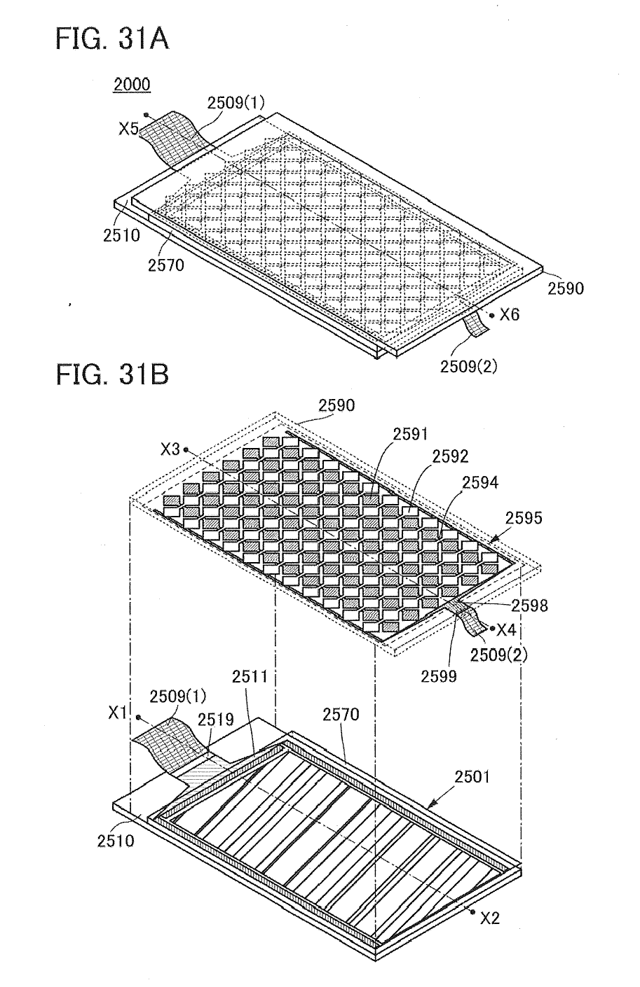

In this embodiment, a display device including a semiconductor device of one embodiment of the present invention and an electronic device in which the display device is provided with an input device will be described with reference to FIGS. 31A and 31B, FIGS. 32A and 32B, FIG. 33, FIGS. 34A and 34B, FIGS. 35A and 35B, and FIG. 36.

### <Touch Panel>

In this embodiment, a touch panel 2000 including a display device and an input device will be described as an example of an electronic device. In addition, an example in which a touch sensor is used as an input device will be described.

FIGS. 31A and 31B are perspective views of the touch panel 2000. Note that FIGS. 31A and 31B illustrate only main components of the touch panel 2000 for simplicity.

The touch panel 2000 includes a display device 2501 and a touch sensor 2595 (see FIG. 31B). The touch panel 2000 also includes a substrate 2510, a substrate 2570, and a substrate 2590. The substrate 2510, the substrate 2570, and the substrate 2590 each have flexibility. Note that one or all of the substrates 2510, 2570, and 2590 may be inflexible.

The display device 2501 includes a plurality of pixels over the substrate 2510 and a plurality of wirings 2511 through which signals are supplied to the pixels. The plurality of wirings 2511 are led to a peripheral portion of the substrate 2510, and parts of the plurality of wirings 2511 form a terminal 2519. The terminal 2519 is electrically connected to an FPC 2509(1).

The substrate 2590 includes the touch sensor 2595 and a plurality of wirings 2598 electrically connected to the touch sensor 2595. The plurality of wirings 2598 are led to a peripheral portion of the substrate 2590, and parts of the plurality of wirings 2598 form a terminal. The terminal is electrically connected to an FPC 2509(2). Note that in FIG. 31B, electrodes, wirings, and the like of the touch sensor 2595 provided on the back side of the substrate 2590 (the side facing the substrate 2510) are indicated by solid lines for clarity.

As the touch sensor 2595, a capacitive touch sensor can be used. Examples of the capacitive touch sensor are a surface capacitive touch sensor and a projected capacitive touch sensor.

Examples of the projected capacitive touch sensor are a self capacitive touch sensor and a mutual capacitive touch sensor, which differ mainly in the driving method. The use of a mutual capacitive type is preferable because multiple points can be sensed simultaneously.

Note that the touch sensor 2595 illustrated in FIG. 31B is an example of using a projected capacitive touch sensor.

Note that a variety of sensors that can sense proximity or touch of a sensing target such as a finger can be used as the touch sensor 2595.

The projected capacitive touch sensor 2595 includes electrodes 2591 and electrodes 2592. The electrodes 2591 are electrically connected to any of the plurality of wirings 2598, and the electrodes 2592 are electrically connected to any of the other wirings 2598.

The electrodes 2592 each have a shape of a plurality of quadrangles arranged in one direction with one corner of a quadrangle connected to one corner of another quadrangle as illustrated in FIGS. 31A and 31B.

The electrodes 2591 each have a quadrangular shape and are arranged in a direction intersecting with the direction in which the electrodes 2592 extend.

A wiring 2594 electrically connects two electrodes 2591 between which the electrode 2592 is positioned. The intersecting area of the electrode 2592 and the wiring 2594 is preferably as small as possible. Such a structure allows a reduction in the area of a region where the electrodes are not provided, reducing variation in transmittance. As a result, variation in luminance of light passing through the touch sensor 2595 can be reduced.

Note that the shapes of the electrodes 2591 and the electrodes 2592 are not limited thereto and can be any of a variety of shapes. For example, a structure may be employed in which the plurality of electrodes 2591 are arranged so that gaps between the electrodes 2591 are reduced as much as possible, and the electrodes 2592 are spaced apart from the electrodes 2591 with an insulating layer interposed therebetween to have regions not overlapping with the electrodes 2591. In this case, it is preferable to provide, between two adjacent electrodes 2592, a dummy electrode electrically insulated from these electrodes because the area of regions having different transmittances can be reduced.

Note that as a material of the conductive films used for the electrodes 2591, the electrodes 2592, and the wirings 2598, that is, wirings and electrodes forming the touch panel, a transparent conductive film containing indium oxide, tin oxide, zinc oxide, or the like (e.g., ITO) can be given. For example, a low-resistance material is preferably used as a material that can be used as the wirings and electrodes forming the touch panel. For example, silver, copper, aluminum, a carbon nanotube, graphene, or a metal halide (such as a silver halide) may be used. Alternatively, a metal nanowire including a plurality of conductors with an extremely small width (for example, a diameter of several nanometers) may be used. Further alternatively, a net-like metal mesh with a conductor may be used. For example, an Ag nanowire, a Cu nanowire, an Al nanowire, an Ag mesh, a Cu mesh, or an Al mesh may be used. For example, in the case of using an Ag nanowire as the wirings and electrodes forming the touch panel, a visible light transmittance of 89% or more and a sheet resistance of 40 ∩/cm² or more and 100 Ω/cm² or less can be achieved. Since the above-described metal nanowire, metal mesh, carbon nanotube, graphene, and the like, which are examples of the material that can be used as the wirings and electrodes forming the touch panel, have high visible light transmittances, they may be used as electrodes of display elements (e.g., a pixel electrode or a common electrode).

### <Display Device>

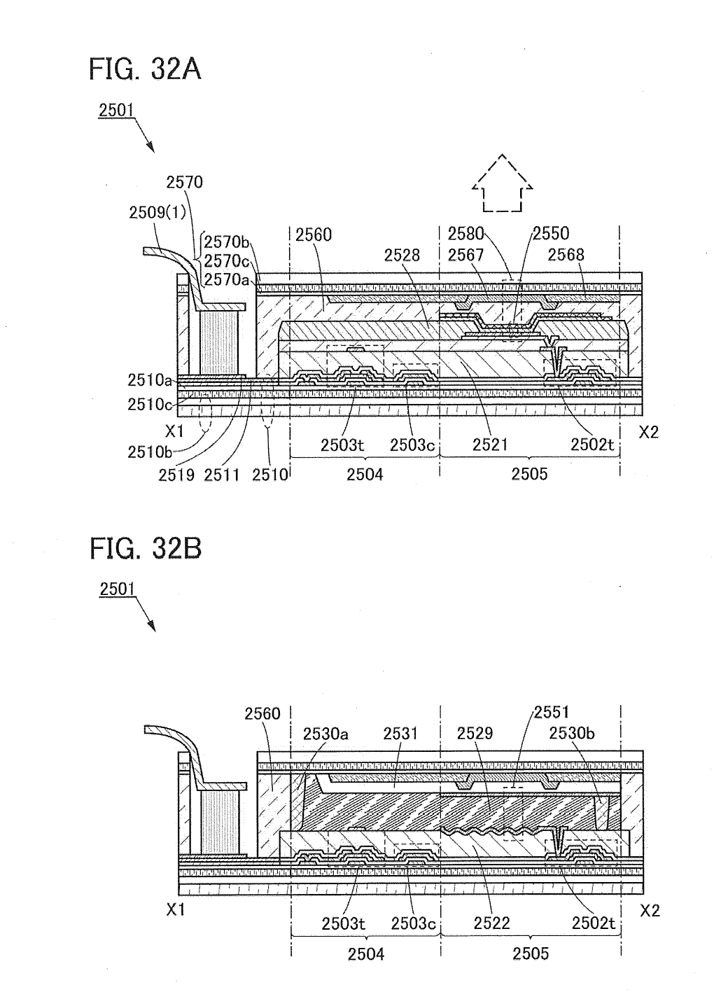

Next, the display device 2501 will be described in detail with reference to FIGS. 32A and 32B. FIGS. 32A and 32B correspond to cross-sectional views taken along dashed-dotted line X1-X2 in FIG. 31B.

The display device 2501 includes a plurality of pixels arranged in a matrix. Each of the pixels includes a display element and a pixel circuit for driving the display element.

(Structure with EL Element as Display Element)

First, a structure that uses an EL element as a display element will be described below with reference to FIG. 32A. In the following description, an example of using an EL element that emits white light will be described; however, the EL element is not limited to this element. For example, EL elements that emit light of different colors may be included so that the light of different colors can be emitted from adjacent pixels.

For the substrate 2510 and the substrate 2570, for example, a flexible material with a vapor permeability of lower than or equal to 10⁻⁵ g/(m²·day), preferably lower than or equal to 10⁻⁶ g/(m²·day) can be favorably used. Alternatively, materials whose thermal expansion coefficients are substantially equal to each other are preferably used for the substrate 2510 and the substrate 2570. For example, the coefficients of linear expansion of the materials are preferably lower than or equal to 1×10⁻³/K, further preferably lower than or equal to 5×10⁻⁵/K, and still further preferably lower than or equal to 1×10⁻⁵/K.

Note that the substrate 2510 is a stacked body including an insulating layer 2510a for preventing impurity diffusion into the EL element, a flexible substrate 2510b, and an adhesive layer 2510c for attaching the insulating layer 2510a and the flexible substrate 2510b to each other. The substrate 2570 is a stacked body including an insulating layer 2570a for preventing impurity diffusion into the EL element, a flexible substrate 2570b, and an adhesive layer 2570c for attaching the insulating layer 2570a and the flexible substrate 2570b to each other.

For the adhesive layer 2510c and the adhesive layer 2570c, for example, materials that include polyester, polyolefin, polyamide (e.g., nylon, aramid), polyimide, polycarbonate, polyurethane, an acrylic resin, an epoxy resin, or a resin having a siloxane bond can be used.

A sealing layer 2560 is provided between the substrate 2510 and the substrate 2570. The sealing layer 2560 preferably has a refractive index higher than that of air. In the case where light is extracted to the sealing layer 2560 side as illustrated in FIG. 32A, the sealing layer 2560 can also serve as an optical element.

A sealant may be formed in the peripheral portion of the sealing layer 2560. With the use of the sealant, an EL element 2550 can be provided in a region surrounded by the substrate 2510, the substrate 2570, the sealing layer 2560, and the sealant. Note that an inert gas (such as nitrogen or argon) may be used instead of the sealing layer 2560. A drying agent may be provided in the inert gas so as to adsorb moisture or the like. For example, an epoxy-based resin or a glass frit is preferably used as the sealant. As a material used for the sealant, a material which does not transmit moisture or oxygen is preferably used.

The display device 2501 illustrated in FIG. 32A includes a pixel 2505. The pixel 2505 includes a light-emitting module 2580, the EL element 2550, and a transistor 2502t that can supply electric power to the EL element 2550. Note that the transistor 2502t functions as part of the pixel circuit.

The light-emitting module 2580 includes the EL element 2550 and a coloring layer 2567. The EL element 2550 includes a lower electrode, an upper electrode, and an EL layer between the lower electrode and the upper electrode.

In the case where the sealing layer 2560 is provided on the light extraction side, the sealing layer 2560 is in contact with the EL element 2550 and the coloring layer 2567.

The coloring layer 2567 is positioned in a region overlapping with the EL element 2550. Accordingly, part of light emitted from the EL element 2550 passes through the coloring layer 2567 and is emitted to the outside of the light-emitting module 2580 as indicated by an arrow in FIG. 32A.

The display device 2501 includes a light-blocking layer 2568 on the light extraction side. The light-blocking layer 2568 is provided so as to surround the coloring layer 2567.

The coloring layer 2567 is a coloring layer having a function of transmitting light in a particular wavelength region. For example, a color filter for transmitting light in a red wavelength range, a color filter for transmitting light in a green wavelength range, a color filter for transmitting light in a blue wavelength range, a color filter for transmitting light in a yellow wavelength range, or the like can be used. Each color filter can be formed with any of various materials by a printing method, an inkjet method, an etching method using a photolithography technique, or the like.

An insulating layer 2521 is provided in the display device 2501. The insulating layer 2521 covers the transistor 2502t and the like. Note that the insulating layer 2521 has a function of covering the roughness caused by the pixel circuit to provide a flat surface. The insulating layer 2521 may have a function of suppressing impurity diffusion. This can prevent the reliability of the transistor 2502t or the like from being lowered by impurity diffusion.

The EL element 2550 is formed over the insulating layer 2521. A partition 2528 is provided so as to overlap with an end portion of the lower electrode of the EL element 2550. Note that a spacer for controlling the distance between the substrate 2510 and the substrate 2570 may be formed over the partition 2528.

A scan line driver circuit 2504 includes a transistor 2503t and a capacitor 2503c. Note that the driver circuit can be formed in the same process and over the same substrate as those of the pixel circuits.

The wirings 2511 through which signals can be supplied are provided over the substrate 2510. The terminal 2519 is provided over the wirings 2511. The FPC 2509(1) is electrically connected to the terminal 2519. The FPC 2509(1) has a function of supplying a video signal, a clock signal, a start signal, a reset signal, or the like. Note that the FPC 2509(1) may be provided with a printed wiring board (PWB).

Any of the transistors described in the above embodiments may be used as one or both of the transistors 2502t and 2503t. The transistors used in this embodiment each include an oxide semiconductor film which is highly purified and in which formation of oxygen vacancies is suppressed. In the transistors, the current in an off state (off-state current) can be made small. Accordingly, an electrical signal such as an image signal can be held for a longer period, and a writing interval can be set longer in an on state. Accordingly, the frequency of refresh operation can be reduced, which leads to an effect of suppressing power consumption. In addition, the transistors used in this embodiment can have relatively high field-effect mobility and thus are capable of high speed operation. For example, with such transistors which can operate at high speed used for the display device 2501, a switching transistor of a pixel circuit and a driver transistor in a driver circuit portion can be formed over one substrate. That is, a semiconductor device formed using a silicon wafer or the like is not additionally needed as a driver circuit, by which the number of components of the semiconductor device can be reduced. In addition, by using a transistor which can operate at high speed in a pixel circuit, a high-quality image can be provided.

(Structure with Liquid Crystal Element as Display Element)

Next, a structure including a liquid crystal element as a display element is described below with reference to FIG. 32B. In the description below, a reflective liquid crystal display device that performs display by reflecting external light is described; however, one embodiment of the present invention is not limited to this type of liquid crystal display device. For example, a light source (e.g., a back light or a side light) may be provided to form a transmissive liquid crystal display device or a transflective liquid crystal display device.

The display device 2501 illustrated in FIG. 32B has the same structure as the display device 2501 illustrated in FIG. 32A except the following points.

The pixel 2505 in the display device 2501 illustrated in FIG. 32B includes a liquid crystal element 2551 and the transistor 2502t that can supply electric power to the liquid crystal element 2551.

The liquid crystal element 2551 includes a lower electrode (also referred to as a pixel electrode), an upper electrode, and a liquid crystal layer 2529 between the lower electrode and the upper electrode. By the application of a voltage between the lower electrode and the upper electrode, the alignment state of the liquid crystal layer 2529 in the liquid crystal element 2551 can be changed. Furthermore, in the liquid crystal layer 2529, a spacer 2530a and a spacer 2530b are provided. Although not illustrated in FIG. 32B, an alignment film may be provided on each of the upper electrode and the lower electrode on the side in contact with the liquid crystal layer 2529.

As the liquid crystal layer 2529, thermtropic liquid crystal, low-molecular liquid crystal, high-molecular liquid crystal, polymer dispersed liquid crystal, ferroelectric liquid crystal, or anti-ferroelectric liquid crystal can be used. Such a liquid crystal material exhibits a cholesteric phase, a smectic phase, a cubic phase, a chiral nematic phase, an isotropic phase, or the like depending on conditions. In the case of employing a horizontal electric field mode liquid crystal display device, liquid crystal exhibiting a blue phase for which an alignment film is unnecessary may be used. In the case where a liquid crystal exhibiting a blue phase is used, an alignment film is not necessarily provided, so that rubbing treatment is also unnecessary. Accordingly, electrostatic discharge damage caused by the rubbing treatment can be prevented and defects and damage of the liquid crystal display device in the manufacturing process can be reduced.

The spacers 2530a and 2530b are formed by selectively etching an insulating film. The spacers 2530a and 2530b are provided in order to control the distance between the substrate 2510 and the substrate 2570 (the cell gap). Note that the spacers 2530a and 2530b may have different sizes from each other and are preferably have a columnar or spherical shape. Although the spacers 2530a and 2530b are provided on the substrate 2570 side in the non-limiting structure in FIG. 32B, they may be provided on the substrate 2510 side.

The upper electrode of the liquid crystal element 2551 is provided on the substrate 2570 side. An insulating layer 2531 is provided between the upper electrode and the coloring layer 2567 and the light-blocking layer 2568. The insulating layer 2531 has a function of covering the roughness caused by the coloring layer 2567 and the light-blocking layer 2568 to provide a flat surface. As the insulating layer 2531, an organic resin film may be used, for example. The lower electrode of the liquid crystal element 2551 functions as a reflective electrode. The display device 2501 illustrated in FIG. 32B is of a reflective type which performs display by reflecting external light at the lower electrode and making the light pass through the coloring layer 2567. Note that in the case of forming a transmissive liquid crystal display device, a transparent electrode is provided as the lower electrode.

The display device 2501 illustrated in FIG. 32B includes an insulating layer 2522. The insulating layer 2522 covers the transistor 2502t and the like. The insulating layer 2522 has a function of covering the roughness caused by the pixel circuit to provide a flat surface and a function of forming roughness on the lower electrode of the liquid crystal element. In this way, roughness can be formed on the surface of the lower electrode. Therefore, when external light is incident on the lower electrode, the light is reflected diffusely at the surface of the lower electrode, whereby visibility can be improved. Note that in the case of forming a transmissive liquid crystal display device, a structure without such roughness may be employed.

### <Touch Sensor>

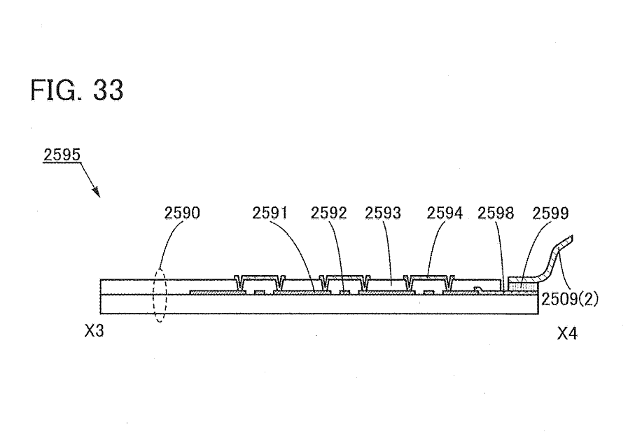

Next, the touch sensor 2595 will be described in detail with reference to FIG. 33. FIG. 33 corresponds to a cross-sectional view taken along dashed-dotted line X3-X4 in FIG. 31B.

The touch sensor 2595 includes the electrodes 2591 and the electrodes 2592 provided in a staggered arrangement on the substrate 2590, an insulating layer 2593 covering the electrodes 2591 and the electrodes 2592, and the wiring 2594 that electrically connects the adjacent electrodes 2591 to each other.

The electrodes 2591 and the electrodes 2592 are formed using a light-transmitting conductive material. As a light-transmitting conductive material, a conductive oxide such as indium oxide, indium tin oxide, indium zinc oxide, zinc oxide, or zinc oxide to which gallium is added can be used. Note that a film containing graphene may be used as well. The film containing graphene can be formed, for example, by reducing a film containing graphene oxide. As a reducing method, a method with application of heat or the like can be employed.

The electrodes 2591 and the electrodes 2592 may be formed by, for example, depositing a light-transmitting conductive material on the substrate 2590 by a sputtering method and then removing an unnecessary portion by any of various pattern forming techniques such as photolithography.

Examples of a material for the insulating layer 2593 are a resin such as an acrylic resin or an epoxy resin, a resin having a siloxane bond, and an inorganic insulating material such as silicon oxide, silicon oxynitride, or aluminum oxide.

Openings reaching the electrodes 2591 are formed in the insulating layer 2593, and the wiring 2594 electrically connects the adjacent electrodes 2591. A light-transmitting conductive material can be favorably used as the wiring 2594 because the aperture ratio of the touch panel can be increased. Moreover, a material with higher conductivity than the conductivities of the electrodes 2591 and 2592 can be favorably used for the wiring 2594 because electric resistance can be reduced.

One electrode 2592 extends in one direction, and a plurality of electrodes 2592 are provided in the form of stripes. The wiring 2594 intersects with the electrode 2592.

Adjacent electrodes 2591 are provided with one electrode 2592 provided therebetween. The wiring 2594 electrically connects the adjacent electrodes 2591.

Note that the plurality of electrodes 2591 are not necessarily arranged in the direction orthogonal to one electrode 2592 and may be arranged to intersect with one electrode 2592 at an angle of more than 0 degrees and less than 90 degrees.

The wiring 2598 is electrically connected to any of the electrodes 2591 and 2592. Part of the wiring 2598 functions as a terminal. For the wiring 2598, a metal material such as aluminum, gold, platinum, silver, nickel, titanium, tungsten, chromium, molybdenum, iron, cobalt, copper, or palladium or an alloy material containing any of these metal materials can be used.

Note that an insulating layer that covers the insulating layer 2593 and the wiring 2594 may be provided to protect the touch sensor 2595.

A connection layer 2599 electrically connects the wiring 2598 to the FPC 2509(2).

As the connection layer 2599, any of various anisotropic conductive films (ACF), anisotropic conductive pastes (ACP), or the like can be used.

### <Touch Panel>

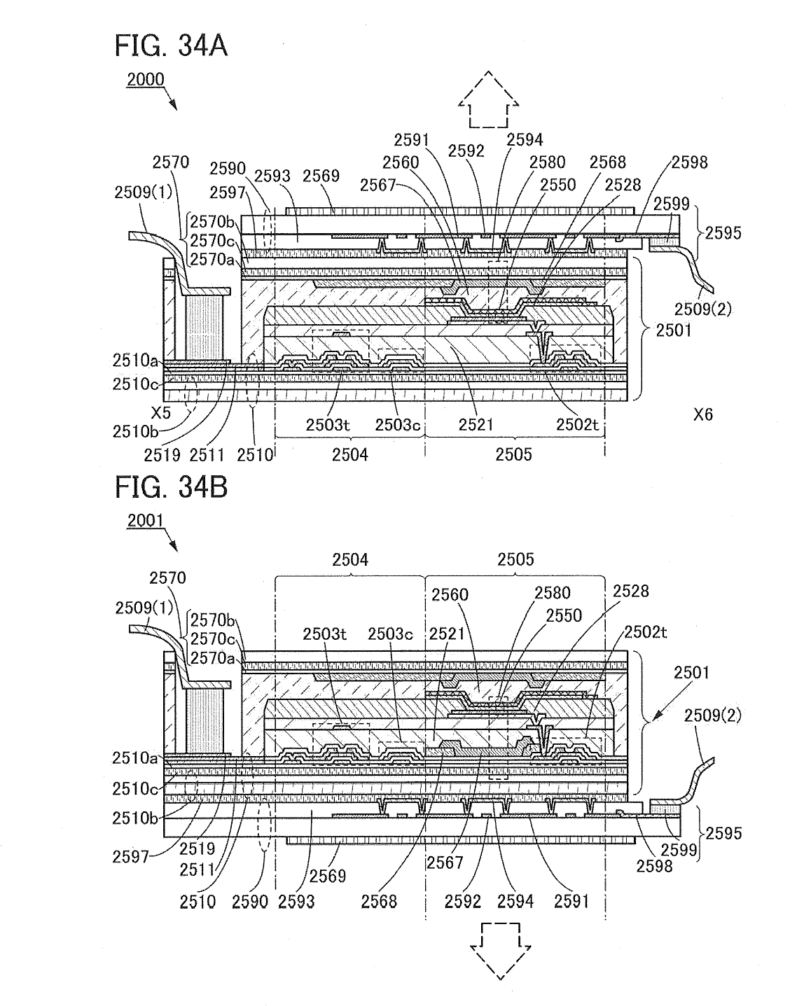

Next, the touch panel 2000 will be described in detail with reference to FIG. 34A. FIG. 34A corresponds to a cross-sectional view taken along dashed-dotted line X5-X6 in FIG. 31A.

In the touch panel 2000 illustrated in FIG. 34A, the display device 2501 described with reference to FIG. 32A and the touch sensor 2595 described with reference to FIG. 33 are attached to each other.

The touch panel 2000 illustrated in FIG. 34A includes an adhesive layer 2597 and an anti-reflective layer 2569 in addition to the components described with reference to FIG. 32A.

The adhesive layer 2597 is provided in contact with the wiring 2594. Note that the adhesive layer 2597 attaches the substrate 2590 to the substrate 2570 so that the touch sensor 2595 overlaps with the display device 2501. The adhesive layer 2597 preferably has a light-transmitting property. A heat curable resin or an ultraviolet curable resin can be used for the adhesive layer 2597. For example, an acrylic resin, a urethane-based resin, an epoxy-based resin, or a siloxane-based resin can be used.

The anti-reflective layer 2569 is positioned in a region overlapping with pixels. As the anti-reflective layer 2569, a circularly polarizing plate can be used, for example.

Next, a touch panel having a structure different from that illustrated in FIG. 34A will be described with reference to FIG. 34B.

FIG. 34B is a cross-sectional view of a touch panel 2001. The touch panel 2001 illustrated in FIG. 34B differs from the touch panel 2000 illustrated in FIG. 34A in the position of the touch sensor 2595 relative to the display device 2501. Different parts are described in detail below, and the above description of the touch panel 2000 is referred to for the other similar parts.

The coloring layer 2567 is positioned under the EL element 2550. The EL element 2550 illustrated in FIG. 34B emits light to the side where the transistor 2502t is provided. Accordingly, part of light emitted from the EL element 2550 passes through the coloring layer 2567 and is emitted to the outside of the light-emitting module 2580 as indicated by an arrow in FIG. 34B.

The touch sensor 2595 is provided on the substrate 2510 side of the display device 2501.

The adhesive layer 2597 is provided between the substrate 2510 and the substrate 2590 and attaches the touch sensor 2595 to the display device 2501.

As illustrated in FIG. 34A or FIG. 34B, light may be emitted from the light-emitting element to one or both of upper and lower sides of the substrate.

### <Driving Method of Touch Panel>

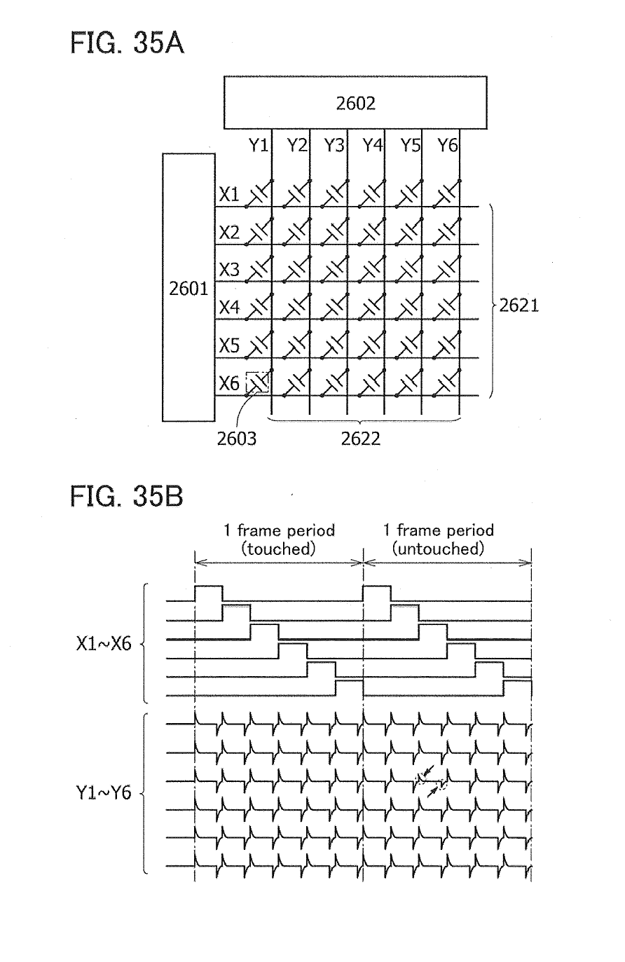

Next, an example of a method for driving a touch panel will be described with reference to FIGS. 35A and 35B.

FIG. 35A is a block diagram illustrating the structure of a mutual capacitive touch sensor. FIG. 35A illustrates a pulse voltage output circuit 2601 and a current sensing circuit 2602. Note that in FIG. 35A, six wirings X1 to X6 represent the electrodes 2621 to which a pulse voltage is applied, and six wirings Y1 to Y6 represent the electrodes 2622 that detect changes in current. FIG. 35A also illustrates capacitors 2603 that are each formed in a region where the electrodes 2621 and 2622 overlap with each other. Note that functional replacement between the electrodes 2621 and 2622 is possible.

The pulse voltage output circuit 2601 is a circuit for sequentially applying a pulse voltage to the wirings X1 to X6. By application of a pulse voltage to the wirings X1 to X6, an electric field is generated between the electrodes 2621 and 2622 of the capacitor 2603. When the electric field between the electrodes is shielded, for example, a change occurs in the capacitor 2603 (mutual capacitance). The approach or contact of a sensing target can be sensed by utilizing this change.

The current sensing circuit 2602 is a circuit for detecting changes in current flowing through the wirings Y1 to Y6 that are caused by the change in mutual capacitance in the capacitor 2603. No change in current value is detected in the wirings Y1 to Y6 when there is no approach or contact of a sensing target, whereas a decrease in current value is detected when mutual capacitance is decreased owing to the approach or contact of a sensing target. Note that an integrator circuit or the like is used for sensing of current values.

FIG. 35B is a timing chart showing input and output waveforms in the mutual capacitive touch sensor illustrated in FIG. 35A. In FIG. 35B, sensing of a sensing target is performed in all the rows and columns in one frame period. FIG. 35B shows a period when a sensing target is not sensed (not touched) and a period when a sensing target is sensed (touched). Sensed current values of the wirings Y1 to Y6 are shown as the waveforms of voltage values.

A pulse voltage is sequentially applied to the wirings X1 to X6, and the waveforms of the wirings Y1 to Y6 change in accordance with the pulse voltage. When there is no approach or contact of a sensing target, the waveforms of the wirings Y1 to Y6 change in accordance with changes in the voltages of the wirings X1 to X6. The current value is decreased at the point of approach or contact of a sensing target and accordingly the waveform of the voltage value changes.

By detecting a change in mutual capacitance in this manner, the approach or contact of a sensing target can be sensed.

### <Sensor Circuit>

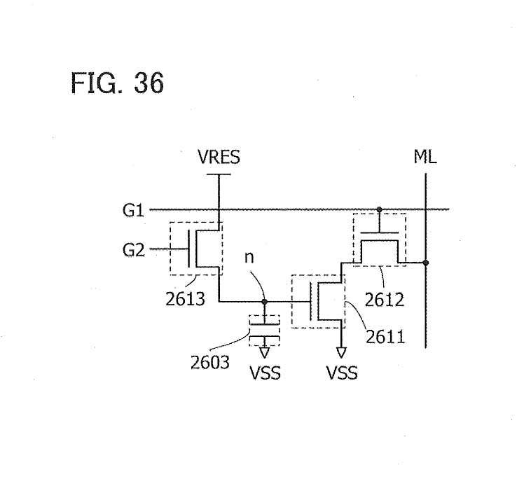

Although FIG. 35A illustrates a passive matrix type touch sensor in which only the capacitor 2603 is provided at the intersection of wirings as a touch sensor, an active matrix type touch sensor including a transistor and a capacitor may be used. FIG. 36 illustrates an example of a sensor circuit included in an active matrix type touch sensor.

The sensor circuit in FIG. 36 includes the capacitor 2603 and transistors 2611, 2612, and 2613.

A signal G2 is applied to a gate of the transistor 2613. A voltage VRES is applied to one of a source and a drain of the transistor 2613, and one electrode of the capacitor 2603 and a gate of the transistor 2611 are electrically connected to the other of the source and the drain of the transistor 2613. One of a source and a drain of the transistor 2611 is electrically connected to one of a source and a drain of the transistor 2612, and a voltage VSS is applied to the other of the source and the drain of the transistor 2611. A signal G1 is applied to a gate of the transistor 2612, and a wiring ML is electrically connected to the other of the source and the drain of the transistor 2612. The voltage VSS is applied to the other electrode of the capacitor 2603.

Next, the operation of the sensor circuit in FIG. 36 will be described. First, a potential for turning on the transistor 2613 is supplied to the signal G2, and a potential with respect to the voltage VRES is thus applied to the node n connected to the gate of the transistor 2611. Then, a potential for turning off the transistor 2613 is applied as the signal G2, whereby the potential of the node n is maintained.

Then, mutual capacitance of the capacitor 2603 changes owing to the approach or contact of a sensing target such as a finger, and accordingly the potential of the node n is changed from VRES.

In reading operation, a potential for turning on the transistor 2612 is supplied to the signal G1. A current flowing through the transistor 2611, that is, a current flowing through the wiring ML is changed in accordance with the potential of the node n. By sensing this current, the approach or contact of a sensing target can be sensed.

In each of the transistors 2611, 2612, and 2613, any of the transistors described in the above embodiments can be used. In particular, it is preferable to use any of the transistors described in the above embodiments as the transistor 2613 because the potential of the node n can be held for a long time and the frequency of operation of resupplying VRES to the node n (refresh operation) can be reduced.

The structure described in this embodiment can be combined as appropriate with any of the structures described in the other embodiments and examples.

### Embodiment 5

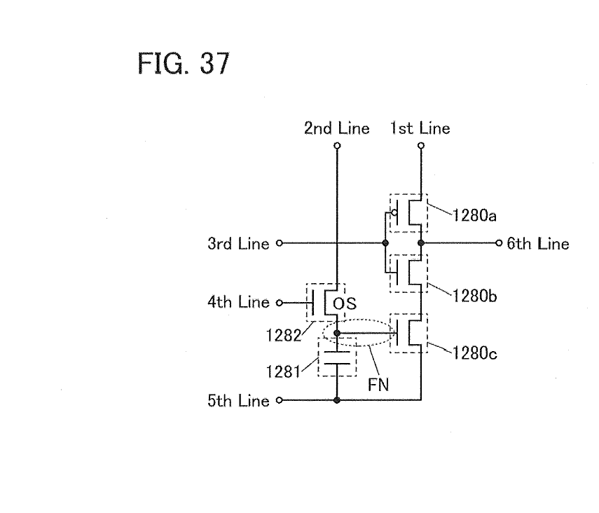

In this embodiment, an example of a circuit configuration of a semiconductor device, which can hold stored data even when not powered, and which does not have a limitation on the number of write cycles, will be described with reference to FIG. 37.

### <Circuit Configuration>

FIG. 37 shows an example of a circuit configuration of a semiconductor device. In FIG. 37, a first wiring (1st Line) is electrically connected to one of a source electrode and a drain electrode of a p-channel transistor 1280a. Further, the other of the source electrode and the drain electrode of the p-channel transistor 1280a is electrically connected to one of a source electrode and a drain electrode of an n-channel transistor 1280b. Further, the other of the source electrode and the drain electrode of the n-channel transistor 1280b is electrically connected to one of a source electrode and a drain electrode of an n-channel transistor 1280c.

A second wiring (2nd Line) is electrically connected to one of a source electrode and a drain electrode of a transistor 1282. Further, the other of the source electrode and the drain electrode of the transistor 1282, one electrode of a capacitor 1281, and a gate electrode of the n-channel transistor 1280c are electrically connected to each other.

A third wiring (3rd Line) and gate electrodes of the p-channel transistor 1280a and the n-channel transistor 1280b are electrically connected to each other. Further, a fourth wiring (4th Line) is electrically connected to a gate electrode of the transistor 1282. Further, a fifth wiring (5th Line), the other electrode of the capacitor 1281, and the other of the source electrode and the drain electrode of the n-channel transistor 1280c are electrically connected to each other. Further, a sixth wiring (6th Line), the other of the source electrode and the drain electrode of the p-channel transistor 1280a, and one of the source electrode and the drain electrode of the n-channel transistor 1280b are electrically connected to each other.

Note that the transistor 1282 can be formed using an oxide semiconductor (OS). Therefore, in FIG. 37, “OS” is written beside the transistor 1282. Note that the transistor 1282 may be formed using a material other than an oxide semiconductor.

Further, in FIG. 37, a floating node (FN) is written at a connection portion of the other of the source electrode and the drain electrode of the transistor 1282, the one electrode of the capacitor 1281, and the gate electrode of the n-channel transistor 1280c. When the transistor 1282 is turned off, potentials supplied to the floating node, the one electrode of the capacitor 1281, and the gate electrode of the n-channel transistor 1280c can be held.

The circuit configuration in FIG. 37 utilizes the advantage that the potential of the gate electrode of the n-channel transistor 1280c can be held, whereby writing, holding, and reading of data can be performed as described below.

### <Writing and Holding of Data>

First, writing and holding of data will be described. The potential of the fourth wiring is set to a potential at which the transistor 1282 is turned on, so that the transistor 1282 is turned on. Accordingly, the potential of the second wiring is supplied to the gate electrode of the n-channel transistor 1280c and the capacitor 1281. That is, predetermined charge is supplied to the gate electrode of the n-channel transistor 1280c (writing). After that, the potential of the fourth wiring is set to a potential at which the transistor 1282 is turned off, and the transistor 1282 is turned off. Accordingly, charge applied to the gate electrode of the n-channel transistor 1280c is held (holding).

Since the off-state current of the transistor 1282 is significantly small, the charge in the gate electrode of the n-channel transistor 1280c is held for a long time.

### <Reading of Data>

Next, reading of data is described. When the potential of the third wiring is a Low-level potential, the p-channel transistor 1280a is turned on and the n-channel transistor 1280b is turned off. At this time, the potential of the first wiring is applied to the sixth wiring. On the other hand, when the potential of the third wiring is a High-level potential, the p-channel transistor 1280a is turned off and the n-channel transistor 1280b is turned on. At this time, the potential of the sixth wiring varies in response to the amount of charge held in the floating node (FN). Therefore, the retained data can be read by measuring the potential of the sixth wiring (reading).

The transistor 1282 in which a channel formation region is formed using an oxide semiconductor has a significantly low off-state current. The off-state current of the transistor 1282 using an oxide semiconductor is lower than or equal to one hundred-thousandth of that of the off-state current of a transistor formed using a silicon semiconductor or the like; thus, loss of the electrical charge accumulated in the floating node (FN) due to leakage of the transistor 1282 is as small as negligible. That is, the transistor 1282 formed using an oxide semiconductor makes it possible to obtain a nonvolatile memory circuit which can hold data even without being supplied with power.

By applying the semiconductor device including the above-described circuit configuration to a memory device such as a register or a cache memory, data in the memory device can be prevented from being erased owing to the stop of the supply of the power supply voltage. In addition, after the supply of the power supply voltage is resumed, the storage element can return to the state same as that before the power supply voltage is stopped in a short time. Therefore, the power supply can be stopped even for a short time when the whole memory device or one or a plurality of logic circuits included in the memory device is in a standby state. Accordingly, power consumption can be suppressed.

The structure and method described in this embodiment can be combined as appropriate with any of the other structures and methods described in the other embodiments and examples.

### Embodiment 6

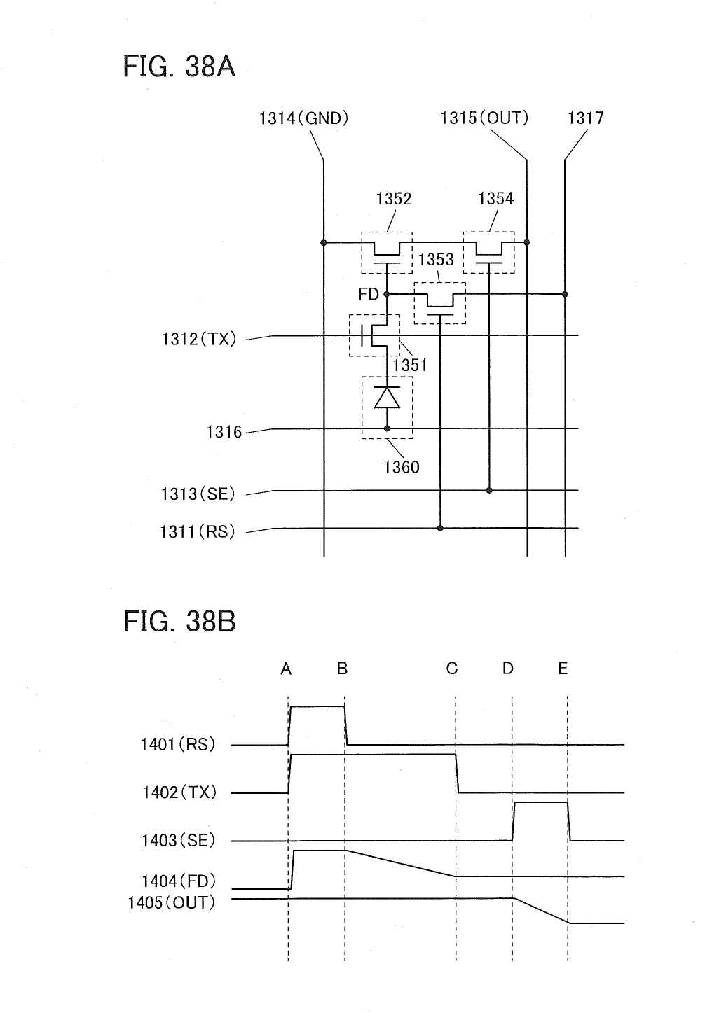

In this embodiment, a configuration of a pixel circuit capable of being used in a semiconductor device of one embodiment of the present invention will be described below with reference to FIG. 38A.

### <Configuration of Pixel Circuit>

FIG. 3 8A illustrates a configuration of the pixel circuit. The circuit in FIG. 38A includes a photoelectric conversion element 1360, a transistor 1351, a transistor 1352, a transistor 1353, and a transistor 1354.

An anode of the photoelectric conversion element 1360 is connected to a wiring 1316, and a cathode of the photoelectric conversion element 1360 is connected to one of a source electrode and a drain electrode of the transistor 1351. The other of the source electrode and the drain electrode of the transistor 1351 is connected to a charge accumulation portion (FD), and a gate electrode of the transistor 1351 is connected to a wiring 1312 (TX). One of a source electrode and a drain electrode of the transistor 1352 is connected to a wiring 1314 (GND), and the, other of the source electrode and the drain electrode of the transistor 1352 is connected to one of a source electrode and a drain electrode of the transistor 1354. A gate electrode of the transistor 1352 is connected to the charge accumulation portion (FD). One of a source electrode and a drain electrode of the transistor 1353 is connected to the charge accumulation portion (FD), and the other of the source electrode and the drain electrode of the transistor 1353 is connected to a wiring 1317. A gate electrode of the transistor 1353 is connected to a wiring 1311 (RS). The other of the source electrode and the drain electrode of the transistor 1354 is connected to a wiring 1315 (OUT), and a gate electrode of the transistor 1354 is connected to a wiring 1313 (SE). Note that all the connection is electrical connection.

A potential such as GND, VSS, or VDD may be applied to the wiring 1314. Here, a potential or voltage has a relative value. Therefore, the potential GND is not necessarily 0 V.

The photoelectric conversion element 1360 is a light-receiving element and has a function of generating current based on the amount of light that enters the pixel circuit. The transistor 1353 has a function of controlling accumulation of charge in the charge accumulation portion (FD) by the photoelectric conversion element 1360. The transistor 1354 has a function of outputting a signal based on the potential of the charge accumulation portion (FD). The transistor 1352 has a function of resetting the potential of the charge accumulation portion (FD). The transistor 1352 has a function of controlling selection of the pixel circuit at the time of reading.

Note that the charge accumulation portion (FD) is a charge retention node and retains charge that is changed depending on the amount of light received by the photoelectric conversion element 1360.

Note that the transistors 1352 and 1354 only need to be connected in series between the wirings 1314 and 1315. Thus, the wiring 1314, the transistor 1352, the transistor 1354, and the wiring 1315 may be arranged in that order, or the wiring 1314, the transistor 1354, the transistor 1352, and the wiring 1315 may be arranged in that order.

The wiring 1311 (RS) functions as a signal line for controlling the transistor 1353. The wiring 1312 (TX) functions as a signal line for controlling the transistor 1351. The wiring 1313 (SE) functions as a signal line for controlling the transistor 1354. The wiring 1314 (GND) functions as a signal line for supplying a reference potential (e.g., GND). The wiring 1315 (OUT) functions as a signal line for reading a signal output from the transistor 1352. The wiring 1316 functions as a signal line for outputting charge from the charge accumulation portion (FD) through the photoelectric conversion element 1360 and is a low-potential line in the circuit in FIG. 38A. The wiring 1317 functions as a signal line for resetting the potential of the charge accumulation portion (FD) and is a high-potential line in the circuit in FIG. 38A.

Next, a structure of each component illustrated in FIG. 3 8A will be described.

### <Photoelectric Conversion Element>

An element including selenium or a selenium-containing compound (hereinafter referred to as a selenium-based material) or an element including silicon (e.g., an element in which a pin junction is formed) can be used as the photoelectric conversion element 1360. The photoelectric conversion element including the selenium-based material is preferably used in combination with a transistor including an oxide semiconductor, in which case high reliability can be achieved.

### <Transistor>

Although a silicon semiconductor such as amorphous silicon, microcrystalline silicon, polycrystalline silicon, or single crystal silicon can be used to form the transistors 1351 to 1354, the transistors 1351 to 1354 are preferably OS transistors. A transistor in which a channel formation region is formed using an oxide semiconductor has extremely low off-state current. The transistor described in Embodiment 1, for example, can be used as the transistor in which the channel formation region is formed of an oxide semiconductor.

In particular, when the transistors 1351 and 1353 connected to the charge accumulation portion (FD) has high leakage current, charge accumulated in the charge accumulation portion (FD) cannot be held for a sufficiently long time. The use of OS transistors as the transistors 1351 and 1353 can prevent unwanted output of charge from the charge accumulation portion (FD).

Unwanted output of charge also occurs in the wiring 1314 or 1315 when the transistors 1352 and 1354 have high leakage current; thus, a transistor in which a channel formation region is formed using an oxide semiconductor is preferably used as each of these transistors.

The transistor shown in FIG. 38A includes one gate electrode. However, the transistor is not limited thereto and may include a plurality of gate electrodes, for example. The transistor including a plurality of gate electrodes is, for example, a transistor including a first gate electrode and a second gate electrode (also referred to as a back-gate electrode) which overlap with a semiconductor film in which a channel formation region is formed. The back-gate electrode may be supplied with a potential which is the same as that supplied to the first gate electrode, a floating potential, or a potential which is different from that supplied to the first gate electrode.

### <Timing Chart of Circuit Operation>

An example of operation of the circuit shown in FIG. 38A will be described with reference to a timing chart in FIG. 38B.

In FIG. 38B, the potential of each wiring is a signal that varies between two levels for simplicity. Since each potential is an analog signal, the potential can, in practice, have various levels depending on conditions without being limited to two levels. In FIG. 38B, a signal 1401 corresponds to the potential of the wiring 1311 (RS); a signal 1402 corresponds to the potential of the wiring 1312 (TX); a signal 1403 corresponds to the potential of the wiring 1313 (SE); a signal 1404 corresponds to the potential of the charge accumulation portion (FD); and a signal 1405 corresponds to the potential of the wiring 1315 (OUT). Note that the potential of the wiring 1316 is always at a low level, and the potential of the wiring 1317 is always at a high level.

At time A, the potential (signal 1401) of the wiring 1311 is at a high level and the potential (signal 1402) of the wiring 1312 is at a high level, so that the potential (signal 1404) of the charge accumulation portion (FD) is initialized to the potential (high level) of the wiring 1317, and reset operation is started. Note that the potential (signal 1405) of the wiring 1315 is precharged to a high level.

At time B, the potential (signal 1401) of the wiring 1311 is set at a low level, so that the reset operation is terminated to start accumulation operation. Here, a reverse bias is applied to the photoelectric conversion element 1360, so that the potential (signal 1404) of the charge accumulation portion (FD) starts to decrease due to reverse current. Since irradiation of the photoelectric conversion element 1360 with light increases the reverse current, the rate of decrease in the potential (signal 1404) of the charge accumulation portion (FD) changes depending on the amount of the light irradiation. In other words, channel resistance between the source electrode and the drain electrode of the transistor 1354 changes depending on the amount of light delivered to the photoelectric conversion element 1360.

At time C, the potential (signal 1402) of the wiring 1312 is set to a low level to terminate the accumulation operation, so that the potential (signal 1404) of the charge accumulation portion (FD) becomes constant. Here, the potential is determined by the amount of charge generated by the photoelectric conversion element 1360 during the accumulation operation. That is, the potential changes depending on the amount of light delivered to the photoelectric conversion element 1360. Furthermore, since each of the transistors 1351 and 1353 is a transistor that includes a channel formation region formed using an oxide semiconductor and has extremely low off-state current, the potential of the charge accumulation portion (FD) can be kept constant until subsequent selection operation (read operation) is performed.

Note that when the potential (signal 1402) of the wiring 1312 is set at a low level, the potential of the charge accumulation portion (FD) might change owing to parasitic capacitance between the wiring 1312 and the charge accumulation portion (FD). In the case where the amount of change in the potential is large, the amount of charge generated by the photoelectric conversion element 1360 during the accumulation operation cannot be obtained accurately. Examples of effective measures to reduce the amount of change in the potential include reducing capacitance between the gate electrode and the source electrode (or between the gate electrode and the drain electrode) of the transistor 1351, increasing the gate capacitance of the transistor 1352, and providing a storage capacitor in the charge accumulation portion (FD). Note that in this embodiment, the change in the potential can be ignored by taking these measures.

At time D, the potential (signal 1403) of the wiring 1313 is set at a high level to turn on the transistor 1354, so that selection operation starts and the wirings 1314 and 1315 are electrically connected to each other through the transistors 1352 and 1354. The potential (signal 1405) of the wiring 1315 starts to decrease. Note that precharge of the wiring 1315 is terminated before the time D. Here, the rate at which the potential (signal 1405) of the wiring 1315 decreases depends on current between the source electrode and the drain electrode of the transistor 1352. That is, the potential (signal 1405) of the wiring 1315 changes depending on the amount of light delivered to the photoelectric conversion element 1360 during the accumulation operation.

At time E, the potential (signal 1403) of the wiring 1313 is set at a low level to turn off the transistor 1354, so that the selection operation is terminated and the potential (signal 1405) of the wiring 1315 becomes a constant value. Here, the constant value changes depending on the amount of light delivered to the photoelectric conversion element 1360. Therefore, the amount of light delivered to the photoelectric conversion element 1360 during the accumulation operation can be determined by measuring the potential of the wiring 1315.

Specifically, when the photoelectric conversion element 1360 is irradiated with light with high intensity, the potential of the charge accumulation portion (FD), that is, the gate voltage of the transistor 1352 is decreased. Therefore, current flowing between the source electrode and the drain electrode of the transistor 1352 becomes small; as a result, the potential (signal 1405) of the wiring 1315 is gradually decreased. Thus, a comparatively high potential can be read from the wiring 1315.

In contrast, when the photoelectric conversion element 1360 is irradiated with light with low intensity, the potential of the charge accumulation portion (FD), that is, the gate voltage of the transistor 1352 is increased. Therefore, the current flowing between the source electrode and the drain electrode of the transistor 1352 becomes large; as a result, the potential (signal 1405) of the wiring 1315 is rapidly decreased. Thus, a comparatively low potential can be read from the wiring 1315.

The structure described in this embodiment can be combined as appropriate with any of the structures described in the other embodiments and examples.

### Embodiment 7

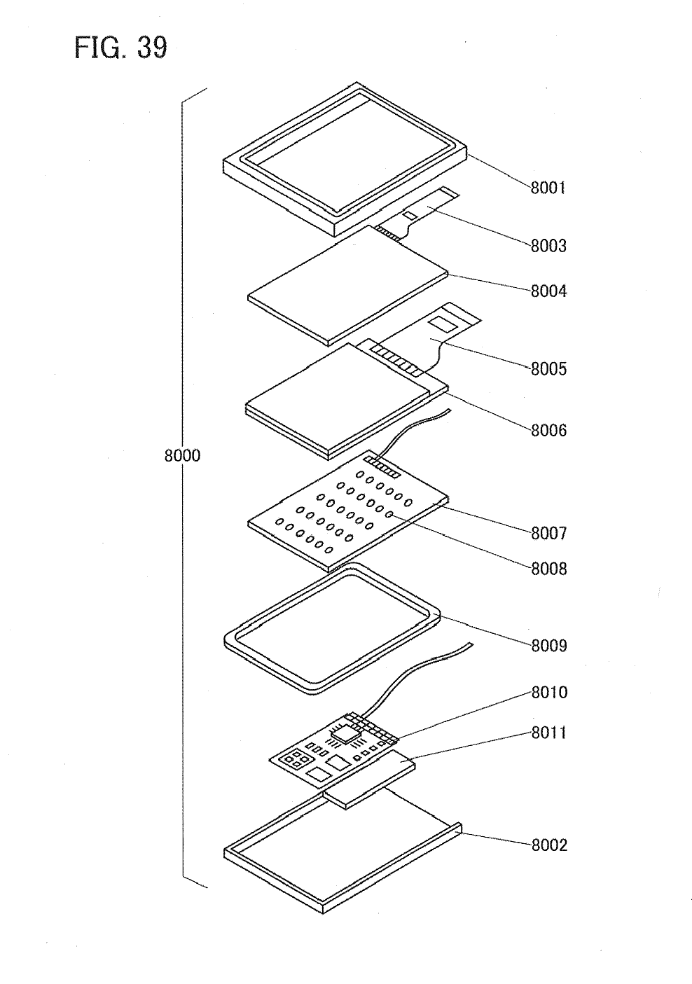

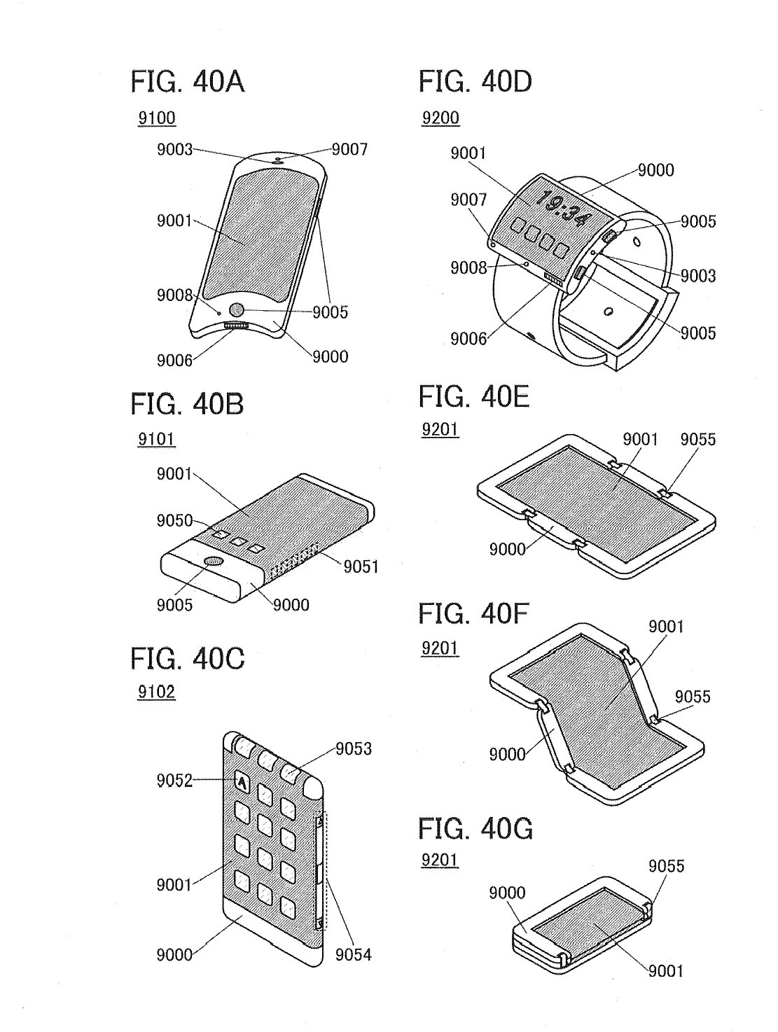

In this embodiment, a display module and electronic devices which include a semiconductor device of one embodiment of the present invention will be described with reference to FIG. 39 and FIGS. 40A to 40G.

### <Display Module>

In a display module 8000 illustrated in FIG. 39, a touch panel 8004 connected to an FPC 8003, a display panel 8006 connected to an FPC 8005, a backlight 8007, a frame 8009, a printed board 8010, and a battery 8011 are provided between an upper cover 8001 and a lower cover 8002.

The semiconductor device of one embodiment of the present invention can be used for, for example, the display panel 8006.

The shapes and sizes of the upper cover 8001 and the lower cover 8002 can be changed as appropriate in accordance with the sizes of the touch panel 8004 and the display panel 8006.

The touch panel 8004 can be a resistive touch panel or a capacitive touch panel and can be formed to overlap with the display panel 8006. A counter substrate (sealing substrate) of the display panel 8006 can have a touch panel function. A photosensor may be provided in each pixel of the display panel 8006 to form an optical touch panel.

The backlight 8007 includes light sources 8008. Note that although a structure in which the light sources 8008 are provided over the backlight 8007 is illustrated in FIG. 39, one embodiment of the present invention is not limited to this structure. For example, a structure in which the light sources 8008 are provided at an end portion of the backlight 8007 and a light diffusion plate is further provided may be employed. Note that the backlight 8007 need not be provided in the case where a self-luminous light-emitting element such as an organic EL element is used or in the case where a reflective panel or the like is employed.

The frame 8009 protects the display panel 8006 and also functions as an electromagnetic shield for blocking electromagnetic waves generated by the operation of the printed board 8010. The frame 8009 may function as a radiator plate.

The printed board 8010 is provided with a power supply circuit and a signal processing circuit for outputting a video signal and a clock signal. As a power source for supplying power to the power supply circuit, an external commercial power source or a power source using the battery 8011 provided separately may be used. The battery 8011 can be omitted in the case of using a commercial power source.

The display module 8000 may be additionally provided with a member such as a polarizing plate, a retardation plate, or a prism sheet.

### <Electronic Device>

FIGS. 40A to 40G illustrate electronic devices. These electronic devices can each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, oscillation, odor, or infrared rays), a microphone 9008, and the like.

The electronic devices illustrated in FIGS. 40A to 40G can have a variety of functions, for example, a function of displaying a variety of information (a still image, a moving image, a text image, and the like) on the display portion, a touch panel function, a function of displaying a calendar, the date, the time, and the like, a function of controlling processing with a variety of software (programs), a wireless communication function, a function of being connected to a variety of computer networks with a wireless communication function, a function of transmitting and receiving a variety of data with a wireless communication function, a function of reading a program or data stored in a storage medium and displaying the program or data on the display portion, and the like. Note that functions of the electronic devices illustrated in FIGS. 40A to 40G are not limited thereto, and the electronic devices can have a variety of functions. Although not illustrated in FIGS. 40A to 40G, the electronic devices may each have a plurality of display portions. The electronic devices may each have a camera or the like and a function of taking a still image, a function of taking a moving image, a function of storing the taken image in a storage medium (an external storage medium or a storage medium incorporated in the camera), a function of displaying the taken image on the display portion, and the like.

The electronic devices illustrated in FIGS. 40A to 40G will be described in detail below.

FIG. 40A is a perspective view of a portable information terminal 9100. The display portion 9001 of the portable information terminal 9100 is flexible and thus can be incorporated along the curved surface of the housing 9000. Furthermore, the display portion 9001 includes a touch sensor, and operation can be performed by touching a screen with a finger, a stylus, or the like. For example, by touching an icon displayed on the display portion 9001, an application can be started.

FIG. 40B is a perspective view of a portable information terminal 9101. The portable information terminal 9101 functions as, for example, one or more of a telephone set, a notebook, an information browsing system, and the like. Specifically, the portable information terminal 9101 can be used as a smartphone. Note that the speaker 9003, the connection terminal 9006, the sensor 9007, and the like, which are not illustrated in FIG. 40B, can be positioned in the portable information terminal 9101 as in the portable information terminal 9100 illustrated in FIG. 40A. The portable information terminal 9101 can display characters and image information on its plurality of surfaces. For example, three operation buttons 9050 (also referred to as operation icons, or simply, icons) can be displayed on one surface of the display portion 9001. Furthermore, information 9051 indicated by dashed rectangles can be displayed on another surface of the display portion 9001. Examples of the information 9051 include display indicating reception of an incoming e-mail, social networking service (SNS) message, call, or the like; the title and sender of an e-mail, SNS message, or the like; the date; the time; remaining battery; the strength of an antenna; and the like. Instead of the information 9051, the operation buttons 9050 or the like may be displayed in the position where the information 9051 is displayed.

FIG. 40C is a perspective view of a portable information terminal 9102. The portable information terminal 9102 has a function of displaying information on three or more surfaces of the display portion 9001. Here, information 9052, information 9053, and information 9054 are displayed on different surfaces. For example, a user of the portable information terminal 9102 can see the display (here, the information 9053) with the portable information terminal 9102 put in a breast pocket of his/her clothes. Specifically, a caller's phone number, name, or the like of an incoming call is displayed in the position that can be seen from above the portable information terminal 9102. Thus, the user can see the display without taking out the portable information terminal 9102 from the pocket and decide whether to answer the call.

FIG. 40D is a perspective view of a watch-type portable information terminal 9200. The portable information terminal 9200 is capable of executing a variety of applications such as mobile phone calls, e-mailing, viewing and editing texts, music reproduction, Internet communication, and computer games. The display surface of the display portion 9001 is curved, and display can be performed on the curved display surface. The portable information terminal 9200 can employ near field communication conformable to a communication standard. For example, hands-free calling can be achieved with mutual communication between the portable information terminal 9200 and a headset capable of wireless communication. Moreover, the portable information terminal 9200 includes the connection terminal 9006, and data can be directly transmitted to and received from another information terminal via a connector. Charging through the connection terminal 9006 is also possible. Note that the charging operation may be performed by wireless power feeding without using the connection terminal 9006.

FIGS. 40E, 40F, and 40G are perspective views of a foldable portable information terminal 9201. FIG. 40E is a perspective view of the foldable portable information terminal 9201 that is opened. FIG. 40F is a perspective view of the foldable portable information terminal 9201 that is being opened or being folded. FIG. 40G is a perspective view of the foldable portable information terminal 9201 that is folded. The portable information terminal 9201 is highly portable when folded. When the portable information terminal 9201 is opened, a seamless large display region provides high browsability. The display portion 9001 of the portable information terminal 9201 is supported by three housings 9000 joined together by hinges 9055. By folding the portable information terminal 9201 at a connection portion between two housings 9000 with the hinges 9055, the portable information terminal 9201 can be reversibly changed in shape from the opened state to the folded state. For example, the portable information terminal 9201 can be bent with a radius of curvature of greater than or equal to 1 mm and less than or equal to 150 mm.

The electronic devices described in this embodiment each include the display portion for displaying some sort of data. Note that the semiconductor device of one embodiment of the present invention can also be used for an electronic device that does not have a display portion. The structure in which the display portion of the electronic device described in this embodiment is flexible and display can be performed on the curved display surface or the structure in which the display portion of the electronic device is foldable is described as an example; however, the structure is not limited thereto, and a structure in which the display portion of the electronic device is not flexible and display is performed on a plane portion may be employed.

The structure described in this embodiment can be combined as appropriate with any of the structures described in the other embodiments and examples.

### Embodiment 8

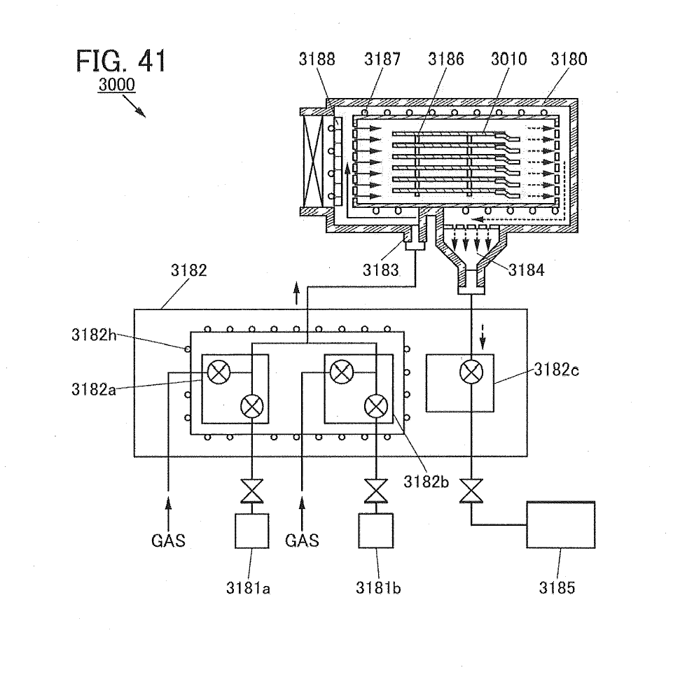

In this embodiment, a deposition apparatus which can be used for manufacturing the display module of one embodiment of the present invention will be described with reference to FIG. 41.

FIG. 41 illustrates a deposition apparatus 3000 which can be used for manufacturing the display module of one embodiment of the present invention. Note that the deposition apparatus 3000 is an example of a batch-type ALD apparatus.

### <Structural Example of Deposition Apparatus>

The deposition apparatus 3000 described in this embodiment includes a deposition chamber 3180 and a control portion 3182 connected to the deposition chamber 3180 (see FIG. 41).

The control portion 3182 includes a control unit (not illustrated) which supplies control signals and flow rate controllers 3182a, 3182b, and 3182c to which the control signals are supplied. For example, high-speed valves can be used as the flow rate controllers. Specifically, flow rates can be precisely controlled by using ALD valves or the like. The control portion 3182 also includes a heating mechanism 3182h which controls the temperatures of the flow rate controllers and pipes.

The flow rate controller 3182a is supplied with a control signal, a first source material, and an inert gas and has a function of supplying the first source material or the inert gas in accordance with the control signal.

The flow rate controller 3182b is supplied with a control signal, a second source material, and an inert gas and has a function of supplying the second source material or the inert gas in accordance with the control signal.

The flow rate controller 3182c is supplied with a control signal and has a function of connecting to an evacuation unit 3185 in accordance with the control signal.

### <Source Material Supply Portion>

A source material supply portion 3181a has a function of supplying the first source material and is connected to the flow rate controller 3182a.

A source material supply portion 3181b has a function of supplying the second source material and is connected to the flow rate controller 3182b.

A vaporizer, a heating unit, or the like can be used as each of the source material supply portions. Thus, a gaseous source material can be generated from a solid or liquid source material.

Note that the number of source material supply portions is not limited to two and may be three or more.

### <Source Material>

Any of a variety of substances can be used as the first source material. For example, an organometallic compound, a metal alkoxide, or the like can be used as the first source material. Any of a variety of substances which react with the first source material can be used as the second source material. For example, a substance which contributes to an oxidation reaction, a substance which contributes to a reduction reaction, a substance which contributes to an addition reaction, a substance which contributes to a decomposition reaction, a substance which contributes to a hydrolysis reaction, or the like can be used as the second source material.

Furthermore, a radical or the like can be used. For example, plasma obtained by supplying a source material to a plasma source or the like can be used. Specifically, an oxygen radical, a nitrogen radical, or the like can be used.

The second source material combined with the first source material is preferably a source material which reacts at a temperature close to room temperature. For example, a source material which reacts at a temperature higher than or equal to room temperature and lower than or equal to 200° C., preferably higher than or equal to 50° C. and lower than or equal to 150° C., is preferable.

### <Evacuation Unit>

The evacuation unit 3185 has an evacuating function and is connected to the flow rate controller 3182c. Note that a trap for capturing the source material to be evacuated may be provided between an outlet port 3184 and the flow rate controller 3182c. The evacuated gas or the like is removed by using a removal unit.

### <Control Portion>

The control portion 3182 supplies the control signals which controls the flow rate controllers, a control signal which controls the heating mechanism, or the like. For example, in a first step, the first source material is supplied to a surface of a process member. Then, in a second step, the second source material which reacts with the first source material is supplied. Accordingly, a reaction product of the first source material and the second source material can be deposited onto a surface of a process member 3010.

Note that the amount of the reaction product to be deposited onto the surface of the process member 3010 can be controlled by repetition of the first step and the second step.

Note that the amount of the first source material to be supplied to the process member 3010 is limited by the maximum possible amount of adsorption on the surface of the process member 3010. For example, conditions are selected so that a monomolecular layer of the first source material is formed on the surface of the process member 3010, and the formed monomolecular layer of the first source material is reacted with the second source material, whereby a significantly uniform layer containing the reaction product of the first source material and the second source material can be formed.

Accordingly, a variety of materials can be deposited on a surface of the process member 3010 even when the surface has a complicated structure. For example, a film having a thickness greater than or equal to 3 nm and less than or equal to 200 nm can be formed on the process member 3010.

In the case where, for example, a small hole called a pinhole or the like is formed in the surface of the process member 3010, the pinhole can be filled by depositing a material into the pinhole.

The remainder of the first source material or the second source material is evacuated from the deposition chamber 3180 with use of the evacuation unit 3185. For example, the evacuation may be performed while an inert gas such as argon or nitrogen is introduced.

### <Deposition Chamber>

The deposition chamber 3180 includes an inlet port 3183 from which the first source material, the second source material, and the inert gas are supplied and the outlet port 3184 from which the first source material, the second source material, and the inert gas are evacuated.

The deposition chamber 3180 includes a support portion 3186 which has a function of supporting one or a plurality of process members 3010, a heating mechanism 3187 which has a function of heating the one or plurality of process members 3010, and a door 3188 which has a function of opening or closing to load and unload the one or plurality of process members 3010.

For example, a resistive heater, an infrared lamp, or the like can be used as the heating mechanism 3187. The heating mechanism 3187 has a function of heating up, for example, to 80° C. or higher, 100° C. or higher, or 150° C. or higher. The heating mechanism 3187 heats the one or plurality of process members 3010 to a temperature higher than or equal to room temperature and lower than or equal to 200° C., preferably higher than or equal to 50° C. and lower than or equal to 150° C.

The deposition chamber 3180 may also include a pressure regulator and a pressure detector.

### <Support Portion>

The support portion 3186 supports the one or plurality of process members 3010. Accordingly, an insulating film, for example, can be formed over the one or plurality of process members 3010 in each treatment.

### <Example of Film>

An example of a film which can be formed with the deposition apparatus 3000 described in this embodiment will be described.

For example, a film including an oxide, a nitride, a fluoride, a sulfide, a ternary compound, a metal, or a polymer can be formed.

For example, the film can be formed with a material including aluminum oxide, hafnium oxide, aluminum silicate, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like.

For example, the film can be formed with a material including aluminum nitride, hafnium nitride, silicon nitride, tantalum nitride, titanium nitride, niobium nitride, molybdenum nitride, zirconium nitride, gallium nitride, or the like.

For example, the film can be formed with a material including copper, platinum, ruthenium, tungsten, iridium, palladium, iron, cobalt, nickel, or the like.

For example, the film can be formed with a material including zinc sulfide, strontium sulfide, calcium sulfide, lead sulfide, calcium fluoride, strontium fluoride, zinc fluoride, or the like.

For example, the film can be formed with a material which includes a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The structure described in this embodiment can be combined as appropriate with any of the structures described in the other embodiments and examples.

### EXAMPLE 1

In this example, a low resistance region formed in an oxide semiconductor film by deposition power for a conductive film formed over the oxide semiconductor film was evaluated. Note that for evaluation of the low resistance region, the sheet resistance and the spin surface density were measured.

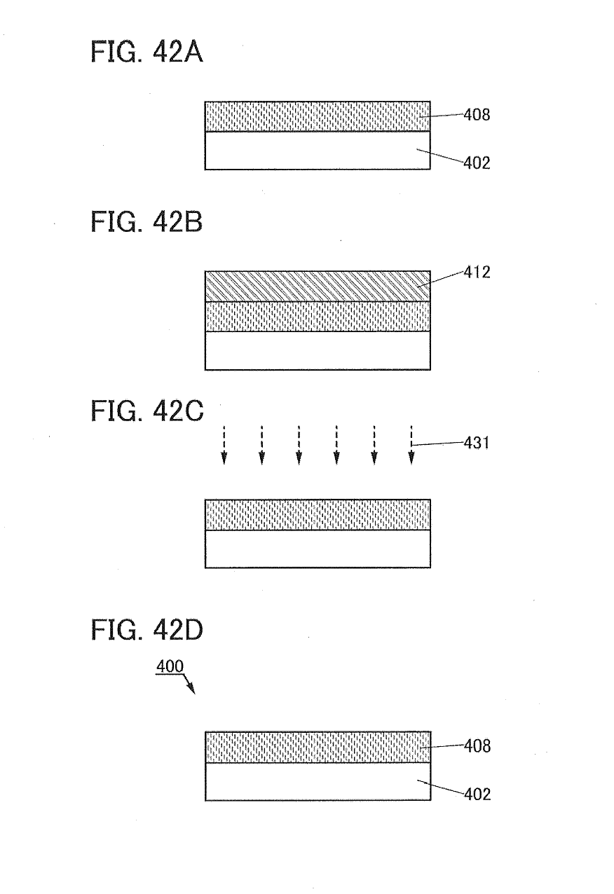

As a sample for measurement of the sheet resistance and the spin surface density, a sample 400 illustrated in FIG. 42D was fabricated. Note that FIG. 42D is a schematic cross-sectional view illustrating the sample 400 for measurement of the sheet resistance and the spin density, and FIGS. 42A to 42C are schematic cross-sectional views illustrating a method for fabricating the sample 400. First, measurement of the sheet resistance will be described, and then measurement of the spin density will be described.

### <1-1. Sample for Measurement of Sheet Resistance>

As the sample 400 for measurement of the sheet resistance, two samples with different deposition power for a conductive film formed over an oxide semiconductor film were fabricated. A sample in which a conductive film was formed with the deposition power of 20 kw is referred to as Sample A1, and a sample in which a conductive film was formed with the deposition power of 60 kw is referred to as Sample A2. A method for fabricating the samples for measurement of the sheet resistance will be described in detail below.

### <1-2. Method for Fabricating Samples for Measurement of Sheet Resistance>

An oxide semiconductor film 408 was formed over a substrate 402. A glass substrate was used as the substrate 402. A 100-nm-thick IGZO film was formed as the oxide semiconductor film 408. The IGZO film was formed under the conditions where a sputtering target having an atomic ratio of In:Ga:Zn=1:1:1.2 was used; an oxygen gas and an argon gas were each supplied at a flow rate of 100 sccm (the proportion of oxygen is 50%) to a treatment chamber of a sputtering apparatus; the pressure in the treatment chamber was controlled to 0.6 Pa; and an alternating-current power of 2.5 kW was supplied. Note that the oxide semiconductor film 408 was formed at a substrate temperature of 170° C. (see FIG. 42A).

Next, the oxide semiconductor film 408 was subjected to heat treatment. As the heat treatment, heat treatment at 450° C. in a nitrogen atmosphere for one hour and heat treatment at 450° C. in a mixed gas atmosphere of nitrogen and oxygen for one hour were successively performed.

Next, a conductive film 412 was formed over the oxide semiconductor film 408. As the conductive film 412, a 100 nm-thick tungsten (W) film was formed (see FIG. 42B).

Note that the conditions for forming the tungsten film in Sample A1 are different from those in Sample A2. The tungsten film in Sample A1 was formed under the conditions where an argon gas was supplied at a flow rate of 100 sccm to a treatment chamber of the sputtering apparatus; the pressure in the treatment chamber was controlled to 2 Pa; and a direct-current power of 20 kW (the power density of 2.70 W/cm²) was supplied to a sputtering target of tungsten. Note that the tungsten film was formed at a substrate temperature of 100° C. The tungsten film in Sample A2 was formed under the conditions where an argon gas was supplied at a flow rate of 100 sccm to the treatment chamber of the sputtering apparatus; the pressure in the treatment chamber was controlled to 2 Pa; and a direct-current power of 60 kW (the power density of 8.09 W/cm²) was supplied to a sputtering target of tungsten. Note that the tungsten film was formed at a substrate temperature of 100° C.

Next, the conductive film 412 was removed with an etching gas 431 under the etching conditions where an SF₆ gas at a flow rate of 900 sccm and an oxygen gas at a flow rate of 100 sccm were supplied to the treatment chamber; the pressure in the treatment chamber was controlled to 2 Pa; and the ICP power of 2000 W and the bias power of 200 W were supplied (see FIG. 42C).

Through the above process, Sample A1 and Sample A2 were fabricated.

### <1-3. Sheet Resistance Measurement>

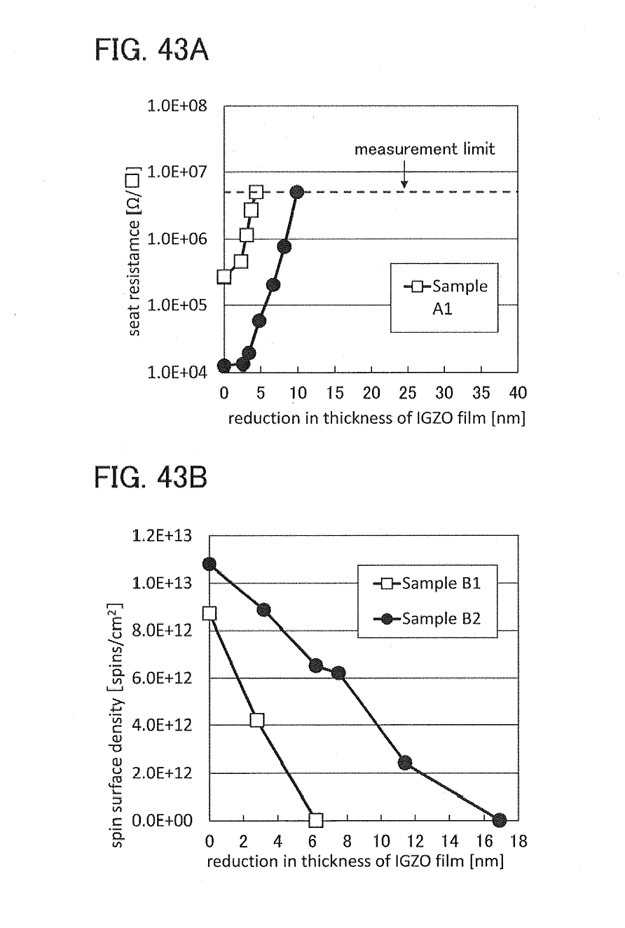

Next, the sheet resistances of Sample A1 and Sample A2 were measured. FIG. 43A shows measurement results of the sheet resistances. The sheet resistances were measured by a four-probe method. Note that measurement upper limit of a sheet resistance measurer is 5 MΩ/sq.

The sheet resistance measurement was performed as follows: after the sheet resistance of a surface of the IGZO film (the amount of a reduction in the thickness of the IGZO film was 0 nm in FIG. 43A) was measured, a chemical solution (a mixed solution in which hydrogen peroxide water, an ammonia aqueous solution, and water are mixed at a volume ratio of 5:1:5) was supplied from the surface of the IGZO film, and the amount of a reduction in the thickness of the IGZO film was measured, and then the sheet resistance was measured again. Note that the amount of a reduction in the thickness of the IGZO film was measured with an optical film thickness measurement system. Furthermore, supply of the chemical solution, measurement of the amount of a reduction in the thickness of the IGZO film, and measurement of the sheet resistance were repeated plural times until the sheet resistance of the IGZO film reached the measurement upper limit

As shown in FIG. 43A, in Sample A2, the sheet resistance of the IGZO film reached the measurement upper limit (5 MΩ/sq) when the amount of a reduction in the thickness of the IGZO film was approximately 10 nm. This shows that the low resistance region was formed in the IGZO film from the surface to a depth of approximately 10 nm under the conditions where the deposition power for the tungsten (W) film was 60 kW (the power density was 8.09 W/cm²). In Sample A1, the sheet resistance of the IGZO film reached the measurement upper limit (5 MΩ/sq.) when the amount of a reduction in the thickness of the IGZO film was approximately 5 nm. This shows that the low resistance region was formed in the IGZO film from the surface to a depth of approximately 5 nm under the conditions where the deposition power for the tungsten (W) film was 20 kW (the power density was 2.70 W/cm²).

As described above, it was found that the thickness of the low resistance region formed in the oxide semiconductor film in the depth direction was able to be controlled by changing the deposition power for the conductive film formed over the oxide semiconductor film. It was also found that the low resistance region formed in the vicinity of the surface of the oxide semiconductor film was able to be removed by supply of a chemical solution from above the oxide semiconductor film.

### <1-4. Samples for ESR Measurement>

As the sample 400 for ESR measurement, two samples with different deposition power for a conductive film formed over an oxide semiconductor film were fabricated. A sample in which a conductive film was formed with the deposition power of 20 kw is referred to as Sample B1, and a sample in which a conductive film was formed with the deposition power of 60 kw is referred to as Sample B2. A method for fabricating the sample 400 for ESR measurement will be described in detail below.

### <1-5. Method for Fabricating Samples for ESR Measurement>

The oxide semiconductor film 408 was formed over the substrate 402. As the substrate 402, a quartz substrate was used. A 35-nm-thick IGZO film was formed as the oxide semiconductor film 408. The IGZO film was formed under the conditions where a sputtering target having an atomic ratio of In:Ga:Zn=1:1:1.2 was used; an oxygen gas (the proportion of oxygen is 50%) and an argon gas were each supplied at a flow rate of 100 sccm to a treatment chamber of a sputtering apparatus; the pressure in the treatment chamber was controlled to 0.6 Pa; and an alternating-current power of 2.5 kW was supplied. Note that the oxide semiconductor film 408 was formed at a substrate temperature of 170° C. (see FIG. 42A).

Next, the oxide semiconductor film 408 was subjected to heat treatment. As the heat treatment, heat treatment at 450° C. in a nitrogen atmosphere for one hour and heat treatment at 450° C. in a mixed gas atmosphere of nitrogen and oxygen for one hour were successively performed.

Next, the conductive film 412 was formed over the oxide semiconductor film 408. As the conductive film 412, a 100 nm-thick tungsten (W) film was formed (see FIG. 42B).

Note that the conditions for forming the tungsten film in Sample B1 are different from those in Sample B2. The conditions for forming the tungsten film in Sample B1 were the same as those in Sample A1 described above. The conditions for forming the tungsten film in Sample B2 were the same as those in Sample A2 described above.

Next, each of the conductive films 412 was removed with the etching gas 431 under the etching conditions where an SF₆ gas at a flow rate of 900 sccm and an oxygen gas at a flow rate of 100 sccm were supplied to the treatment chamber; the pressure in the treatment chamber was controlled to 2 Pa; and the ICP power of 2000 W and the bias power of 200 W were supplied (see FIG. 42C).

Through the above process, Samples B1 and Sample B2 were fabricated.

### <1-6. ESR Measurement>

Next, Sample B1 and Sample B2 were measured by ESR. In the ESR measurement performed at a predetermined temperature, a value of a magnetic field (H₀) where a microwave is absorbed is used for an equation g=hv/βH₀, and a parameter “g-factor” can be obtained. Note that v represents the frequency of the microwave. Note that h and β represent the Planck constant and the Bohr magneton, respectively, and are both constants.

In this example, the ESR measurement was performed under the following conditions.

The measurement temperature was room temperature (25° C.), the high-frequency power (power of microwaves) of 8.9 GHz was 20 mW, and the direction of a magnetic field was parallel to a surface of each sample. Note that the detection limit of the spin surface density of a signal attributed to V_{O}H in the IGZO film, which appeared at a g (g-factor) of greater than or equal to 1.89 and less than or equal to 1.96, was 3.7×10¹¹ spins/cm².

Note that VₒH is obtained by bond of an oxygen vacancy V_{O}, which is one of defects contained in the oxide semiconductor film, and an H atom positioned in the Vₒ. VₒH serves as a donor in the oxide semiconductor film. When the density of VₒH is increased in the oxide semiconductor film, the oxide semiconductor film becomes n-type.

FIG. 43B shows the spin surface densities of Sample B1 and Sample B2 which were measured by ESR. In FIG. 43B, a signal attributed to VₒH, which appeared at a g (g-factor) of 1.93, is plotted as the spin surface density.

Furthermore, the ESR measurement was performed on each of Sample B1 and Sample B2 as follows: after ESR measurement was performed on the IGZO film (the amount of a reduction in the thickness of the IGZO film was 0 nm in FIG. 43B), a chemical solution (a mixed solution in which hydrogen peroxide water, an ammonia aqueous solution, and water are mixed at a volume ratio of 5:1:5) was supplied from the surface of the IGZO film, and the amount of a reduction in the thickness of the IGZO film was measured, and then the ESR measurement was performed again. Note that the amount of a reduction in the thickness of the IGZO film was measured with an optical film thickness measurement system. Furthermore, supply of the chemical solution, measurement of the amount of a reduction in the thickness of the IGZO film, and ESR measurement were repeated plural times until the spin surface density of the IGZO film reached the detection limit.

As shown in FIG. 43B, in Sample B1, a signal attributed to VₒH, which appeared at a g (g-factor) of 1.93, was detected until the amount of a reduction in the thickness of the IGZO film reached approximately 6 nm. In Sample B2, a signal attributed to VₒH, which appeared at a g (g-factor) of 1.93, was detected until the amount of a reduction in the thickness of the IGZO film reached approximately 17 nm.

As described above, it was found that the position (depth) of VₒH formed in the oxide semiconductor film in the depth direction was able to be controlled by changing the deposition power for the conductive film formed over the oxide semiconductor film. It was also found that VₒH formed in the vicinity of the surface of the oxide semiconductor film in forming the conductive film was removed by supply of a chemical solution from above the oxide semiconductor film. The results in FIGS. 43A and 43B suggested that the low resistance region formed in the vicinity of the surface of the oxide semiconductor film was attributed to VₒH.

The structure described above in this example can be combined as appropriate with any of the structures described in the other embodiments and examples.

### EXAMPLE 2

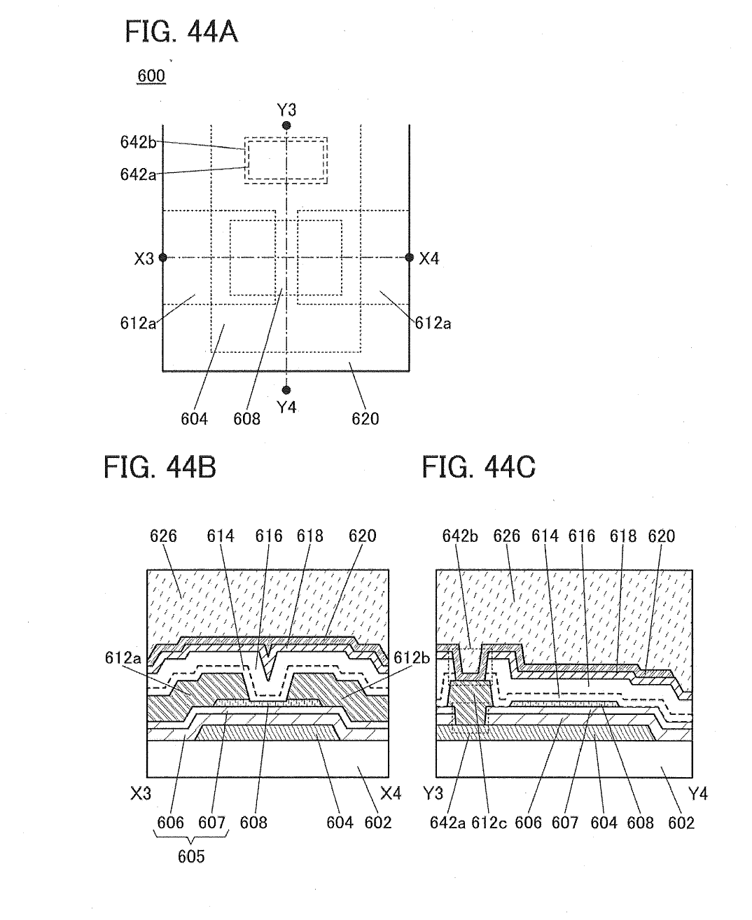

In this example, a transistor corresponding to a transistor 600 in FIGS. 44A to 44C was fabricated and tests for electrical characteristics and reliability were performed.

### <2-1. Structure of Transistor>

First, the transistor 600 in FIGS. 44A to 44C will be described. Note that FIG. 44A is a top view of the transistor 600, FIG. 44B is a cross-sectional view taken along dashed-dotted line X3-X4 in FIG. 44A, and FIG. 44C is a cross-sectional view taken along dashed-dotted line Y3-Y4 in FIG. 44A.

The transistor 600 includes a conductive film 604 functioning as a first gate electrode over a substrate 602, an insulating film 606 over the substrate 602 and the conductive film 604, an insulating film 607 over the insulating film 606, an oxide semiconductor film 608 over the insulating film 607, a conductive film 612a functioning as a source electrode electrically connected to the oxide semiconductor film 608, and a conductive film 612b functioning as a drain electrode electrically connected to the oxide semiconductor film 608.

Over the transistor 600, specifically, over the conductive films 612a and 612b and the oxide semiconductor film 608, insulating films 614, 616, and 618 are provided. A conductive film 620 is provided over the insulating film 618. An opening 642a reaching the conductive film 604 is provided in the insulating films 606 and 607, and a conductive film 612c is formed so as to cover the opening 642a. An opening 642b reaching the conductive film 612c is provided in the insulating films 614, 616, and 618. The conductive film 620 is connected to the conductive film 612c through the opening 642b. That is, the conductive film 604 and the conductive film 620 are electrically connected to each other. A planarization insulating film 626 is provided over the conductive film 620. Note that the conductive film 620 functions as a second gate electrode (also referred to as a back gate electrode) of the transistor 600.

In this example, as a transistor corresponding to the transistor 600 in FIGS. 44A to 44C, Sample C1 and Sample C2 described below were fabricated and evaluated. Note that Sample C1 and Sample C2 were each a transistor with a channel length L of 3 μm and a channel width W of 5 μm.

### <2-2. Method for Fabricating Transistors>

First, the conductive film 604 was formed over the substrate 602. A glass substrate was used as the substrate 602. As the conductive film 604, a 100-nm-thick tungsten film was formed with a sputtering apparatus.

Next, the insulating film 606 and the insulating film 607 were formed over the substrate 602 and the conductive film 604. As the insulating film 606, a 400-nm-thick silicon nitride film was formed with a PECVD apparatus. As the insulating film 607, a 50-nm-thick silicon oxynitride film was formed with a PECVD apparatus.

Next, the oxide semiconductor film 608 was formed over the insulating film 607. As the oxide semiconductor film 608, a 35-nm-thick IGZO film was formed with a sputtering apparatus. Note that the IGZO film was deposited under the conditions where the substrate temperature was 170° C., an argon gas at a flow rate of 100 sccm and an oxygen gas at a flow rate of 100 sccm were introduced into a chamber, the pressure was 0.6 Pa, and an AC power of 2500 W was applied to a metal oxide sputtering target (having an atomic ratio of In:Ga:Zn=1:1:1.2).

Then, first heat treatment was performed. As the first heat treatment, heat treatment was performed at 450° C. for 1 hour in a nitrogen atmosphere and then heat treatment was performed at 450° C. for 1 hour in a mixed atmosphere of nitrogen and oxygen.

Next, a resist mask was formed over the insulating film 607 and the oxide semiconductor film 608, and a desired region was etched, whereby the opening 642a reaching the conductive film 604 was foamed. The opening 642a was formed with a dry etching apparatus. Note that the resist mask was removed after the opening 642a was formed.

After that, a conductive film was formed over the insulating film 607, the oxide semiconductor film 608, and the opening 642a, a resist mask was formed over the conductive film, and a desired region was etched, whereby the conductive films 612a, 612b, and 612c were formed. As the conductive films 612a, 612b, and 612c, a 50-nm-thick tungsten film, a 400-nm-thick aluminum film, and a 100-nm-thick titanium film were successively formed in vacuum with a sputtering apparatus. Note that the resist mask was removed after the conductive films 612a, 612b, and 612c were formed.

The conditions for forming the tungsten film in Sample C1 are different from those in Sample C2. Specifically, the tungsten film in Sample C1 was formed under the conditions where an argon gas was supplied at a flow rate of 100 sccm to a treatment chamber of the sputtering apparatus; the pressure in the treatment chamber was controlled to 2 Pa; and a direct-current power of 20 kW (the power density of 2.70 W/cm²) was supplied to a sputtering target of tungsten. The tungsten film in Sample C2 was formed under the conditions where an argon gas was supplied at a flow rate of 100 sccm to a treatment chamber of the sputtering apparatus; the pressure in the treatment chamber was controlled to 2 Pa; and a direct-current power of 60 kW (the power density of 8.09 W/cm²) was supplied to a sputtering target of tungsten.

Next, a phosphoric acid solution (a solution obtained by diluting a solution having a phosphoric acid concentration of 85% with water by 100 times) was supplied from above the insulating film 607, the oxide semiconductor film 608, and the conductive films 612a and 612b, and thus part of a surface of the oxide semiconductor film 608, which was not covered with the conductive films 612a and 612b, was removed.

Next, the insulating films 614 and 616 were formed over the insulating film 607, the oxide semiconductor film 608, and the conductive films 612a and 612b. As the insulating film 614, a 50-nm-thick silicon oxynitride film was formed with a PECVD apparatus. As the insulating film 616, a 400-nm-thick silicon oxynitride film was formed with a PECVD apparatus. Note that the insulating films 614 and 616 were formed successively in vacuum with a PECVD apparatus.

The insulating film 614 was deposited under the conditions where the substrate temperature was 220° C., a silane gas at a flow rate of 50 sccm and a dinitrogen monoxide gas at a flow rate of 2000 sccm were introduced into a chamber, the pressure was 20 Pa, and an RF power of 100 W was supplied between parallel-plate electrodes provided in a PECVD apparatus. The insulating film 616 was deposited under the conditions where the substrate temperature was 220° C., a silane gas at a flow rate of 160 sccm and a dinitrogen monoxide gas at a flow rate of 4000 sccm were introduced into a chamber, the pressure was 200 Pa, and an RF power of 1500 W was supplied between the parallel-plate electrodes provided in the PECVD apparatus.

Then, second heat treatment was performed. The second heat treatment was performed at 350° C. in a nitrogen atmosphere for 1 hour.

Next, a protective film was formed over the insulating film 616. As the protective film, a 5-nm-thick ITSO film was formed with a sputtering apparatus. The ITSO film was deposited under the conditions where the substrate temperature was room temperature, an argon gas at a flow rate of 72 sccm and an oxygen gas at a flow rate of 5 sccm were introduced into a chamber, the pressure was 0.15 Pa, and a DC power of 1000 W was supplied to a metal oxide target (In₂O₃:SnO₂:SiO₂=85:10:5 [wt. %]) provided in a sputtering apparatus.

Next, oxygen addition treatment was performed on the insulating films 614 and 616 through the protective film. The oxygen addition treatment was performed with an ashing apparatus under the conditions where the substrate temperature was 40° C., an oxygen gas at a flow rate of 250 sccm was introduced into a chamber, the pressure was 15 Pa, and an RF power of 4500 W was supplied for 120 sec. between parallel-plate electrodes provided in the ashing apparatus so that a bias would be applied to the substrate side.

Next, the protective film was removed to expose a surface of the insulating film 616. The protective film was removed in such a manner that treatment with an oxalic acid solution containing an oxalic acid at a concentration of 5% was performed for 300 sec. and then treatment with a hydrofluoric acid solution containing a hydrofluoric acid at a concentration of 0.5% was performed for 15 sec.

The insulating film 618 was formed over the insulating film 616. As the insulating film 618, a 100-nm-thick silicon nitride film was formed with a PECVD apparatus. The insulating film 618 was deposited under the conditions where the substrate temperature was 350° C.; a silane gas at a flow rate of 50 sccm, a nitrogen gas at a flow rate of 5000 sccm, and an ammonia gas at a flow rate of 100 sccm were introduced into a chamber; the pressure was 100 Pa; and an RF power of 1000 W was supplied between parallel-plate electrodes provided in a PECVD apparatus. Note that preheating was not performed on the substrate before formation of the insulating film 618.

Next, a resist mask was formed over the insulating film 618, and a desired region was etched, whereby the opening 642b reaching the conductive film 612c was formed. The opening 642b was formed with a dry etching apparatus. Note that the resist mask was removed after the opening 642b was formed.

Next, a conductive film was formed over the insulating film 618 to cover the opening 642b and processed to form the conductive film 620. As the conductive film 620, a 100-nm-thick ITSO film was formed with a sputtering apparatus. The ITSO film was deposited under the conditions where the substrate temperature was room temperature, an argon gas at a flow rate of 72 sccm and an oxygen gas at a flow rate of 5 sccm were introduced into a chamber, the pressure was 0.15 Pa, and a DC power of 3200 W was supplied to a metal oxide target provided in a sputtering apparatus. Note that the composition of the metal oxide target used for forming the ITSO film was the same as that used for forming the protective film described above.

Then, third heat treatment was performed. The third heat treatment was performed at 250° C. for 1 hour in a nitrogen atmosphere.

Through the above process, Sample C1 and Sample C2 were fabricated.

### <2-3. Reliability Test>

Next, reliability tests were performed on Sample C1 and Sample C2.

As the reliability test, a dark negative stress (hereinafter, referred to as negative bias temperature stress (NBTS)) test was performed. Note that the NBTS test is one kind of accelerated test and a change in characteristics, caused by long-term usage, of transistors can be evaluated in a short time. In particular, the amount of change in threshold voltage (ΔVth) of the transistor between before and after a NBTS test is an important indicator for examining reliability. The smaller the amount of a change in the threshold voltage (ΔVth) between before and after the NBTS test is, the higher the reliability of the transistor is.

The NETS test was performed under the conditions where the gate voltage (Vg) and the back gate voltage (Vbg) were −30 V; the drain voltage (Vd) and the source voltage (Vs) were 0 V (COMMON); the stress temperature was 60° C.; the stress application time was the following six conditions: 0 sec, 100 sec, 500 sec, 1500 sec, 2000 sec, and 3600 sec; and the measurement environment was a dark environment. In other words, the source electrode and the drain electrode of the transistor were set at the same potential, and a potential different from that of the source and drain electrodes was applied to the gate electrode for a certain time (six conditions, here). The potential applied to the gate electrode was lower than the potential of the source electrode and the drain electrode.

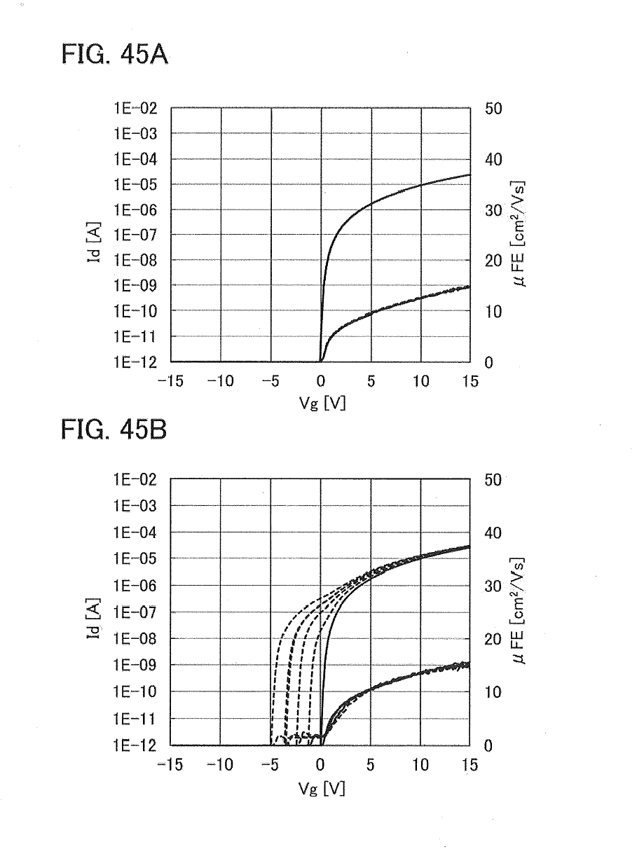

Results of the reliability tests of Sample C1 and Sample C2 are shown in FIGS. 45A and 45B.

Note that FIGS. 45A and 45B show the result of the reliability test of Sample C1 and the result of the reliability test of Sample C2, respectively. In FIGS. 45A and 45B, the first vertical axis shows the drain current I_{d} (A), the second vertical axis shows the mobility μFE (cm²/Vs), and the horizontal axis shows the gate voltage V_{g} (V). Furthermore, voltage between the source electrode and the drain electrode (the voltage is expressed as Vd) was set at 10 V, and Vg was applied from −15 V to 15 V at intervals of 0.25 V. In FIGS. 45A and 45B, results of the stress application time (0 sec, 100 sec, 500 sec, 1500 sec, 2000 sec, and 3600 sec) are also shown. In FIGS. 45A and 45B, a solid line shows the result of an initial state (the stress application time of 0 sec), and dashed lines show the results after the stress application (the stress application time was 100 sec, 500 sec, 1500 sec, 2000 sec, and 3600 sec).

According to the results in FIGS. 45A and 45B, the amount of a change in threshold voltage before and after the NBTS test is small in Sample C1. In Sample C2, the threshold voltage is shifted in the negative direction after the NBTS test.

### <2-4. Cross-Sectional Observation 1>

Next, since it was found that there was a difference in the amount of change in threshold voltage before and after the NBTS test between Sample C1 and Sample C2, and cross sections of Sample C1 and Sample C2 were observed.

The cross-sectional observation was performed with a transmission electron microscope (TEM) in the channel length direction.

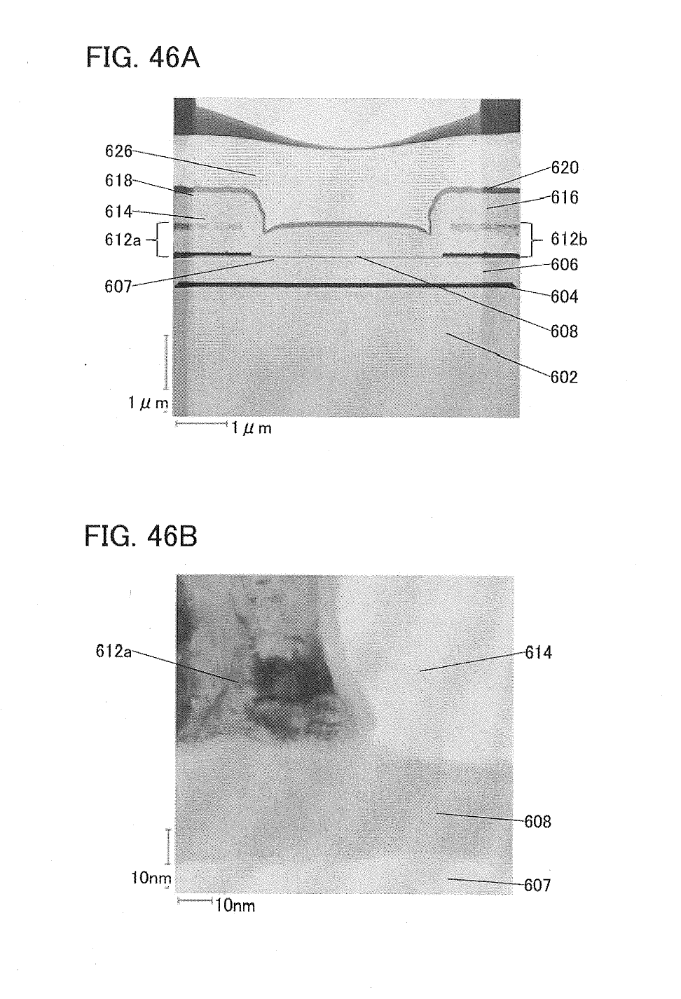

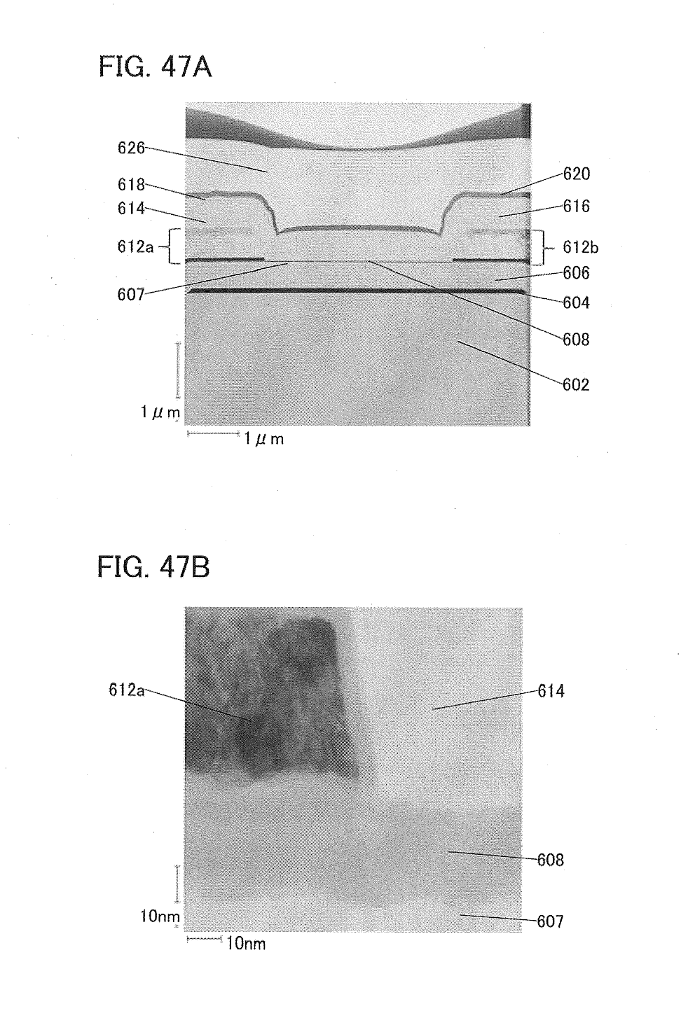

FIGS. 46A and 46B show an observation result of the cross section of Sample C1, and FIGS. 47A and 47B show an observation result of the cross section of Sample C2.

Note that FIG. 46B and FIG. 47B each show an enlarged cross section of the vicinity of the oxide semiconductor film 608.

According to the result in FIG. 46B, the thickness of the oxide semiconductor film 608 in Sample C1 in a region where the conductive film 612a was formed was 33.5 nm, and the thickness of the oxide semiconductor film 608 in Sample C1 in a region where the conductive film 612a was not formed was 28.8 nm. That is, in the oxide semiconductor film 608 of Sample C1, the difference in thickness between the region where the conductive film 612a was formed and the region where the conductive film 612a was not formed was 4.7 nm.

According to the result in FIG. 47B, the thickness of a region of the oxide semiconductor film 608 in Sample C2, where the conductive film 612a was formed, was 31.2 nm, and the thickness of a region of the oxide semiconductor film 608 in Sample C2, where the conductive film 612a was not formed, was 24.9 nm. That is, in the oxide semiconductor film 608 of Sample C2, the difference in thickness between the region where the conductive film 612a was formed and the region where the conductive film 612a was not formed was 6.3 nm.

Sample C1 and Sample C2 differ from each other in the conditions for forming the tungsten film (conductive film 612a). In Sample C1, the deposition power of the tungsten film was 20 kW. In Sample C2, the deposition power of the tungsten film was 60 kW. As described in Example 1, in the case where the tungsten film was formed with deposition power of 20 kW, a low resistance region having a thickness of approximately 5 nm and a region which includes VₒH and has a thickness of approximately 6 nm were formed in the oxide semiconductor film. In the case where the tungsten film was formed with deposition power of 60 kW, a low resistance region having a thickness of approximately 10 nm and a region which includes VₒH and has a thickness of approximately 17 nm were formed in the oxide semiconductor film.

It is indicated that Sample C1 has high reliability because of its structure in which the low resistance region and the region which includes VₒH are almost removed in a region where the conductive film 612a was not formed, that is, the channel region, and Sample C2 has low reliability because of its structure in which most of the low resistance region and most of the region which includes VₒH are left in a region where the conductive film 612a was not formed, that is, the channel region.

### <2-5. Cross-Sectional Observation 2>

Next, portions of the cross sections of Sample C1 and Sample C2, which are different from those in <2-4. Cross-Sectional Observation 1>, were observed.

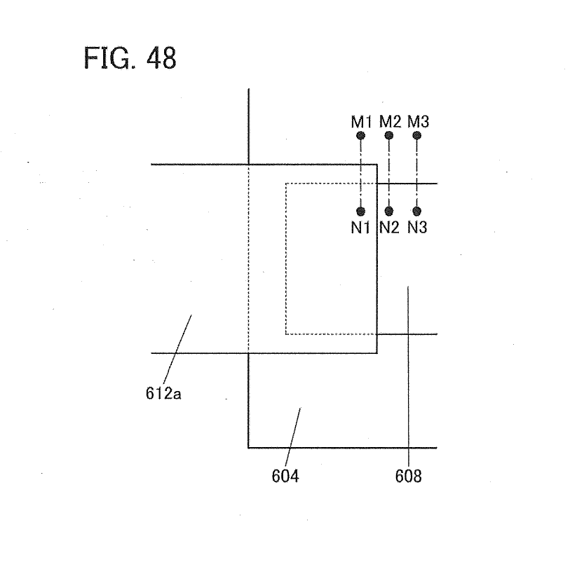

The cross-sectional observation was performed with a transmission electron microscope (TEM). The observation portions of the cross sections were portions indicated by dashed dotted line M1-N1, a dashed dotted line M2-N2, and a dashed dotted line M3-N3 in FIG. 48. Note that FIG. 48 is an enlarged view of the vicinity of the conductive film 604 functioning as a gate electrode, the oxide semiconductor film 608, and the conductive film 612a functioning as a source electrode of the transistor 600 in FIG. 44A.

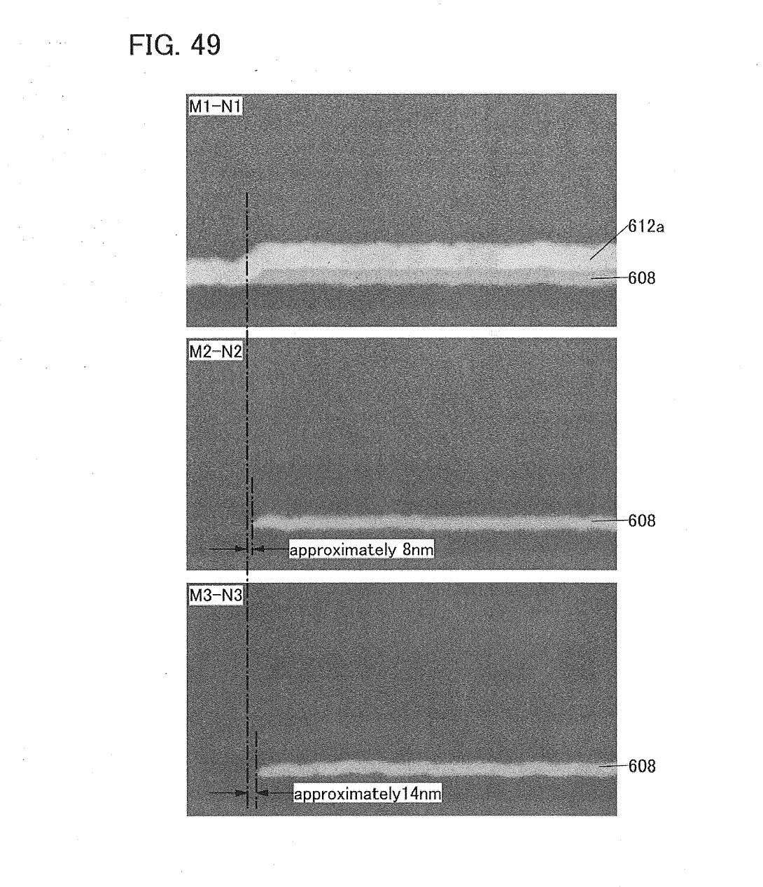

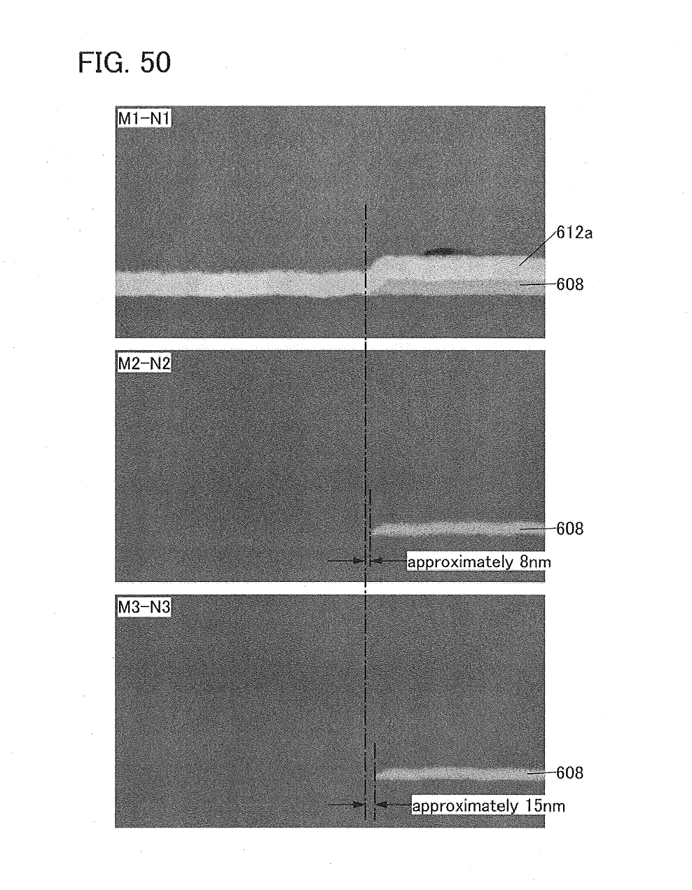

FIG. 49 shows an observation result of the cross section of Sample C1, and FIG. 50 shows an observation result of the cross section of Sample C2. Note that in FIG. 49 and FIG. 50, cross-sectional TEM images taken along dashed dotted line M1-N1, dashed dotted line M2-N2, and dashed dotted line M3-N3 in FIG. 48 are shown. In the cross-sectional TEM images, an auxiliary line and the like are added.

According to the results in FIG. 49 and FIG. 50, in each of Sample C1 and Sample C2, the oxide semiconductor film 608 under the conductive film 612a includes a region having a side edge portion with an acute angle. A region of the oxide semiconductor film 608, which is not covered with the conductive film 612a, that is, the region of the oxide semiconductor film 608, which functions as a channel region, includes a region having an arc-shaped side edge portion. In each of Sample C1 and Sample C2, the channel width of the region of the oxide semiconductor film 608, which functions as the channel region, is reduced by approximately 8 nm to 15 nm as compared to the oxide semiconductor film 608 under the conductive film 612a. It is indicated that the side edge portion of the region of the oxide semiconductor film 608, which functions as a channel region, has an arc shape because part of the oxide semiconductor film 608 was removed after formation of the conductive films 612a and 612b with a phosphoric acid solution (a solution obtained by diluting a solution having a phosphoric acid concentration of 85% with water by 100 times).

As described above, in the case where the conductive film is formed over the oxide semiconductor film, the low resistance region may be formed in the vicinity of the surface of the oxide semiconductor film. By removal of part of the low resistance region formed in the vicinity of the surface of the oxide semiconductor film, a highly reliable transistor can be provided.

The structure described above in this example can be combined as appropriate with any of the structures described in the other embodiments and examples.

### EXAMPLE 3

In this example, transistors having a structure different from the structure of Sample C1 and Sample C2 in Example 2 were fabricated, and in-plane variation of the transistors was evaluated, and reliability tests thereof were performed. Note that the structure of the transistors fabricated in this example was the same as that of the transistor 600 in Example 2.

In this example, Sample D1 and Sample D2 described below were fabricated as a transistor corresponding to the transistor 600. Note that each of Sample D1 and Sample D2 is a sample in which 40 transistors each having a channel length L of 6 μm and a channel width W of 50 μm are provided. Note that the transistors of Sample D1 and Sample D2 are each a transistor of one embodiment of the present invention.

### <3-1. Method for Fabricating Sample D1 and Sample D2>

First, the conductive film 604 was formed over the substrate 602. A glass substrate was used as the substrate 602. As the conductive film 604, a 100-nm-thick tungsten film was formed with a sputtering apparatus.

Next, the insulating film 606 and the insulating film 607 were formed over the substrate 602 and the conductive film 604. As the insulating film 606, a 400-nm-thick silicon nitride film was formed with a PECVD apparatus. As the insulating film 607, a 50-nm-thick silicon oxynitride film was formed with a PECVD apparatus.

Next, the oxide semiconductor film 608 was formed over the insulating film 607.

Note that Sample D1 and Sample D2 are different in conditions for forming the oxide semiconductor film 608.

As the oxide semiconductor film 608 of Sample D1, a 35-nm-thick IGZO film was formed with a sputtering apparatus. Note that the IGZO film was deposited under the conditions where the substrate temperature was 170° C., an argon gas at a flow rate of 100 sccm and an oxygen gas at a flow rate of 100 sccm were introduced into a chamber, the pressure was 0.6 Pa, and an AC power of 2500 W was applied to a metal oxide sputtering target (having an atomic ratio of In:Ga:Zn=1:1:1.2).

As the oxide semiconductor film 608 of Sample D2, a 10-nm-thick IGZO-1 film and a 15-nm-thick IGZO-2 film were formed with a sputtering apparatus. Note that the IGZO-1 film was deposited under the conditions where the substrate temperature was 170° C., an argon gas at a flow rate of 100 sccm and an oxygen gas at a flow rate of 100 sccm were introduced into a chamber, the pressure was 0.6 Pa, and an AC power of 2500 W was applied to a metal oxide sputtering target (having an atomic ratio of In:Ga:Zn=1:1:1.2). Note that the IGZO-2 film was deposited under the conditions where the substrate temperature was 170° C., an argon gas at a flow rate of 140 sccm and an oxygen gas at a flow rate of 60 sccm were introduced into a chamber, the pressure was 0.6 Pa, and an AC power of 2500 W was applied to a metal oxide sputtering target (having an atomic ratio of In:Ga:Zn=4:2:4.1).

Then, first heat treatment was performed. As the first heat treatment, heat treatment was performed at 450° C. for 1 hour in a nitrogen atmosphere and then heat treatment was performed at 450° C. for 1 hour in a mixed atmosphere of nitrogen and oxygen.

Next, a resist mask was formed over the insulating film 607 and the oxide semiconductor film 608, and a desired region was etched, whereby the opening 642a reaching the conductive film 604 was formed. The opening 642a was formed with a dry etching apparatus. Note that the resist mask was removed after the opening 642a was formed.

After that, a conductive film was formed over the insulating film 607, the oxide semiconductor film 608, and the opening 642a, a resist mask was formed over the conductive film, and a desired region was etched, whereby the conductive films 612a, 612b, and 612c were formed. As the conductive films 612a and 612b, and 612c, a 50-nm-thick tungsten film, a 400-nm-thick aluminum film, and a 100-nm-thick titanium film were successively formed in vacuum with a sputtering apparatus. Note that the resist mask was removed after the conductive films 612a, 612b, and 612c were formed.

The tungsten film in each of Sample D1 and Sample D2 was formed under the conditions where an argon gas was supplied at a flow rate of 100 sccm to the treatment chamber of the sputtering apparatus; the pressure in the treatment chamber was controlled to 2 Pa; and a direct-current power of 20 kW (the power density of 2.70 W/cm²) was supplied to a sputtering target of tungsten.

Next, a phosphoric acid solution (a solution obtained by diluting a solution having a phosphoric acid concentration of 85% with water by 100 times) was supplied from above the insulating film 607, the oxide semiconductor film 608, and the conductive films 612a and 612b, and thus part of a surface of the oxide semiconductor film 608, which was not covered with the conductive films 612a and 612b, was removed, so that a region of the oxide semiconductor film 608, which was not covered with the conductive films 612a and 612b, was formed.

Next, the insulating films 614 and 616 were formed over the insulating film 607, the oxide semiconductor film 608, and the conductive films 612a and 612b. As the insulating film 614, a 50-nm-thick silicon oxynitride film was formed with a PECVD apparatus. As the insulating film 616, a 400-nm-thick silicon oxynitride film was formed with a PECVD apparatus. Note that the insulating films 614 and 616 were formed successively in vacuum with a PECVD apparatus.

The insulating film 614 was deposited under the conditions where the substrate temperature was 220° C., a silane gas at a flow rate of 50 sccm and a dinitrogen monoxide gas at a flow rate of 2000 sccm were introduced into a chamber, the pressure was 20 Pa, and an RF power of 100 W was supplied between parallel-plate electrodes provided in a PECVD apparatus. The insulating film 616 was deposited under the conditions where the substrate temperature was 220° C., a silane gas at a flow rate of 160 sccm and a dinitrogen monoxide gas at a flow rate of 4000 sccm were introduced into a chamber, the pressure was 200 Pa, and an RF power of 1500 W was supplied between the parallel-plate electrodes provided in the PECVD apparatus.

Then, second heat treatment was performed. The second heat treatment was performed at 350° C. in a nitrogen atmosphere for 1 hour.

Next, the protective film was formed over the insulating film 616. As the protective film, a 5-nm-thick ITSO film was formed with a sputtering apparatus. The ITSO film was deposited under the conditions where the substrate temperature was room temperature, an argon gas at a flow rate of 72 sccm and an oxygen gas at a flow rate of 5 sccm were introduced into a chamber, the pressure was 0.15 Pa, and a DC power of 1000 W was supplied to a metal oxide target (In₂O₃:SnO₂:SiO₂=85:10:5 [wt. %]) provided in a sputtering apparatus.

Next, oxygen addition treatment was performed on the insulating films 614 and 616 through the protective film The oxygen addition treatment was performed with an ashing apparatus under the conditions where the substrate temperature was 40° C., an oxygen gas at a flow rate of 250 sccm was introduced into a chamber, the pressure was 15 Pa, and an RF power of 4500 W was supplied for 120 sec. between parallel-plate electrodes provided in the ashing apparatus so that a bias would be applied to the substrate side.

Next, the protective film was removed to expose a surface of the insulating film 616. The protective film was removed in such a manner that treatment with an oxalic acid solution containing an oxalic acid at a concentration of 5% was performed for 30 sec. and then treatment with hydrofluoric acid containing a hydrofluoric acid at a concentration of 0.5% was performed for 15 sec.

The insulating film 618 was formed over the insulating film 616. As the insulating film 618, a 100-nm-thick silicon nitride film was formed with a PECVD apparatus. The insulating film 618 was deposited under the conditions where the substrate temperature was 350° C.; a silane gas at a flow rate of 50 sccm, a nitrogen gas at a flow rate of 5000 sccm, and an ammonia gas at a flow rate of 100 sccm were introduced into a chamber; the pressure was 100 Pa; and an RF power of 1000 W was supplied between parallel-plate electrodes provided in a PECVD apparatus. Note that preheating was not performed on the substrate before formation of the insulating film 618.

Next, a resist mask was formed over the insulating film 618, and a desired region was etched, whereby the opening 642b reaching the conductive film 612c was formed. The opening 642b was formed with a dry etching apparatus. Note that the resist mask was removed after the opening 642b was formed.

Next, a conductive film was formed over the insulating film 618 to cover the opening 642b and processed to form the conductive film 620. As the conductive film 620, a 100-nm-thick ITSO film was formed with a sputtering apparatus. The ITSO film was deposited under the conditions where the substrate temperature was room temperature, an argon gas at a flow rate of 72 sccm and an oxygen gas at a flow rate of 5 sccm were introduced into a chamber, the pressure was 0.15 Pa, and a DC power of 3200 W was supplied to a metal oxide target provided in a sputtering apparatus. Note that the composition of the metal oxide target used for forming the ITSO film was the same as that used for forming the protective film described above.

Then, third heat treatment was performed. The third heat treatment was performed at 250° C. for 1 hour in a nitrogen atmosphere.

Through the above process, Sample D1 and Sample D2 were fabricated.

### <3-2. Evaluation of In-Plane Variation of Transistor>

Next, in-plane variations of the transistors of Sample D1 and Sample D2 fabricated above were evaluated. Note that for evaluation of the in-plane variations of the transistors, the on-state current (Ion) and the threshold voltage (Vth) were measured.

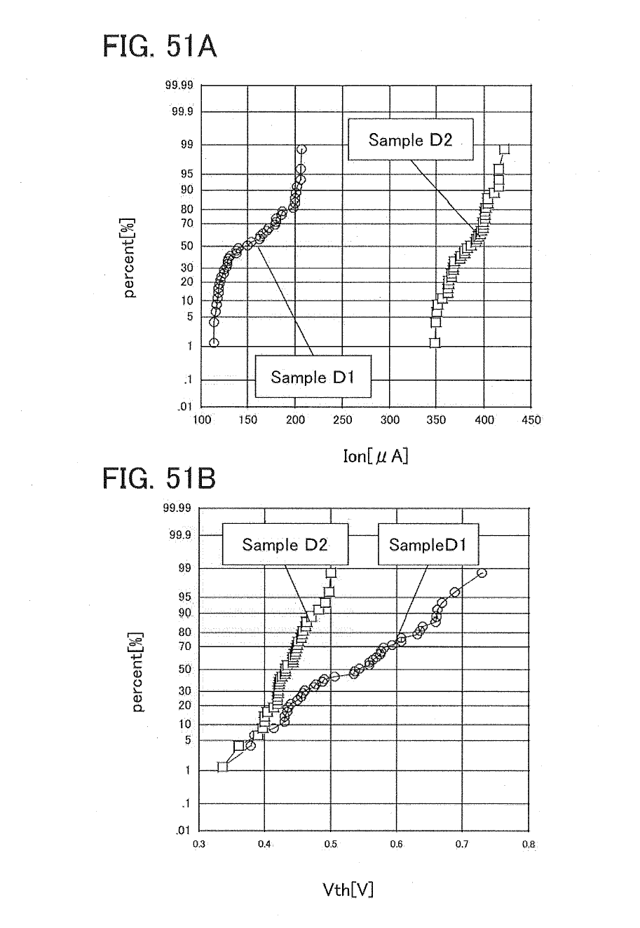

FIGS. 51A and 51B show results of the in-plane variations of Sample D1 and Sample D2. Note that FIG. 51A shows probability distribution of the on-state current (Ion) of Sample D1 and Sample D2, and FIG. 51B shows probability distribution of the threshold voltages (Vth) of Sample D1 and Sample D2.

The results show that Sample D2 has higher on-state current (Ion) and a smaller in-plane variation in the on-state current than Sample D1 because the oxide semiconductor film 608 of Sample D2 has a structure different from that of Sample D1. The results also show that Sample D2 has a smaller in-plane variation in the threshold voltage (Vth) than Sample D1. This reveals that although Sample D1 and Sample D2 are each a transistor of one embodiment of the present invention as described above, Sample D2 in which the oxide semiconductor film 608 has a stacked-layer structure has more favorable electrical characteristics.

### <3-3. Reliability Test>

Next, reliability tests were performed on Samples D1 and D2. As the reliability evaluation, GBT tests were used.

The GBT tests in this example were performed under the conditions where the gate voltage (VG) was ±30 V; the drain voltage (VD) and the source voltage (VS) were 0 V (COMMON); the stress temperature was 60° C.; the time for stress application was 1 hour; and two kinds of measurement environments, a dark environment and a photo environment (irradiation with light having approximately 10000 lx with a white LED), were employed. In other words, the source electrode and the drain electrode of the transistor were set at the same potential, and a potential different from that of the source and drain electrodes was applied to the gate electrode for a certain time (one hour, here). A case where the potential applied to the gate electrode is higher than that of the source and drain electrodes is called positive bias, and a case where the potential applied to the gate electrode is lower than that of the source and drain electrodes is called negative bias. Thus, in combination with the measurement environments, the reliability tests were performed under four conditions, i.e., positive bias temperature stress (PBTS), negative bias temperature stress (NBTS), positive bias illuminations temperature stress (PBITS), and negative bias illuminations temperature stress (KBITS).

The GBT tests were performed on one transistor arbitrarily selected from the 40 transistors formed in each of Sample D1 and Sample D2.

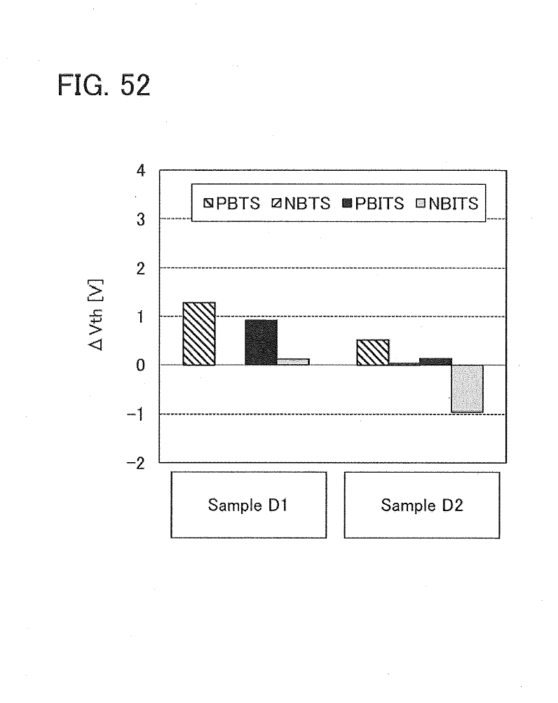

FIG. 52 shows the GBT test results of Samples D1 and D2. In FIG. 52, the vertical axis represents the amount of change in threshold voltage (ΔVth) of the transistor, and the horizontal axis represents Samples D1 and D2.

According to the results in FIG. 52, the amount of change in threshold voltage (ΔVth) in each of Samples D1 and D2 of one embodiment of the present invention was less than or equal to ±2 V. The amount of change in threshold voltage (ΔVth) in Sample D2 was less than or equal to ±1 V.

The structure described above in this example can be combined as appropriate with any of the structures described in the other embodiments and examples.

### EXAMPLE 4

In this example, transistors having structures different from those of Samples D1 and D2 described in Example 3 were fabricated and subjected to constant-current stress tests.

In this example, Sample D3 and Sample D4 were fabricated. Note that each of Sample D3 and Sample D4 is a transistor of one embodiment of the present invention.

A structure and a manufacturing process of Sample D3 were the same as those of the transistor in Sample D1 in Example 3 except for the size of the transistor. Note that the channel length and the channel width of Sample D3 were 3 μm and 6 μm, respectively.

A structure and a manufacturing process of Sample D4 were the same as those of the transistor in Sample D2 in Example 3 except for the size of the transistor. Note that the channel length and the channel width of Sample D4 were 3 μm and 5 μm, respectively.

### <4. Constant-Current Stress Test>

Next, constant-current stress tests were performed on Samples D3 and D4 fabricated above. Note that the constant-current stress tests were performed under the conditions where the atmosphere was an air atmosphere; the state was a dark state (dark); the test temperature was 60° C.; and the drain voltage and the gate voltage were adjusted so that the stress current was 100 nA/μm.

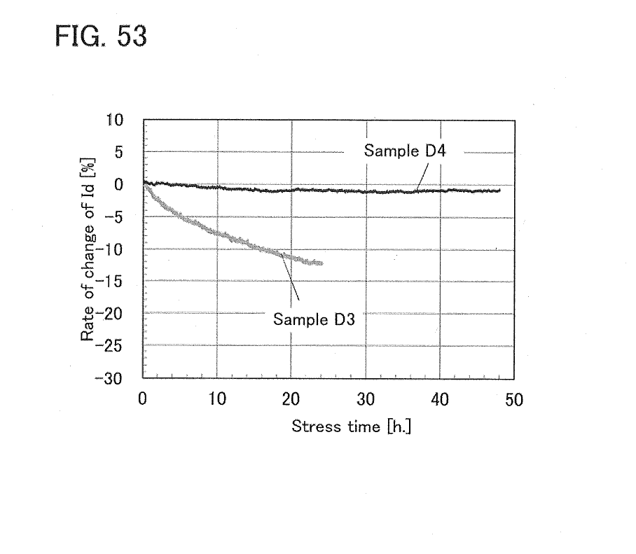

FIG. 53 shows results of the constant-current stress tests of Samples D3 and D4. In FIG. 53, the vertical axis represents the deterioration rate of the on-state current (Ion) of the transistors, and the horizontal axis represents the stress time.

As shown in FIG. 53, Samples D3 and D4 have high reliability. In particular, Sample D4 has an extremely small deterioration rate of the on-state current (Ion) after 40 hours. This shows that a transistor of one embodiment of the present invention has high reliability.

The structure described above in this example can be combined as appropriate with any of the structures described in the other embodiments and examples.

This application is based on Japanese Patent Application serial no. 2014-241466 filed with Japan Patent Office on Nov. 28, 2014 and Japanese Patent Application serial no. 2014-264766 filed with Japan Patent Office on Dec. 26, 2014, the entire contents of which are hereby incorporated by reference.

What is claimed is:

1. A semiconductor device comprising:
a gate electrode;
a gate insulating film over the gate electrode;
an oxide semiconductor film over the gate insulating film; and
a pair of electrodes over the oxide semiconductor film,
wherein the oxide semiconductor film comprises a channel region and n-type regions in contact with the pair of electrodes, and
wherein the channel region has fewer oxygen vacancies than the n-type regions.

2. The semiconductor device according to claim 1, further comprising an oxide insulating film over the oxide semiconductor film and the pair of electrodes.

3. The semiconductor device according to claim 2, wherein oxygen atoms of more than or equal to 8.0×10¹⁴ atoms/cm² are detected from the oxide insulating film by thermal desorption spectroscopy.

4. The semiconductor device according to claim 1, wherein the channel region has a thinner region than a region of the oxide semiconductor film under the pair of electrodes.

5. The semiconductor device according to claim 1,
wherein the oxide semiconductor film comprises In, Zn, and M, and
wherein M is Ti, Ga, Y, Zr, La, Ce, Nd, Sn, or Hf.

6. The semiconductor device according to claim 1,
wherein the oxide semiconductor film comprises a crystal part, and
wherein the crystal part has c-axis alignment and comprises a portion whose c-axis is parallel to a normal vector of a surface over which the oxide semiconductor film is fanned.

7. A display device comprising:
the semiconductor device according to claim 1; and
a display element.

8. A display module comprising:
the display device according to claim 7; and
a touch sensor

9. An electronic device comprising:
the semiconductor device according to claim 1, the display device according to claim 7, or the display module according to claim 8; and
an operation key or a battery.

10. A semiconductor device comprising:
a first gate electrode;
a gate insulating film over the first gate electrode;
an oxide semiconductor film over the gate insulating film;
a pair of electrodes over the oxide semiconductor film;
an oxide insulating film over the oxide semiconductor film and the pair of electrodes;
a nitride insulating film over the oxide insulating film; and
a second gate electrode over the nitride insulating film,
wherein the oxide semiconductor film comprises a channel region and n-type regions in contact with the pair of electrodes, and
wherein the channel region has fewer oxygen vacancies than the n-type regions.

11. The semiconductor device according to claim 10, wherein the channel region has a thinner region than a region of the oxide semiconductor film under the pair of electrodes.

12. The semiconductor device according to claim 10,
wherein the oxide semiconductor film comprises In, Zn, and M, and
wherein M is Ti, Ga, Y, Zr, La, Ce, Nd, Sn, or Hf.

13. The semiconductor device according to claim 10,
wherein the oxide semiconductor film comprises a crystal part, and
wherein the crystal part has c-axis alignment and comprises a portion whose c-axis is parallel to a normal vector of a surface over which the oxide semiconductor film is formed.

14. The semiconductor device according to claim 10, wherein oxygen atoms of more than or equal to 8.0×10¹⁴ atoms/cm² are detected from the oxide insulating film by thermal desorption spectroscopy.

15. A display device comprising:
the semiconductor device according to claim 10; and
a display element.

16. A display module comprising:
the display device according to claim 15; and
a touch sensor

17. An electronic device comprising:
the semiconductor device according to claim 10, the display device according to claim 15, or the display module according to claim 16; and
an operation key or a battery.

18. A method for manufacturing a semiconductor device, comprising the steps of:
forming a gate electrode over a substrate;
forming a gate insulating film over the gate electrode;
forming an oxide semiconductor film over the gate insulating film;
forming a conductive film over the oxide semiconductor film to form a region having oxygen vacancies in the oxide semiconductor film;
processing the conductive film to form a pair of electrodes; and
removing the region of the oxide semiconductor film which is between the pair of electrodes with a chemical solution or a gas.

19. The method for manufacturing a semiconductor device according to claim 18, further comprising the steps of:
forming an oxide insulating film over the oxide semiconductor film and the pair of electrodes; and
adding oxygen to the oxide insulating film.

20. The method for manufacturing a semiconductor device according to claim 18, wherein the conductive film is formed with a sputtering apparatus.

21. The method for manufacturing a semiconductor device according to claim 18, wherein the conductive film is formed with the power density of greater than or equal to 1 W/cm² and less than or equal to 4 W/cm².
